(19) United States
(12) Patent Application Publication
(10) Pub. No.: US 2023/0127039 A1
(43) Pub. Date: Apr. 27, 2023

(54) LIGHT EMITTING ELEMENT

(71) Applicant: Samsung Display Co., Ltd., Yongin-si (KR)

(72) Inventors: TSUYOSHI NAIJO, Suwon-si (KR); HYOSUP SHIN, Hwaseong-si (KR); JIYOUNG LEE, Hwaseong-si (KR)

(21) Appl. No.: 17/889,217

(22) Filed: Aug. 16, 2022

(30) Foreign Application Priority Data
Oct. 19, 2021 (KR) 10-2021-0139013

(51) Int. Cl. H01L 51/00; H01L 51/50

(52) U.S. Cl. CPC H01L 51/008; H01L 51/5056; H01L 51/0072; H01L 51/0064; H01L 51/5072; H01L 51/5004

(57) ABSTRACT

A light emitting element includes a first electrode, a second electrode disposed on the first electrode, and an emission layer disposed between the first electrode and the second electrode. The emission layer may include a hole transporting host, an electron transporting host, a phosphorescent sensitizer, and a delayed fluorescent dopant. The delayed fluorescent dopant may have a greater absolute value of the HOMO energy level than the hole transporting host. Accordingly, the light emitting element including the delayed fluorescent dopant in an embodiment may exhibit long lifespan.

### CROSS-REFERENCE TO RELATED APPLICATIONS

This application claims priority to and the benefit of Korean Patent Application No. 10-2021-0139013, filed on Oct. 19, 2021, the entire content of which is hereby incorporated by reference.

### BACKGROUND

### 1. Field

The present disclosure herein relates to a light emitting element including a delayed fluorescent dopant.

### 2. Description of the Related Art

As image display devices, organic electroluminescence display devices and/or the like have been actively developed lately. The organic electroluminescence display devices are display devices including so-called self-luminescent light emitting elements in which holes and electrons injected from a first electrode and a second electrode recombine in an emission layer, and thus a luminescent material in the emission layer emits light to accomplish display (e.g., to display an image).

In the application of light emitting elements to display devices, there is a demand (or desire) for light emitting elements having long service life, and development of light emitting elements capable of stably attaining such characteristics is being continuously pursued.

### SUMMARY

One or more aspects of embodiments of the present disclosure are directed toward a light emitting element having long lifespan.

According to an embodiment of the present disclosure, a light emitting element includes: a first electrode; a second electrode on the first electrode; and an emission layer between the first electrode and the second electrode and including a hole transporting host, an electron transporting host, a phosphorescent sensitizer, and a delayed fluorescent dopant, wherein the hole transporting host has a lower absolute value of the Highest Occupied Molecular Orbital (HOMO) energy level than the delayed fluorescent dopant.

In an embodiment, the delayed fluorescent dopant may be represented by Formula 1.

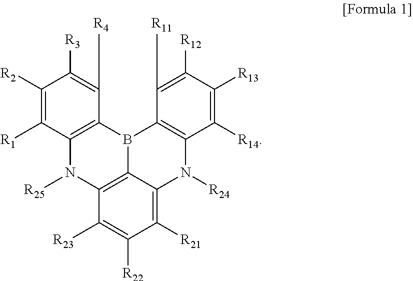

In Formula 1, two or more of R₁ to R₄, R₁₁ to R₁₄, and R₂₁ to R₂₅ may each independently include a substituted or unsubstituted carbazole group, and the rest (e.g., the remaining R₁ to R₄, R₁₁ to R₁₄, and R₂₁ to R₂₅) may each independently be a hydrogen atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms, and when R₁ to R₄, R₁₁ to R₁₄, and/or R₂₁ to R₂₅ each independently includes a substituted carbazole group, a substituent of the substituted carbazole group may be selected from a cyano group, a substituted or unsubstituted alkyl group having 1 to 10 carbon atoms, and a substituted or unsubstituted aryl group having 6 to 30 ring-forming carbon atoms.

In an embodiment, R₁ to R₄, R₁₁ to R₁₄, and R₂₁ to R₂₅ may each independently be represented by any one among groups R1-1 to R1-13:

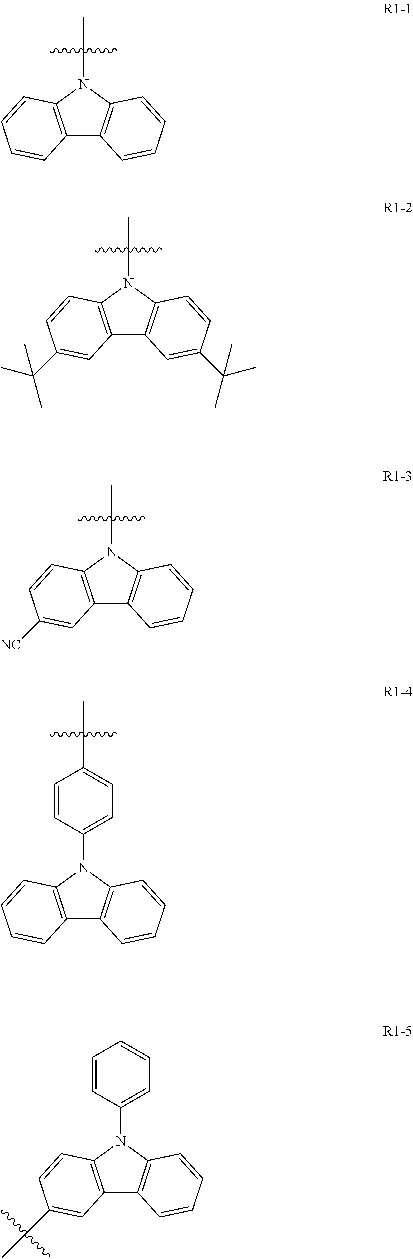 [SMILES: *n1c2ccccc2c2ccccc21 ; *n1c2ccc(C(C)(C)C)cc2c2cc(C(C)(C)C)ccc21 ; *n1c2ccccc2c2cc(C#N)ccc21 ; *c1ccc(-n2c3ccccc3c3ccccc32)cc1 ; *c1ccc2c(c1)c1ccccc1n2-c1ccccc1]

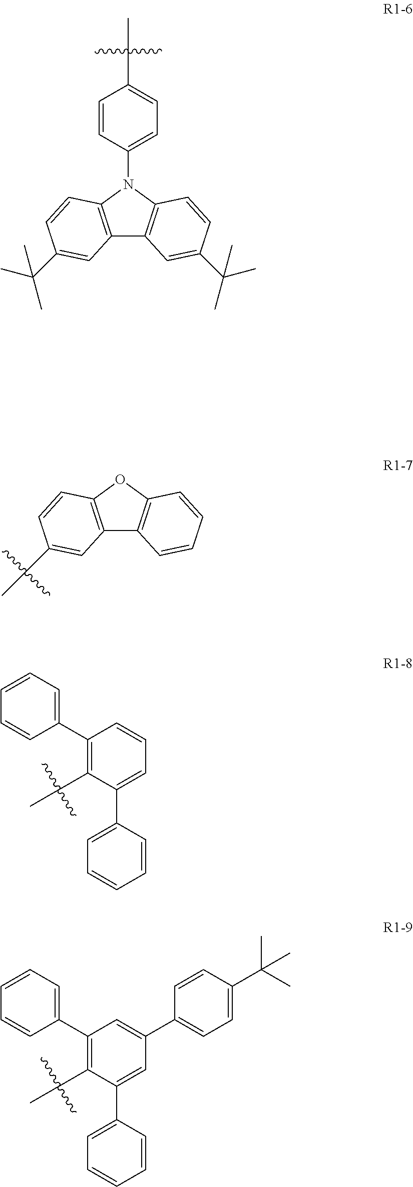 [SMILES: *c1ccc(-n2c3ccc(C(C)(C)C)cc3c3cc(C(C)(C)C)ccc32)cc1 ; *c1ccc2oc3ccccc3c2c1 ; *c1c(-c2ccccc2)cccc1-c1ccccc1 ; *c1c(-c2ccccc2)cc(-c2ccc(C(C)(C)C)cc2)cc1-c1ccccc1]

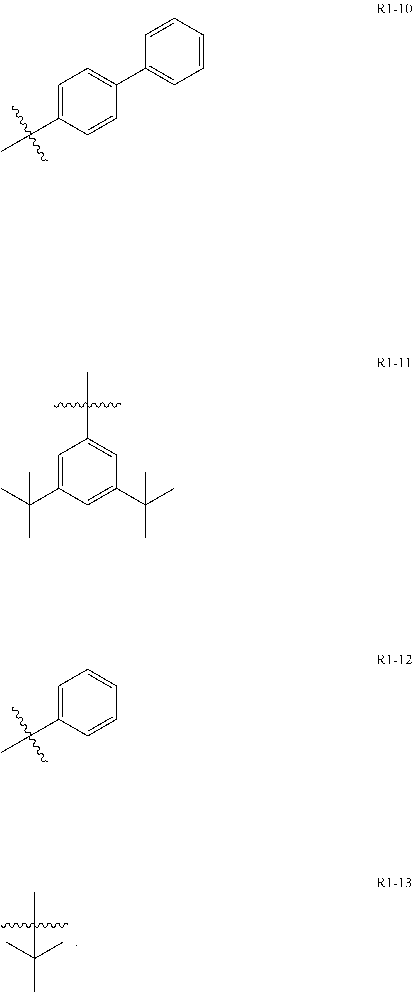

In an embodiment, the delayed fluorescent dopant may be a multiple resonance (MR) type or kind delayed fluorescent dopant.

In an embodiment, the phosphorescent sensitizer may have a lower absolute value of the HOMO energy level than each of the hole transporting host and the delayed fluorescent dopant.

In an embodiment, a difference in the absolute value of the HOMO energy level between the hole transporting host and the delayed fluorescent dopant may be about 0.05 eV to about 0.22 eV.

In an embodiment, the light emitting element may satisfy Expression A-1.

E_{I}≥C_{I}×0.9 [Expression A-1]

In Expression A-1, E_{I} is a current value at a driving voltage of 7.5 V of a first hole only device (HOD) including a first emission layer containing the hole transporting host, the electron transporting host, and the delayed fluorescent dopant; C_{I} is a current value at a driving voltage of 7.5 V of a second hole only device (HOD) including a second emission layer containing the hole transporting host and the electron transporting host without the delayed fluorescent dopant; the first hole only device includes the first electrode, the second electrode on the first electrode, the first emission layer between the first electrode and the second electrode, a first hole transport region between the first electrode and the first emission layer, and a second hole transport region between the first emission layer and the second electrode; and the second hole only device includes the first electrode, the second electrode on the first electrode, the second emission layer between the first electrode and the second electrode, the first hole transport region between the first electrode and the second emission layer, and the second hole transport region between the second emission layer and the second electrode.

In an embodiment, the hole transporting host may be represented by Formula HT-1.

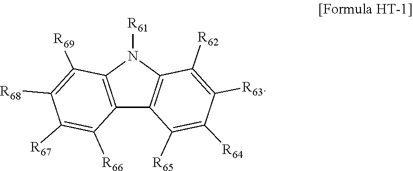

In Formula HT-1, one among R₆₁ to R₆₉ may include a substituted or unsubstituted carbazole group, and the rest (e.g., the remaining among R₆₁ to R₆₉) may each independently be a hydrogen atom, a substituted or unsubstituted aryl group having 6 to 20 ring-forming carbon atoms, or a substituted or unsubstituted heteroaryl group having 2 to 20 ring-forming carbon atoms.

In an embodiment, the electron transporting host may be represented by Formula ET-1.

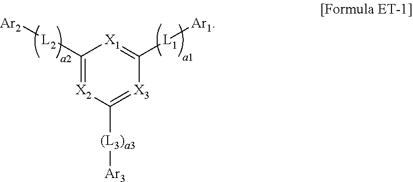

In Formula ET-1, at least one of X₁ to X₃ may be N and the rest (the remaining of X₁ to X₃) may each independently be CRₐ, Rₐ is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, a1 to a3 may each independently be an integer of 0 to 10, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms, and Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the phosphorescent sensitizer may be represented by Formula M-a or Formula M-b:

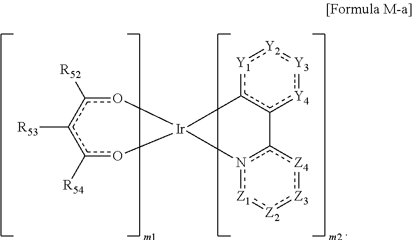

In Formula M-a, Y₁ to Y₄, and Z₁ to Z₄ may each independently be CR₅₁ or N, and R₅₁ to R₅₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, m1 may be 0 or 1, m2 may be 2 or 3, when m1 is 0, m2 is 3, and when m1 is 1, m2 is 2.

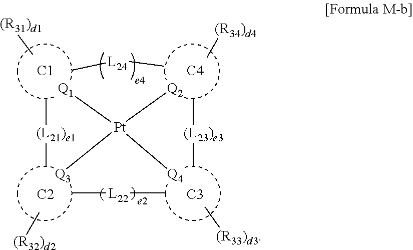

In Formula M-b, Q₁ to Q₄ may each independently be C or N, C1 to C4 may each independently be a substituted or unsubstituted hydrocarbon ring having 5 to 30 ring-forming carbon atoms, or a substituted or unsubstituted heterocycle having 2 to 30 ring-forming carbon atoms, e1 to e4 may each independently be 0 or 1, L₂₁ to L₂₄ may each independently be a direct linkage,

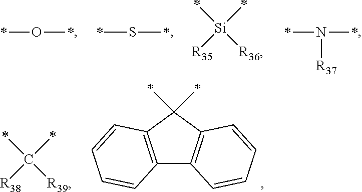

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, d1 to d4 may each independently be an integer of 0 to 4, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In an embodiment, the light emitting element may further include a hole transport region between the first electrode and the emission layer, and an electron transport region between the emission layer and the second electrode.

In an embodiment of the present disclosure, a light emitting element includes: a first electrode; a second electrode on the first electrode; and an emission layer between the first electrode and the second electrode and including a hole transporting host, an electron transporting host, a phosphorescent sensitizer, and a delayed fluorescent dopant represented by Formula 1.

In an embodiment, the hole transporting host may have a lower absolute value of the HOMO energy level than the delayed fluorescent dopant, and the phosphorescent sensitizer may have a lower absolute value of the HOMO energy level than each of the hole transporting host and the delayed fluorescent dopant.

In an embodiment, the hole transporting host may be represented by Formula HT-1, the electron transporting host may be represented by Formula ET-1, and the phosphorescent sensitizer may be represented by Formula M-a or Formula M-b.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a plan view showing a display device according to an embodiment;

FIG. 2 is a cross-sectional view showing a portion corresponding to the line I-I′ of FIG. 1;

FIG. 3 is a cross-sectional view schematically showing a light emitting element according to an embodiment;

FIG. 4 is a cross-sectional view schematically showing a light emitting element according to an embodiment;

FIG. 5 is a cross-sectional view schematically showing a light emitting element according to an embodiment;

FIG. 6 is a cross-sectional view schematically showing a light emitting element according to an embodiment;

FIG. 7 shows an energy diagram of a light emitting element according to an embodiment;

FIG. 8 is a cross-sectional view showing a display device according to an embodiment;

FIG. 9 is a cross-sectional view of a display device according to an embodiment;

FIG. 10 is a cross-sectional view showing a display device according to an embodiment;

FIG. 11 is a cross-sectional view showing a display device according to an embodiment;

FIG. 12 shows relative current values and relative lifespan in light emitting elements of Comparative Examples and Examples; and

FIG. 13 shows HOMO energy levels and relative lifespan of dopants in light emitting elements of Comparative Examples and Examples.

### DETAILED DESCRIPTION

The present disclosure may be modified in many alternate forms, and thus specific embodiments will be shown in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

In the present description, when an element (or a region, a layer, a portion, etc.) is referred to as being “on,” “connected to,” or “coupled to” another element, it refers to that the element may be directly disposed on/connected to/coupled to the other element, or that a third element may be disposed therebetween.

Like reference numerals refer to like elements. In addition, in the drawings, the thickness, the ratio, and the dimensions of elements may be exaggerated for an effective description of technical contents. The term “and/or,” includes all combinations of one or more of which associated configurations may define.

It will be understood that, although the terms “first,” “second,” etc. may be used herein to describe one or more suitable elements, these elements should not be limited by these terms. These terms are only used to distinguish one element from another element. For example, a first element may be referred to as a second element, and similarly, a second element may be referred to as a first element without departing from the teachings of the present disclosure. The singular forms are intended to include the plural forms as well, unless the context clearly indicates otherwise.

Also, terms such as “below”, “on lower side”, “above”, “on upper side”, and/or the like may be used to describe the relationships of the components illustrated in the drawings. The terms are used as a relative concept and are described with reference to the direction indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure pertains. It is also to be understood that terms defined in commonly used dictionaries should be interpreted as having meanings consistent with the meanings in the context of the related art, and will not be interpreted in an idealized or overly formal sense unless expressly so defined herein.

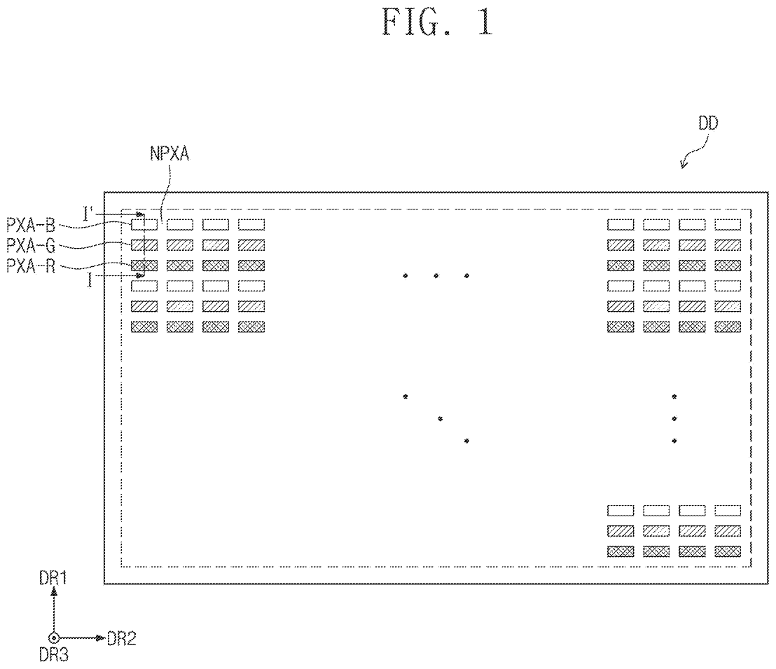

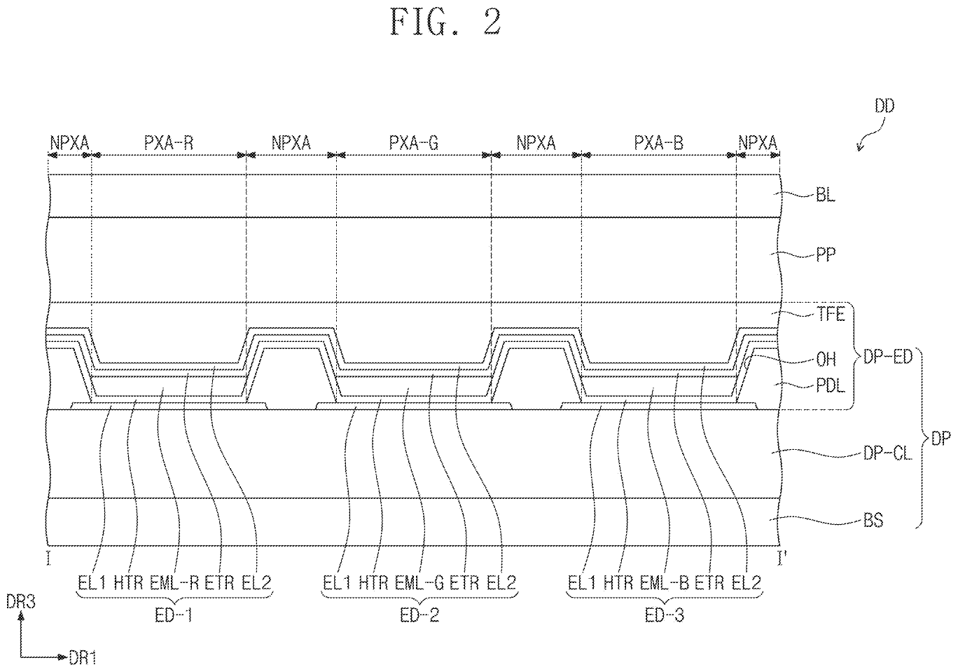

Hereinafter, a light emitting element according to an embodiment will be described with reference to the accompanying drawings. FIG. 1 is a plan view showing an embodiment of a display device DD. FIG. 2 is a cross-sectional view of a display device DD of an embodiment. FIG. 2 is a cross-sectional view showing a portion corresponding to the line I-I′ of FIG. 1.

The display device DD may include a display panel DP and an optical layer PP disposed on the display panel DP. The display panel DP may include light emitting elements ED-1, ED-2, and ED-3. The display device DD may include a plurality of light emitting elements ED-1, ED-2, and ED-3. The optical layer PP may be disposed on the display panel DP to control reflected light in the display panel DP due to external light. The optical layer PP may include, for example, a polarizing layer and/or a color filter layer. In some embodiments, unlike what is shown in the drawings, the optical layer PP may not be provided in the display device DD of an embodiment.

A base substrate BL may be disposed on the optical layer PP. The base substrate BL may be a member providing a base surface on which the optical layer PP is disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, unlike what is shown, the base substrate BL may not be provided.

The display device DD according to an embodiment may further include a filling layer. The filling layer may be disposed between a display element layer DP-ED and the base substrate BL. The filling layer may be an organic material layer. The filling layer may include at least one among (e.g., at least one selected from) an acrylic resin, a silicone-based resin, and an epoxy-based resin.

The display panel DP may include a base layer BS, a circuit layer DP-CL provided on the base layer BS, and a display element layer DP-ED. The display element layer DP-ED may include pixel defining films PDL, a plurality of light emitting elements ED-1, ED-2, and ED-3 disposed between the pixel defining films PDL, and an encapsulation layer TFE disposed on the plurality of light emitting elements ED-1, ED-2, and ED-3.

The base layer BS may be a member providing a base surface on which the display element layer DP-ED is disposed. The base layer BS may be a glass substrate, a metal substrate, a plastic substrate, etc. However, the embodiment of the present disclosure is not limited thereto, and the base layer BS may be an inorganic layer, an organic layer, or a composite material layer.

In an embodiment, the circuit layer DP-CL may be disposed on the base layer BS, and the circuit layer DP-CL may include a plurality of transistors. The transistors may each include a control electrode, an input electrode, and an output electrode. For example, the circuit layer DP-CL may include a switching transistor and a driving transistor for driving the plurality of light emitting elements ED-1, ED-2 and ED-3 of the display element layer DP-ED.

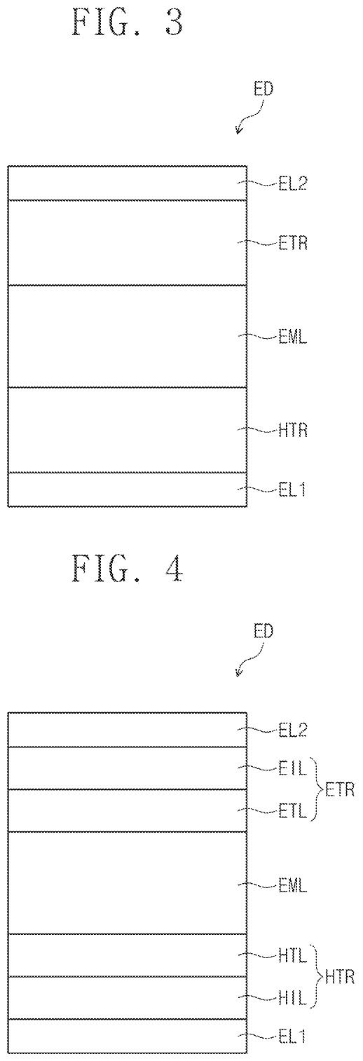

The light emitting elements ED-1, ED-2, and ED-3 may each have a structure of a light emitting element ED of an embodiment shown in FIGS. 3 to 6, which will be described later in more detail. The light emitting elements ED-1, ED-2, and ED-3 may each include a first electrode EL1, a hole transport region HTR, emission layers EML-R, EML-G, and/or EML-B (e.g., the light emitting elements ED-1, ED-2, and ED-3 may each include a corresponding one of the emission layer EML-R, the emission layer EML-G, or the emission layer EML-B), an electron transport region ETR, and a second electrode EL2.

FIG. 2 shows an embodiment in which the emission layers EML-R, EML-G, and EML-B of the light emitting elements ED-1, ED-2, and ED-3 are disposed in the openings OH defined in the pixel defining films PDL, and the hole transport region HTR, the electron transport region ETR, and the second electrode EL2 are provided as a common layer throughout the light emitting elements ED-1, ED-2, and ED-3.

However, the embodiment of the present disclosure is not limited thereto, and unlike what is shown in FIG. 2, in an embodiment, the hole transport region HTR and the electron transport region ETR may be provided to be patterned inside the openings OH defined in the pixel defining films PDL. For example, in an embodiment, the hole transport region HTR, the emission layers EML-R, EML-G, and EML-B, and the electron transport region ETR, etc., of the light emitting elements ED-1, ED-2, and ED-3 may be patterned and provided through an inkjet printing method.

An encapsulation layer TFE may cover the light emitting elements ED-1, ED-2 and ED-3. The encapsulation layer TFE may seal the display element layer DP-ED.

The encapsulation layer TFE may be a thin film encapsulation layer. The encapsulation layer TFE may be a single layer or a laminated layer of a plurality of layers. The encapsulation layer TFE may include at least one insulating layer. The encapsulation layer TFE according to an embodiment may include at least one inorganic film (hereinafter, an encapsulation inorganic film). In some embodiments, the encapsulation layer TFE according to an embodiment may include at least one organic film (hereinafter, an encapsulation organic film) and at least one encapsulation inorganic film.

The encapsulation inorganic film may protect the display element layer DP-ED from moisture/oxygen, and the encapsulation organic film may protect the display element layer DP-ED from foreign substances such as dust particles. The encapsulation inorganic film may include silicon nitride, silicon oxy nitride, silicon oxide, titanium oxide, aluminum oxide, etc., but the present disclosure is not particularly limited thereto. The encapsulation organic layer may include an acrylic compound, an epoxy-based compound, etc. The encapsulation organic layer may include a photopolymerizable organic material, and is not particularly limited.

The encapsulation layer TFE may be disposed on the second electrode EL2, and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region emitting light generated from each of the light emitting elements ED-1, ED-2, and ED-3. The light emitting regions PXA-R, PXA-G, and PXA-B may be spaced apart from each other when viewed on a plane (e.g., in a plan view).

The light emitting regions PXA-R, PXA-G, and PXA-B may each be a region separated by the pixel defining films PDL. The non-light emitting regions NPXA may be regions between neighboring light emitting regions PXA-R, PXA-G, and PXA-B, and may correspond to the pixel defining films PDL. In the present description, the light emitting regions PXA-R, PXA-G, and PXA-B may each correspond to a pixel. The pixel defining films PDL may separate the light emitting elements ED-1, ED-2 and ED-3. The emission layers EML-R, EML-G, and EML-B of the luminescence devices ED-1, ED-2 and ED-3 may be disposed and separated in openings OH defined by the pixel defining films PDL.

The light emitting regions PXA-R, PXA-G, and PXA-B may be divided into a plurality of groups according to the color of light generated from the light emitting elements ED-1, ED-2, and ED-3. In the display device DD of an embodiment shown in FIGS. 1 and 2, three light emitting regions PXA-R, PXA-G, and PXA-B which emit red light, green light, and blue light, respectively, are illustrated as an example. For example, the display device DD of an embodiment may include a red light emitting region PXA-R, a green light emitting region PXA-G, and a blue light emitting region PXA-B, which are distinct from one another.

In the display device DD according to an embodiment, the plurality of light emitting elements ED-1, ED-2, and ED-3 may be to emit light having different wavelength ranges. For example, in an embodiment, the display device DD may include a first light emitting element ED-1 emitting red light, a second light emitting element ED-2 emitting green light, and a third light emitting element ED-3 emitting blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2 and ED-3 may be to emit light in substantially the same wavelength range or emit light in at least one different wavelength range. For example, the first to third light emitting elements ED-1, ED-2, and ED-3 may all emit blue light.

The light emitting regions PXA-R, PXA-G, and PXA-B in the display device DD according to an embodiment may be arranged in the form of a stripe. Referring to FIG. 1, a plurality of red light emitting regions PXA-R may be arranged with each other along a second directional axis DR2, a plurality of green light emitting regions PXA-G may be arranged with each other along the second directional axis DR2, and a plurality of blue light emitting regions PXA-B may be arranged with each other along the second directional axis DR2. In some embodiments, the red light emitting region PXA-R, the green light emitting region PXA-G, and the blue light emitting region PXA-B may be alternately arranged in turn (e.g., with each other) along a first directional axis DR1.

FIGS. 1 and 2 illustrate that the light emitting regions PXA-R, PXA-G, and PXA-B are all similar in size (e.g., area), but the embodiment of the present disclosure is not limited thereto, and the light emitting regions PXA-R, PXA-G and PXA-B may be different in size from each other according to the wavelength range of the emitted light. The areas of the light emitting regions PXA-R, PXA-G, and PXA-B may refer to areas when viewed on a plane defined by the first directional axis DR1 and the second directional axis DR2 (e.g., in a plan view).

The arrangement of the light emitting regions PXA-R, PXA-G, and PXA-B is not limited to what is shown in FIG. 1, and the order in which the red light emitting region PXA-R, the green light emitting region PXA-G, and the blue light emitting region PXA-B are arranged may be provided in one or more suitable combinations according to the characteristics of the display quality desired for the display device DD. For example, the light emitting regions PXA-R, PXA-G, and PXA-B may be in a pentile (PENTILE®) arrangement form (e.g., an RGBG matrix, RGBG structure, or RGBG matrix structure) or a diamond arrangement form. PENTILE® is a duly registered trademark of Samsung Display Co., Ltd.

In some embodiments, the areas of each of the light emitting regions PXA-R, PXA-G, and PXA-B may be different in size from one another. For example, in an embodiment, the green light emitting region PXA-G may be smaller than the blue light emitting region PXA-B in size, but the embodiment of the present disclosure is not limited thereto.

Hereinafter, FIGS. 3 to 6 are cross-sectional views schematically showing a light emitting element according to an embodiment. Referring to FIG. 3, the light emitting element ED according to an embodiment may include a first electrode EL1, a hole transport region HTR, an emission layer EML, an electron transport region ETR, and a second electrode EL2.

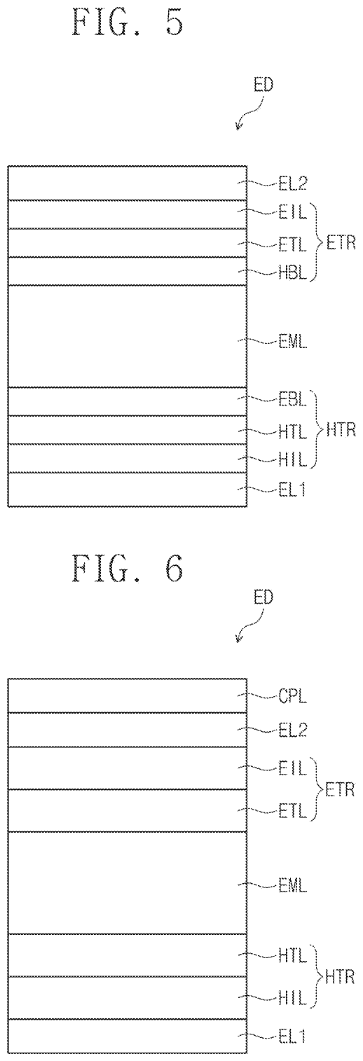

FIG. 4 shows, compared with FIG. 3, a cross-sectional view of a light emitting element ED of an embodiment in which the hole transport region HTR includes a hole injection layer HIL and a hole transport layer HTL, and the electron transport region ETR includes an electron injection layer EIL and an electron transport layer ETL. In some embodiments, FIG. 5 shows, compared with FIG. 3, a cross-sectional view of a light emitting element ED of an embodiment in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. FIG. 6 shows, compared with FIG. 4, a cross-sectional view of a light emitting element ED of an embodiment, in which a capping layer CPL disposed on the second electrode EL2 is provided.

The emission layer EML according to an embodiment may include a hole transporting host, an electron transporting host, a phosphorescent sensitizer, and a delayed fluorescent dopant. The hole transporting host may include a carbazole derivative. The electron transporting host may include a compound containing a heterocyclic group having nitrogen (N) as a ring-forming atom. The phosphorescent sensitizer may include a metal complex containing platinum (Pt) or iridium (Ir). The delayed fluorescent dopant may include a compound containing a fused ring of five rings having two nitrogen atoms (N's) and one boron atom (B) as ring-forming atoms. In an embodiment, the delayed fluorescent dopant may have a greater absolute value of the HOMO energy level than the hole transporting host.

In the present description, the term “substituted or unsubstituted” may refer to a group or substituent that is unsubstituted or that is substituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or as a phenyl group substituted with a phenyl group.

In the present description, the term “bonded to an adjacent group to form a ring” may refer to a group or substituent that is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may each independently be monocyclic or polycyclic. In some embodiments, the rings formed by being bonded to each other may be connected to another ring to form a spiro structure.

In the present description, the term “an adjacent group” may refer to a pair of substituents where the first substituent is connected to an atom which is directly connected to another atom substituted with the second substituent; a pair of substituents connected to the same atom; or a pair of substituents where the first substituent is sterically positioned at the nearest position to the second substituent. For example, two methyl groups in 1,2-dimethylbenzene may be interpreted as mutually “adjacent groups” and two ethyl groups in 1,1-diethylcyclopentane may be interpreted as mutually “adjacent groups”. In some embodiments, two methyl groups in 4,5-dimethylphenanthrene may be interpreted as mutually “adjacent groups”.

In the present description, examples of a halogen atom may include a fluorine atom, a chlorine atom, a bromine atom, and an iodine atom.

In the present description, an alkyl group may be a linear, branched or cyclic alkyl group. The number of carbon atoms in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, a s-butyl group, a t-butyl group, an i-butyl group, a 2-ethylbutyl group, a 3,3-a dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but are not limited thereto.

In the present description, an alkenyl group refers to a hydrocarbon group including at least one carbon-carbon double bond in the middle and/or at a terminal end of an alkyl group having 2 or more carbon atoms. The alkenyl group may be linear or branched. The number of carbon atoms is not particularly limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but are not limited thereto.

In the present description, a hydrocarbon ring group refers to any functional group or substituent derived from an aliphatic hydrocarbon ring and an aromatic hydrocarbon ring. The hydrocarbon ring group may be a hydrocarbon ring group having 5 to 30 ring-forming carbon atoms.

In the present description, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but are not limited thereto.

In the present description, a heterocyclic group refers to any functional group or substituent derived from a ring containing at least one of B, O, N, P, Si, or S as a ring-forming hetero atom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic. When the heterocyclic group contains two or more hetero atoms, the two or more hetero atoms may be the same as or different from each other.

The heterocyclic group may be a monocyclic heterocyclic group or a polycyclic heterocyclic group, and may include a heteroaryl group. The number of ring-forming carbon atoms in the heterocyclic group may be 2 to 30, 2 to 20, or 2 to 10.

In the present description, a heteroaryl group may include at least one of B, O, N, P, Si, or S as a ring-forming hetero atom. When the heteroaryl group contains two or more hetero atoms, the two or more hetero atoms may be the same as or different from each other. The heteroaryl group may be a monocyclic heteroaryl group or a polycyclic heteroaryl group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but are not limited thereto.

In the present description, the above description of the aryl group may be applied to an arylene group, except that the arylene group is a divalent group. The above description of the heteroaryl group may be applied to a heteroarylene group, except that the heteroarylene group is a divalent group.

In the present description, a silyl group may include an alkyl silyl group and an aryl silyl group. Examples of the silyl group may include a trimethylsilyl group, a triethylsilyl group, a t-butyldimethylsilyl group, a propyldimethylsilyl group, a triphenylsilyl group, a diphenylsilyl group, a phenylsilyl group, etc., but are not limited thereto.

In the present description, a thio group may include an alkyl thio group and an aryl thio group. The thio group may refer to that a sulfur atom is bonded to an alkyl group or an aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but are not limited to thereto.

In the present description, an oxy group may refer to that an oxygen atom is bonded to an alkyl group or an aryl group as defined above. The oxy group may include an alkoxy group and an aryl oxy group. The alkoxy group may be linear, branched or cyclic. The number of carbon atoms in the alkoxy group is not particularly limited, but may be, for example, 1 to 20, or 1 to 10. Examples of the oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but are not limited thereto.

In the present description, a boron group may refer to that a boron atom is bonded to an alkyl group or an aryl group as defined above. The boron group may include an alkyl boron group and an aryl boron group. Examples of the boron group may include a dimethylboron group, a diethylboron group, a t-butylmethylboron group, a diphenylboron group, a phenylboron group, etc., but are not limited thereto.

In the present description, the number of carbon atoms in an amine group is not particularly limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but are not limited thereto.

In the present description, examples of the alkyl group included in an alkylthio group, an alkyl sulfoxy group, an alkyl oxy group, an alkyl amino group, an alkyl boron group, an alkyl silyl group, and an alkyl amine group may be the same as the examples of the alkyl group described above.

In the present description, examples of the aryl group included in an aryloxy group, an arylthio group, an aryl sulfoxy group, an aryl amino group, an aryl boron group, an aryl silyl group, and an aryl amine group may be the same as the examples of the aryl group described above.

In the present description, a direct linkage may refer to a single bond. In the present description, and

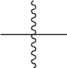

and

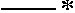 [SMILES: *C]

refer to positions to be connected.

The delayed fluorescent dopant may be represented by Formula 1. The emission layer may include the delayed fluorescent dopant represented by Formula 1.

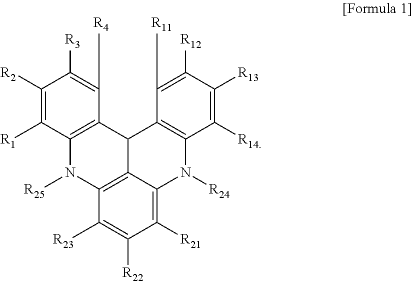

In Formula 1, two or more of R₁ to R₄, R₁₁ to R₁₄, and R₂₁ to R₂₅ may each independently include a substituted or unsubstituted carbazole group, and the rest of R₁ to R₄, R₁₁ to R₁₄, and R₂₁ to R₂₅ may each independently be a hydrogen atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms. That is, at least two of R₁ to R₄, R₁₁ to R₁₄, and R₂₁ to R₂₅ may each independently be a substituted or unsubstituted carbazole group, or may include a substituted or unsubstituted carbazole group as a substituent. When R₁ to R₄, R₁₁ to R₁₄, and/or R₂₁ to R₂₅ each independently includes a substituted carbazole group, a substituent of the substituted carbazole group may be selected from a cyano group, a substituted or unsubstituted alkyl group having 1 to 10 carbon atoms, and a substituted or unsubstituted aryl group having 6 to 30 ring-forming carbon atoms as a substituent.

In an embodiment, the delayed fluorescent dopant including two or more substituted or unsubstituted carbazole groups may have low hole trapping properties. A dopant material having high hole trapping properties may reduce hole movement in an emission layer. In some embodiments, the delayed fluorescent dopant including two or more substituted or unsubstituted carbazole groups may have a greater absolute value of the HOMO energy level than the hole transporting host. Accordingly, direct recombination in the delayed fluorescent dopant may be reduced, and the delayed fluorescent dopant may be less deteriorated. The recombination may refer to combination between holes and electrons.

When two or more of R₁ to R₄, R₁₁ to R₁₄, and R₂₁ to R₂₅ each independently include a substituted or unsubstituted carbazole group, the carbazole groups may all be the same or at least one may be different from the others. In an embodiment, R₁ to R₄, R₁₁ to R₁₄, and R₂₁ to R₂₅ may each independently be represented by any one among groups R1-1 to R1-13.

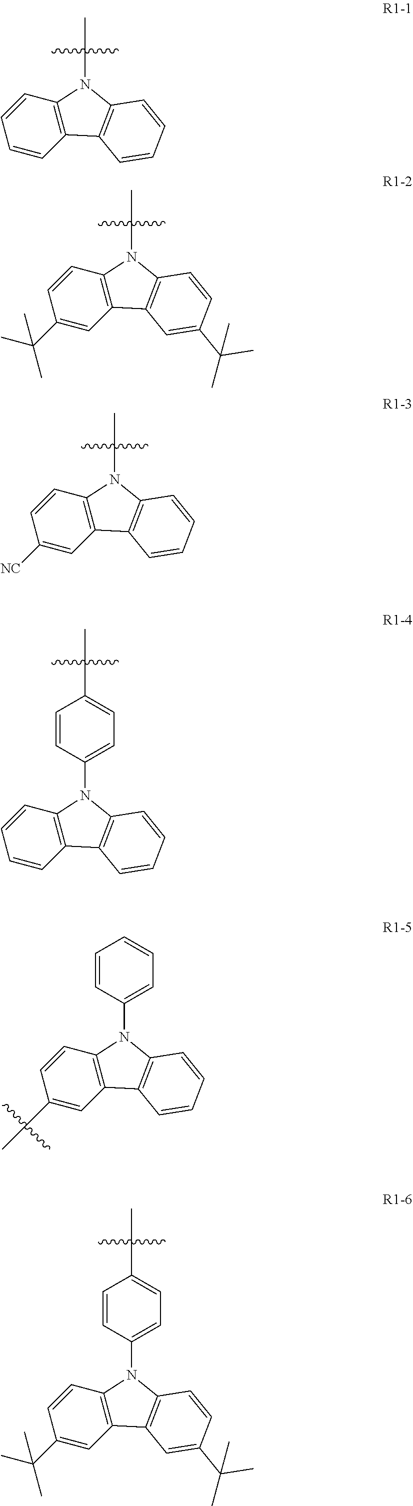

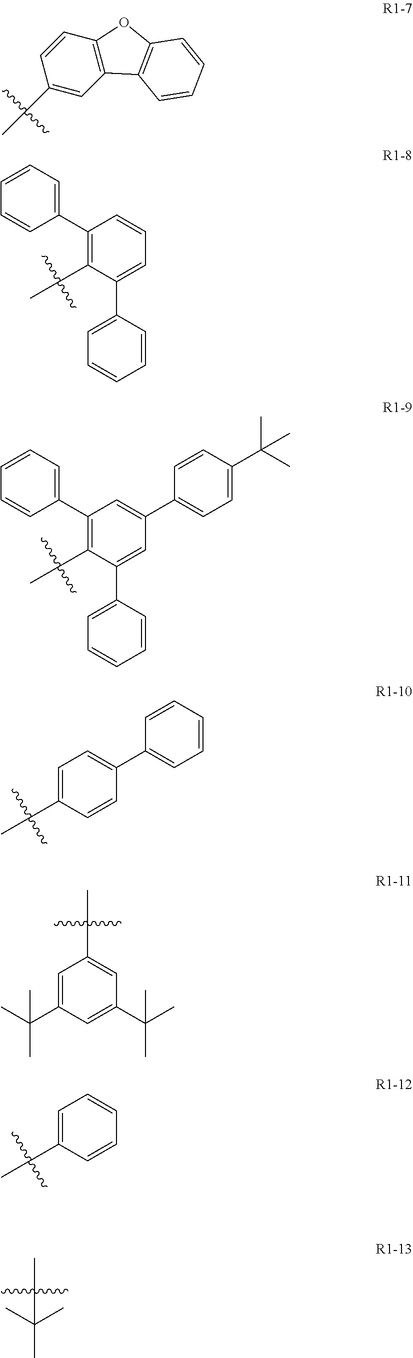

R1-1 indicates an unsubstituted carbazole group, R1-2 indicates a carbazole group substituted with two t-butyl groups, and R1-3 indicates a carbazole group substituted with a cyano group. R1-4 and R1-5 each indicate a carbazole group substituted with a phenyl group, and have different bonding positions. The bonding position in R1-4 is placed in the phenyl group, and the bonding position in R1-5 is placed in the carbazole group. R1-6 indicates a phenyl group substituted with (the N atom of) a carbazole group, and the carbazole group is further substituted with two t-butyl groups. R1-7 indicates an unsubstituted dibenzofuran, and R1-8 indicates an o-terphenyl (ortho-terphenyl) group. R1-9 indicates an o-terphenyl group substituted with a phenyl group, and the phenyl group is further substituted with a t-butyl group. R-10 indicates a biphenyl group, and R1-11 indicates a phenyl group substituted with two t-butyl groups. R1-12 indicates an unsubstituted phenyl group, and R1-13 indicates a t-butyl group. In some embodiments, the delayed fluorescent dopant represented by Formula 1 may include two or more of R1-1 to R1-6.

The delayed fluorescent dopant may include any one among compounds of Compound Group 1. The light emitting element ED of an embodiment may include any one among compounds of Compound Group 1.

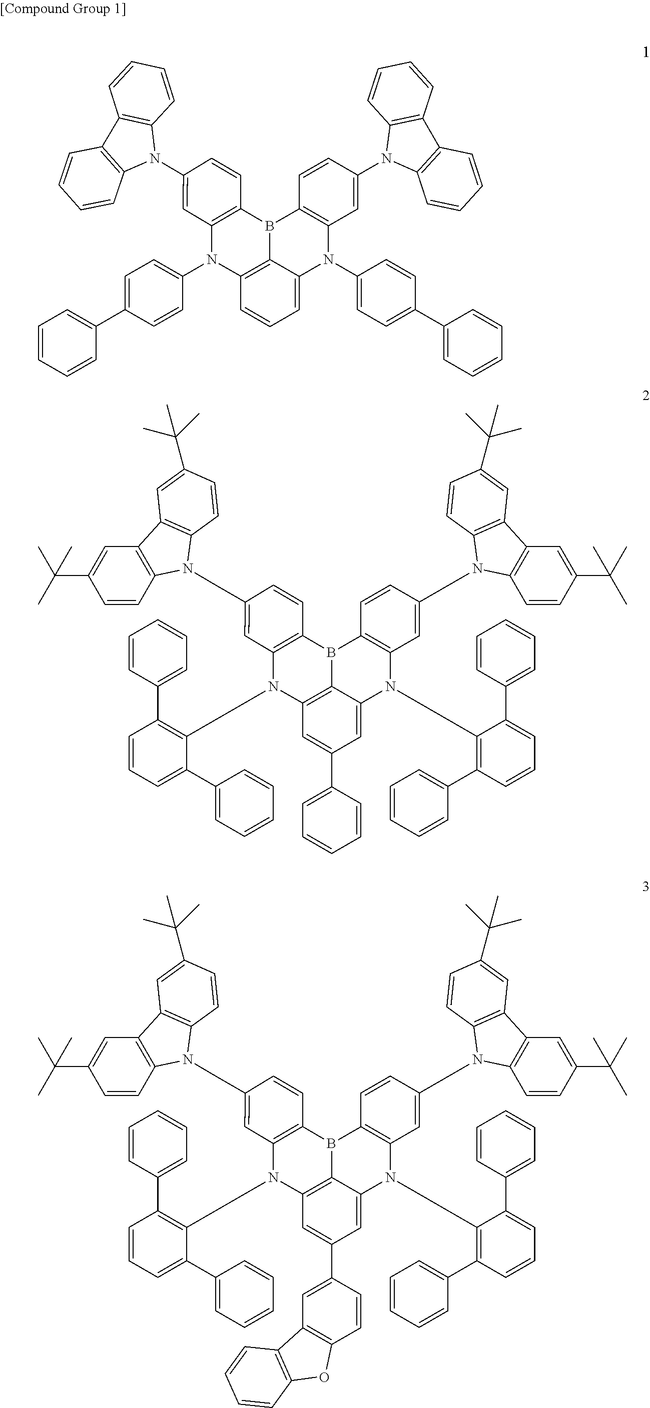

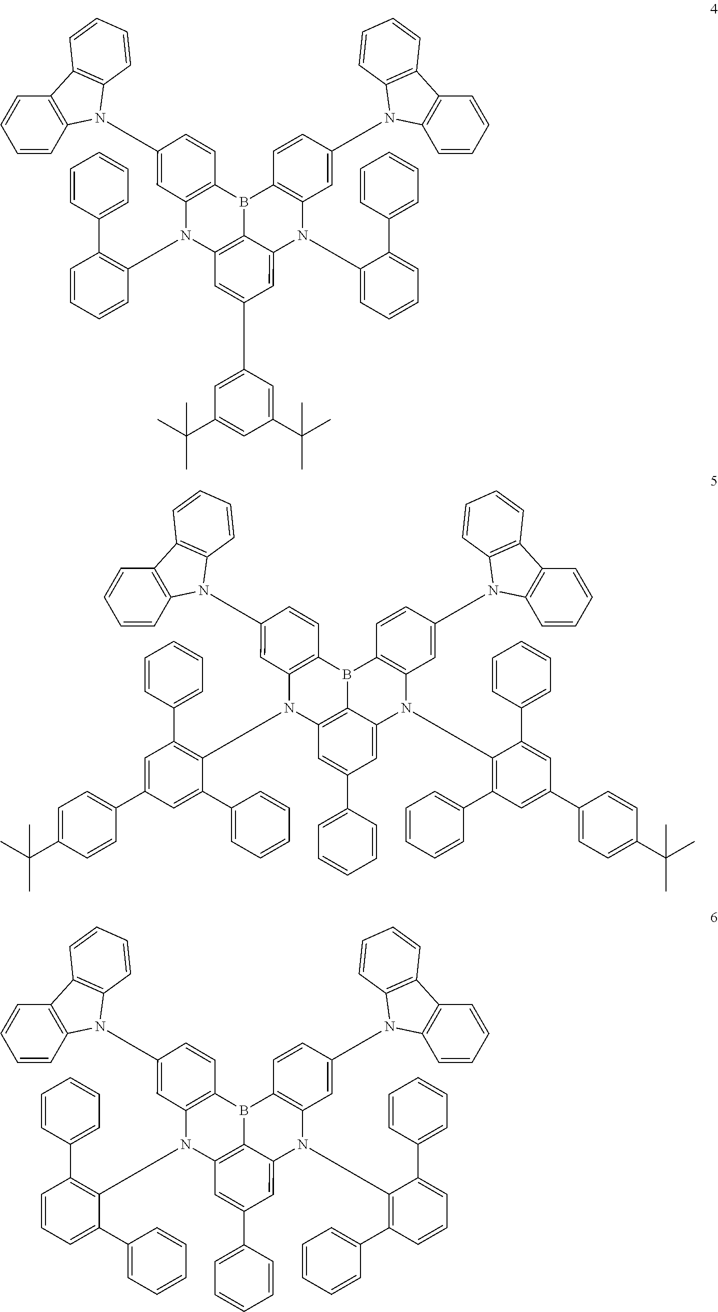

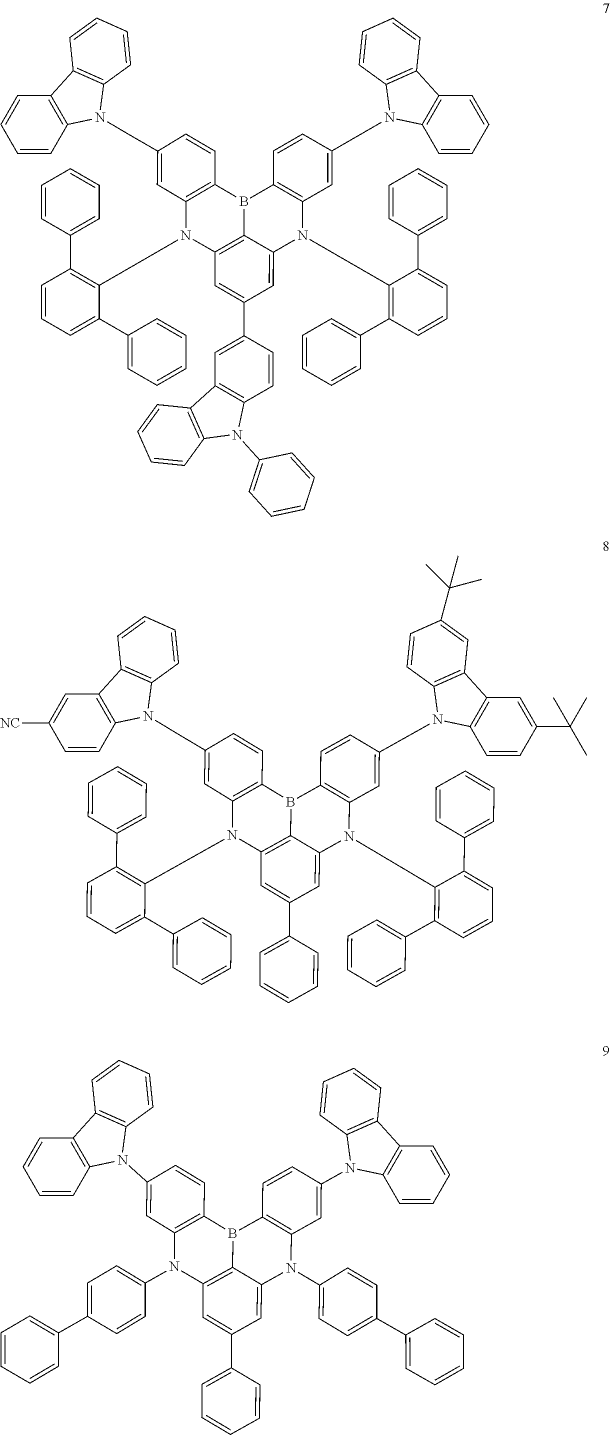 [SMILES: c1ccc(-c2cccc(-c3ccccc3)c2CCN2c3cc(Cn4c5ccccc5c5ccccc54)ccc3B3c4ccc(Cn5c6ccccc6c6ccccc65)cc4N(CCc4c(-c5ccccc5)cccc4-c4ccccc4)c4cc(-c5ccc6c(c5)c5ccccc5n6-c5ccccc5)cc2c43)cc1 ; CC(C)(C)c1ccc2c(c1)c1cc(C(C)(C)C)ccc1n2Cc1ccc2c(c1)N(CCc1c(-c3ccccc3)cccc1-c1ccccc1)c1cc(-c3ccccc3)cc3c1B2c1ccc(Cn2c4ccccc4c4cc(C#N)ccc42)cc1N3CCc1c(-c2ccccc2)cccc1-c1ccccc1 ; c1ccc(-c2ccc(N3c4cc(-n5c6ccccc6c6ccccc65)ccc4B4c5ccc(-n6c7ccccc7c7ccccc76)cc5N(c5ccc(-c6ccccc6)cc5)c5cc(-c6ccccc6)cc3c54)cc2)cc1]

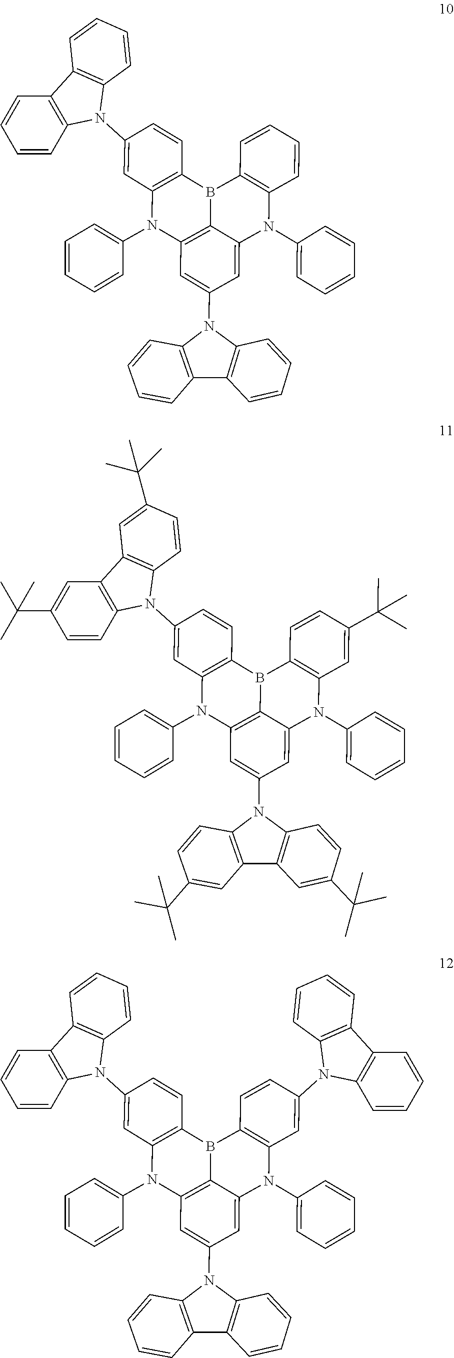

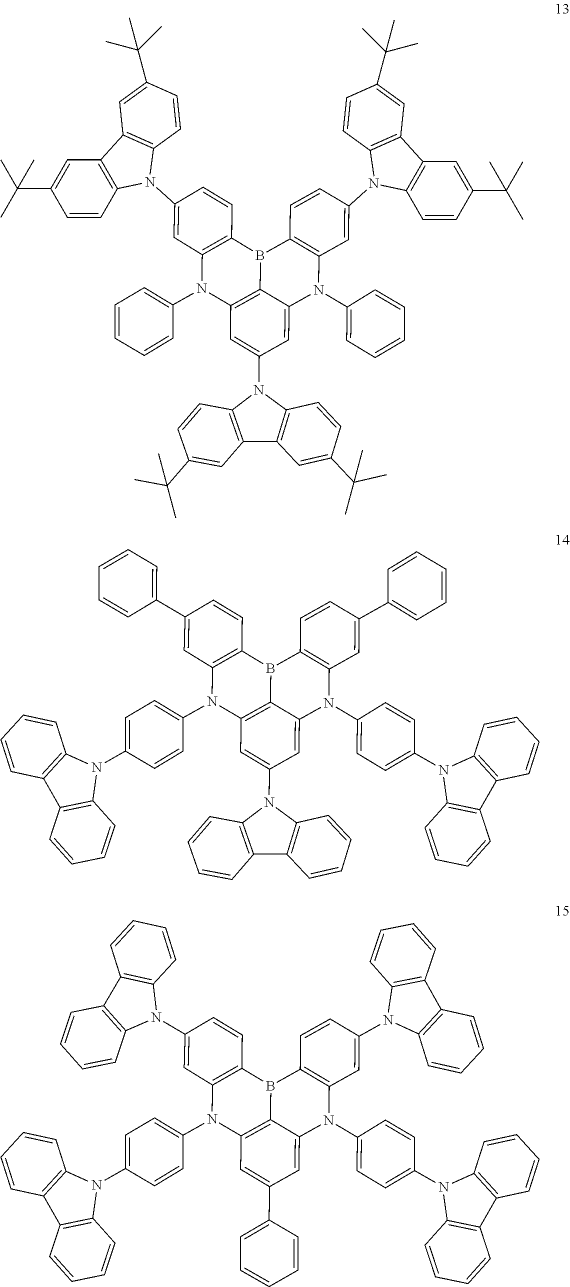 [SMILES: CC(C)(C)c1ccc2c(c1)c1cc(C(C)(C)C)ccc1n2-c1ccc2c(c1)N(c1ccccc1)c1cc(-n3c4ccc(C(C)(C)C)cc4c4cc(C(C)(C)C)ccc43)cc3c1B2c1ccc(-n2c4ccc(C(C)(C)C)cc4c4cc(C(C)(C)C)ccc42)cc1N3c1ccccc1 ; c1ccc(-c2ccc3c(c2)N(c2ccc(-n4c5ccccc5c5ccccc54)cc2)c2cc(-n4c5ccccc5c5ccccc54)cc4c2B3c2ccc(-c3ccccc3)cc2N4c2ccc(-n3c4ccccc4c4ccccc43)cc2)cc1 ; c1ccc(-c2cc3c4c(c2)N(c2ccc(-n5c6ccccc6c6ccccc65)cc2)c2cc(-n5c6ccccc6c6ccccc65)ccc2B4c2ccc(-n4c5ccccc5c5ccccc54)cc2N3c2ccc(-n3c4ccccc4c4ccccc43)cc2)cc1]

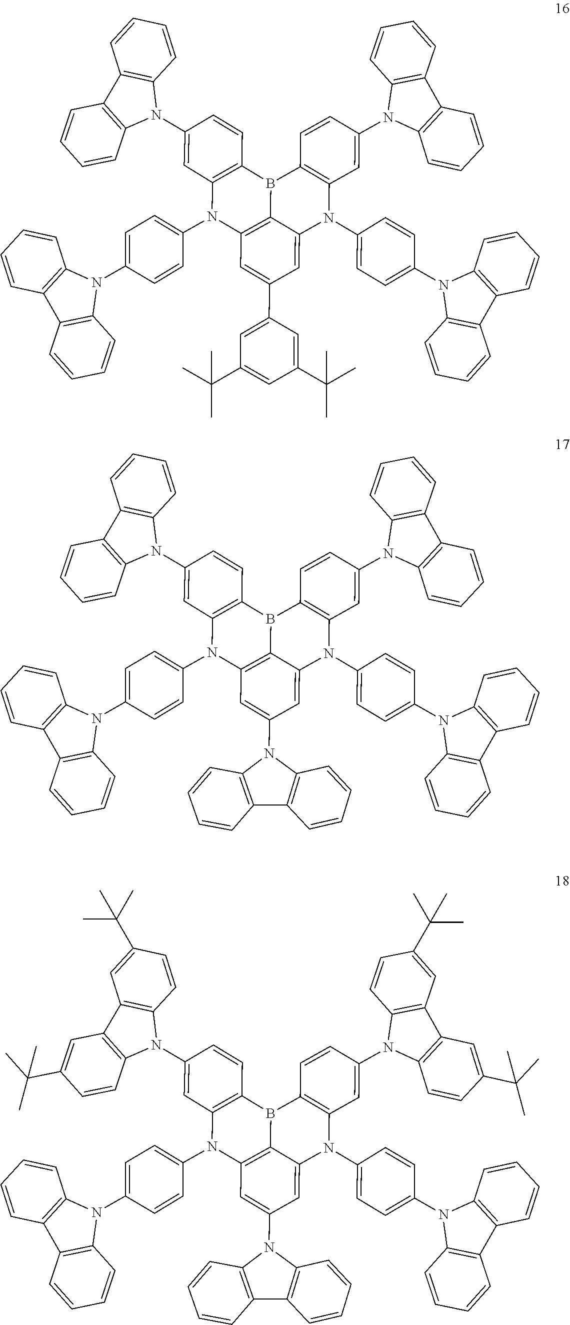

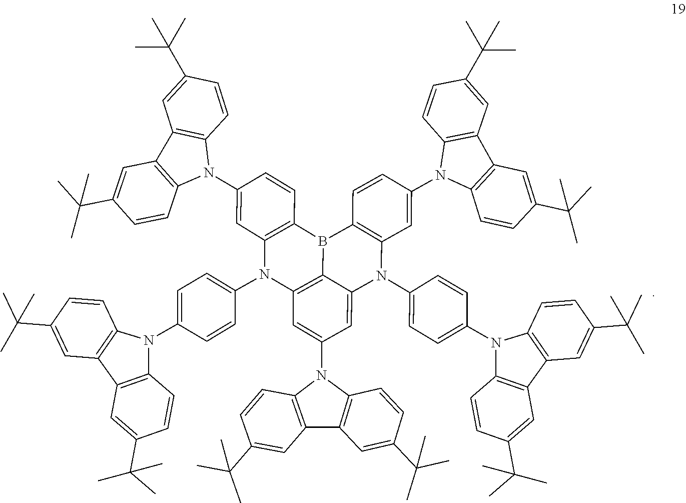 [SMILES: CC(C)(C)c1ccc2c(c1)c1cc(C(C)(C)C)ccc1n2-c1ccc(N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(-n5c6ccc(C(C)(C)C)cc6c6cc(C(C)(C)C)ccc65)cc4)c4cc(-n5c6ccc(C(C)(C)C)cc6c6cc(C(C)(C)C)ccc65)cc2c43)cc1]

In the light emitting element ED according to an embodiment, the emission layer EML including the delayed fluorescent dopant represented by Formula 1 may be to emit light of delayed fluorescence. The delayed fluorescent dopant according to an embodiment may be a multiple resonance (MR) type or kind delayed fluorescent dopant. For example, the emission layer EML may be to emit light of thermally activated delayed fluorescence (TADF).

The hole transporting host includes a carbazole derivative and may be represented by Formula HT-1. The emission layer EML may include a hole transporting host represented by Formula HT-1.

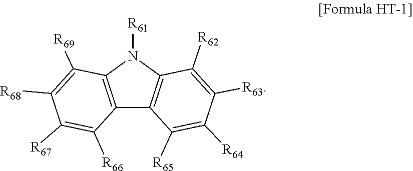

In Formula HT-1, one among R₆₁ to R₆₉ may include a substituted or unsubstituted carbazole group, and the rest among R₆₁ to R₆₉ may each independently be a hydrogen atom, a substituted or unsubstituted aryl group having 6 to 20 ring-forming carbon atoms, or a substituted or unsubstituted heteroaryl group having 2 to 20 ring-forming carbon atoms. Any one of R₆₁ to R₆₉ may be represented by a substituted or unsubstituted carbazole group, or may include a substituted or unsubstituted carbazole group as a substituent. For example, in Formula HT-1, R₆₁ may include a substituted carbazole group. In some embodiments, in Formula HT-1, R₆₄ may be an unsubstituted carbazole group.

The hole transporting host may include any one among compounds of Compound Group 2. The light emitting element ED of an embodiment may include any one among compounds of Compound Group 2.

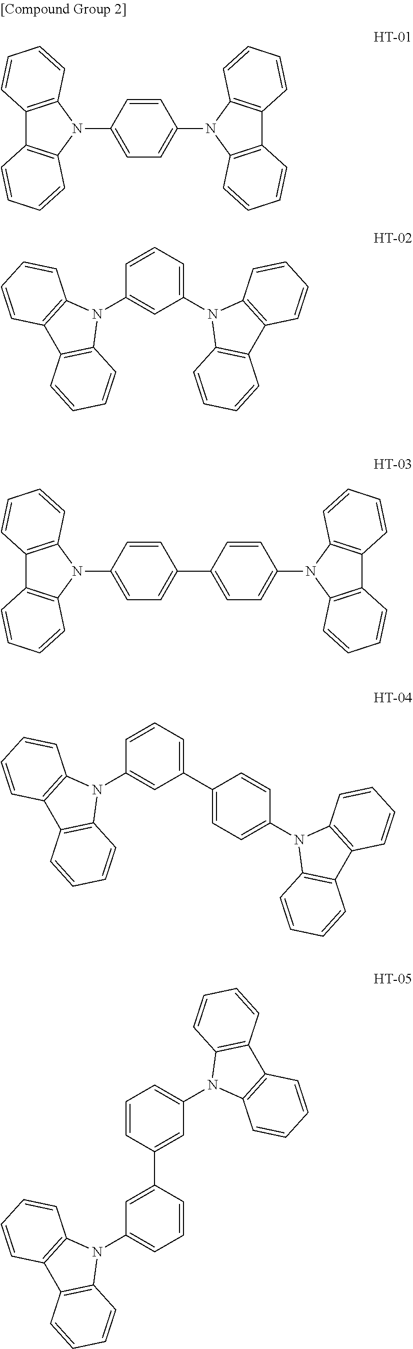 [SMILES: c1ccc2c(c1)c1ccccc1n2-c1ccc(-n2c3ccccc3c3ccccc32)cc1 ; c1cc(-n2c3ccccc3c3ccccc32)cc(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-c2ccc(-n3c4ccccc4c4ccccc43)cc2)cc(-n2c3ccccc3c3ccccc32)c1 ; c1cc(-c2cccc(-n3c4ccccc4c4ccccc43)c2)cc(-n2c3ccccc3c3ccccc32)c1]

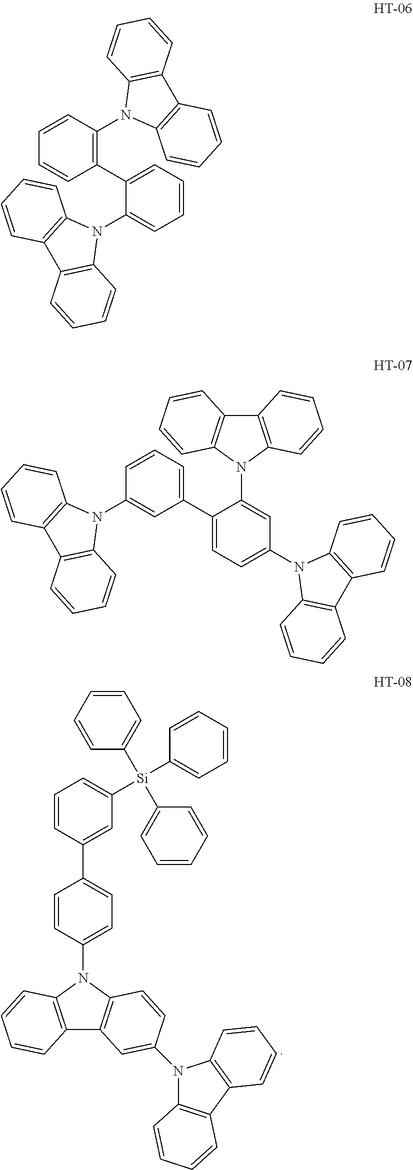 [SMILES: c1ccc(-n2c3ccccc3c3ccccc32)c(-c2ccccc2-n2c3ccccc3c3ccccc32)c1 ; c1cc(-c2ccc(-n3c4ccccc4c4ccccc43)cc2-n2c3ccccc3c3ccccc32)cc(-n2c3ccccc3c3ccccc32)c1 ; c1ccc([Si](c2ccccc2)(c2ccccc2)c2cccc(-c3ccc(-n4c5ccccc5c5cc(-n6c7ccccc7c7ccccc76)ccc54)cc3)c2)cc1]

In an embodiment, the electron transporting host may be represented by Formula ET-1. The emission layer EML may include the electron transporting host represented by Formula ET-1. The electron transporting host represented by Formula ET-1 may include a pyridine group, a pyrimidine group, or a triazine group.

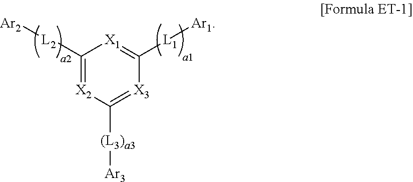

In Formula ET-1, at least one of X₁ to X₃ may be N and the rest of X₁ to X₃ may be CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

a1 to a3 may each independently be an integer of 0 to 10. When a1 is an integer of 2 or greater, a plurality of L₁'s may all be the same or at least one may be different from the others. When a2 is an integer of 2 or greater, a plurality of L₂'s may all be the same or at least one may be different from the others. When a3 is an integer of 2 or greater, a plurality of L₃'s may all be the same or at least one may be different from the others. L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms.

Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₁ to Ar₃ may each independently be a substituted or unsubstituted phenyl group or an unsubstituted carbazole group.

The electron transporting host may include any one among compounds of Compound Group 3. The light emitting element ED of an embodiment may include any one among compounds of Compound Group 3.

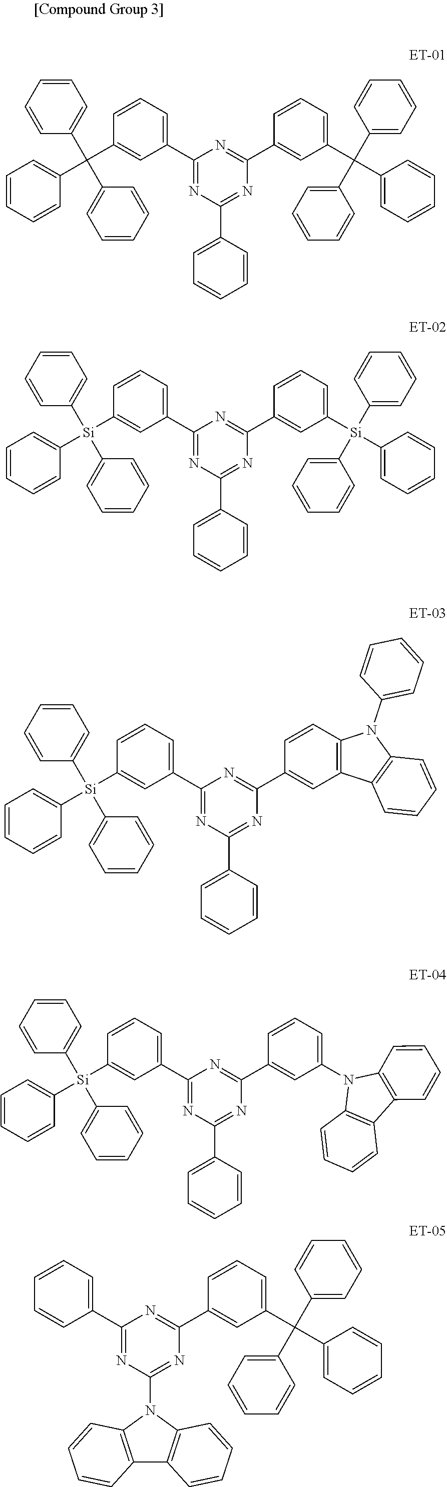

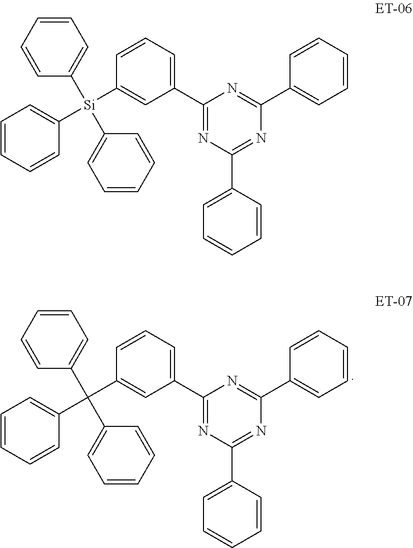 [SMILES: c1ccc(-c2nc(-c3ccccc3)nc(-c3cccc([Si](c4ccccc4)(c4ccccc4)c4ccccc4)c3)n2)cc1 ; c1ccc(-c2nc(-c3ccccc3)nc(-c3cccc(C(c4ccccc4)(c4ccccc4)c4ccccc4)c3)n2)cc1]

A phosphorescent sensitizer may be represented by Formula M-a. The emission layer EML may include the phosphorescent sensitizer represented by Formula M-a. Formula M-a indicates a metal complex containing iridium.

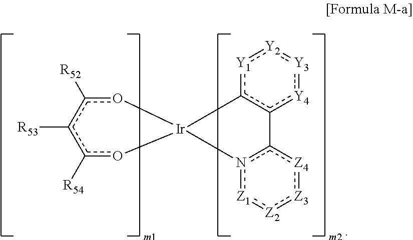

In Formula M-a, Y₁ to Y₄, and Z₁ to Z₄ may each independently be CR₅₁ or N. R₅₁ to R₅₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula M-a, m1 may be 0 or 1, and m2 may be 2 or 3. When m1 is 0, m2 may be 3, and when m1 is 1, m2 may be 2.

In some embodiments, the phosphorescent sensitizer may be represented by Formula M-b. The emission layer EML may include the phosphorescent sensitizer represented by Formula M-b. Formula M-b indicates a metal complex containing platinum.

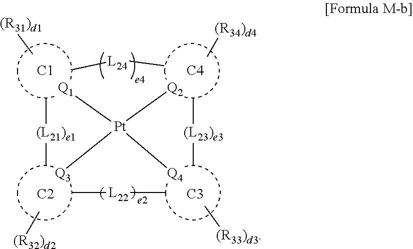

In Formula M-b, Q₁ to 04 may each independently be C or N. C1 to 04 may each independently be a substituted or unsubstituted hydrocarbon ring having 5 to 30 ring-forming carbon atoms, or a substituted or unsubstituted heterocycle having 2 to 30 ring-forming carbon atoms.

e1 to e4 may each independently be 0 or 1. L₂₁ to L₂₄ may each independently be a direct linkage,

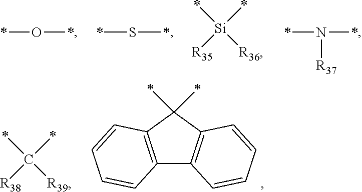

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

d1 to d4 may each independently be an integer of 0 to 4. When d1 is an integer of 2 or greater, a plurality of R₃₁'s may all be the same or at least one may be different from the others. When d2 is an integer of 2 or greater, a plurality of R₃₂'s may all be the same or at least one may be different from the others. When d3 is an integer of 2 or greater, a plurality of R₃₃'s may all be the same or at least one may be different from the others. When d4 is an integer of 2 or greater, a plurality of R₃₄'s may all be the same or at least one may be different from the others.

R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

The phosphorescent sensitizer may include any one among compounds of Compound Group 4 or Compound Group 5. The light emitting element ED of an embodiment may include any one among compounds of Compound Group 4 or Compound Group 5.

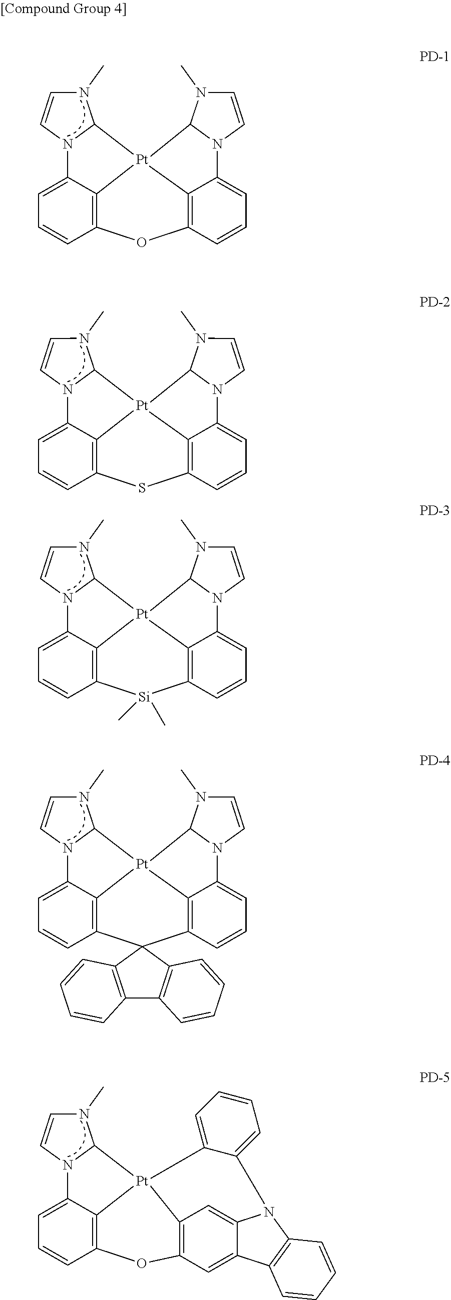

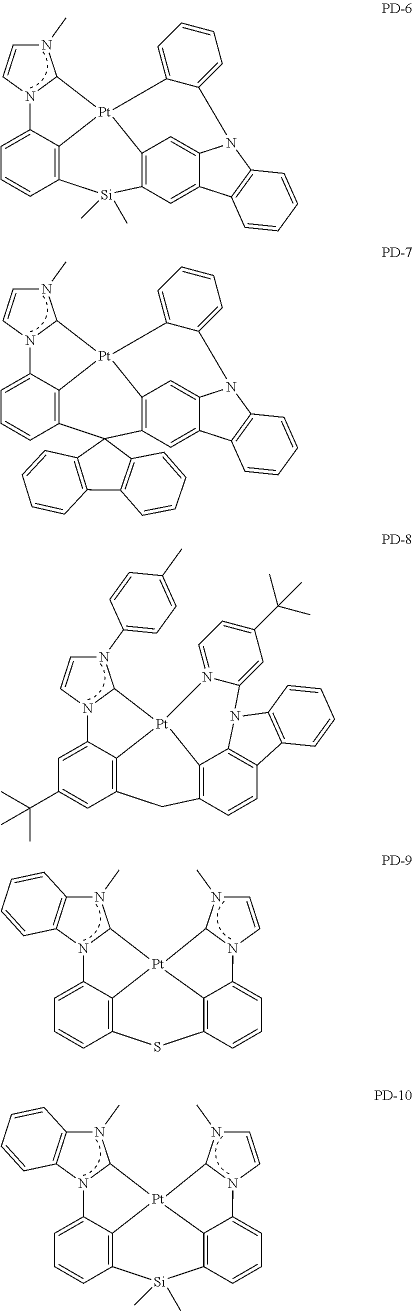

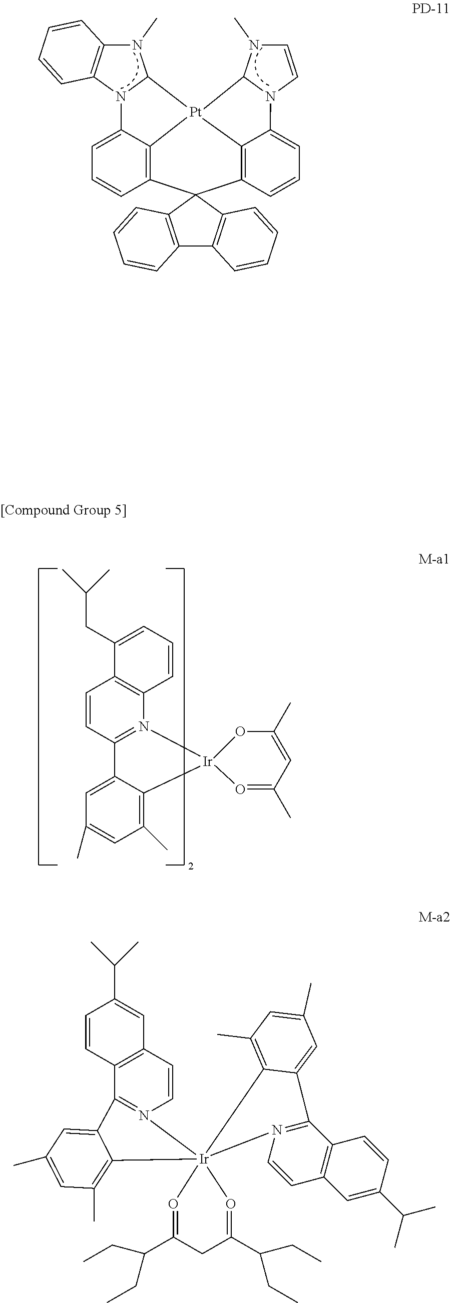

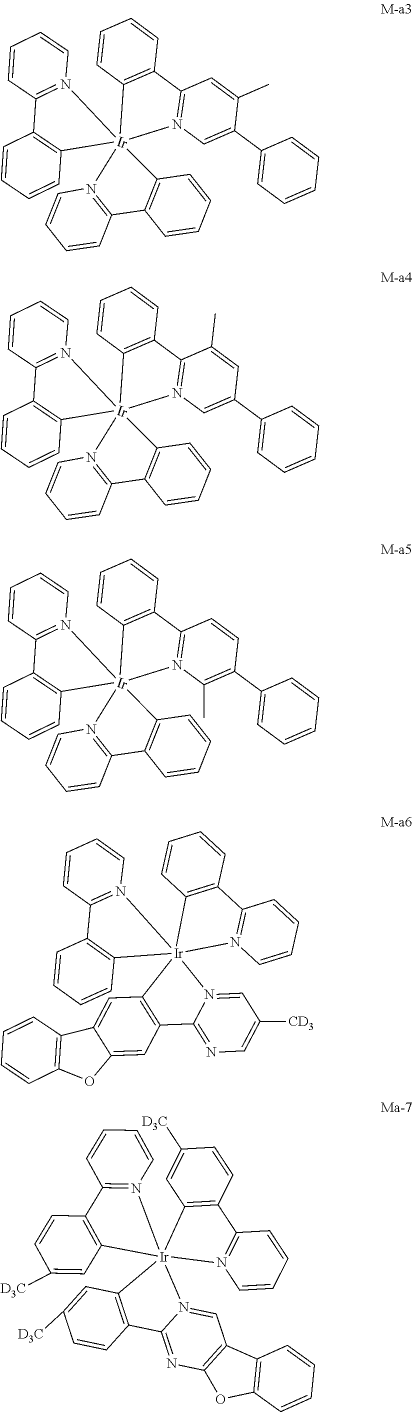

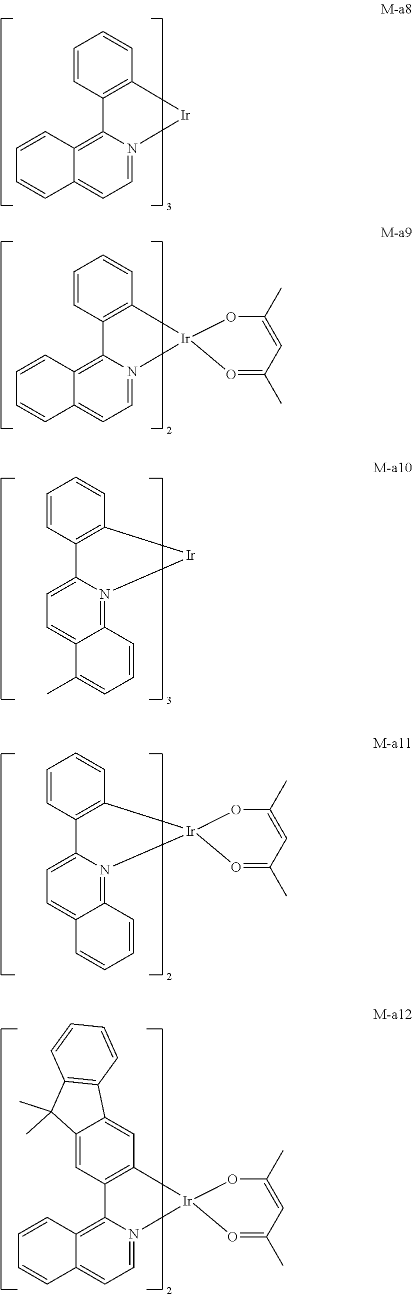

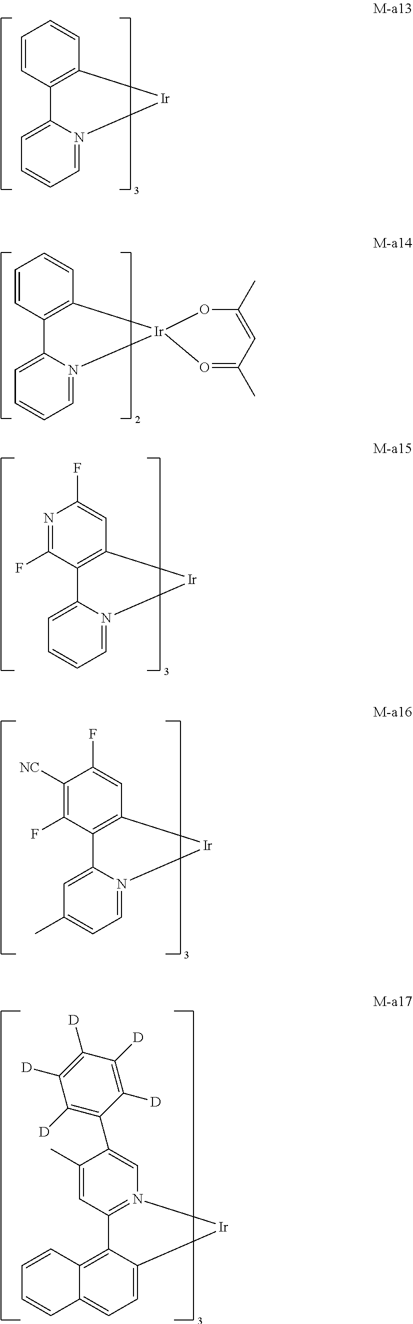

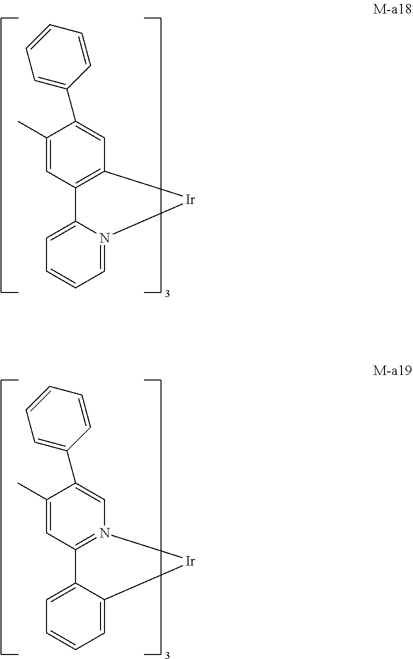

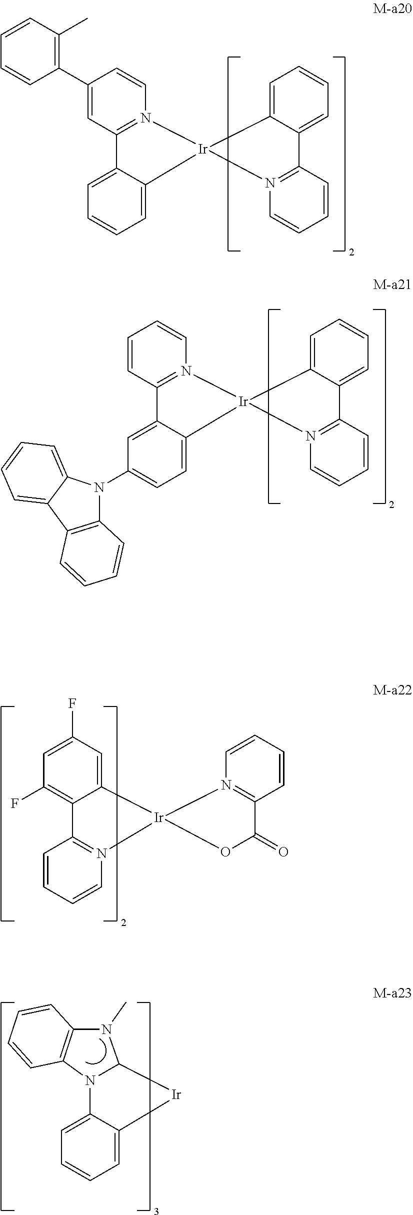

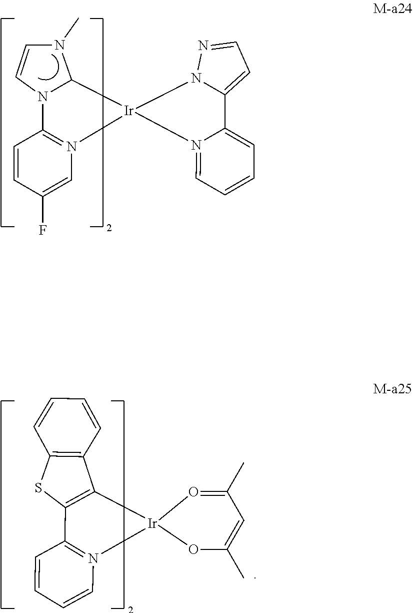

In the emission layer EML, the hole transporting host and the electron transporting host may form an exciplex. Energy may be transferred from the exciplex to the phosphorescent photosensitizer, and energy may be transferred from the phosphorescent photosensitizer to the delayed fluorescent dopant, thereby emitting light.

The exciplex formed by the hole transporting host and the electron transporting host has a triplet state energy which is different from the triplet state energy level of the hole transporting host and the electron transporting host, and may have a new triplet state energy level. The triplet state energy of the exciplex formed by the hole transporting host and the electron transporting host corresponds to a difference between the Lowest Unoccupied Molecular Orbital (LUMO) energy level of the electron transporting host and the HOMO energy level of the hole transporting host.

For example, the exciplex formed by the hole transporting host and the electron transporting host in a light emitting element may have an absolute value of about 2.4 eV to about 3.0 eV in the triplet state energy level. In some embodiments, the triplet state energy of the exciplex may have a value smaller than the energy gap of each host material. The energy gap may be a difference between the LUMO energy level and the HOMO energy level. For example, the hole transporting host and the electron transporting host may each have an energy gap of about 3.0 eV or greater, and the exciplex may have a triplet state energy level of about 3.0 eV or less. However, this is presented as an example, and the triplet state energy level of the exciplex is not limited thereto.

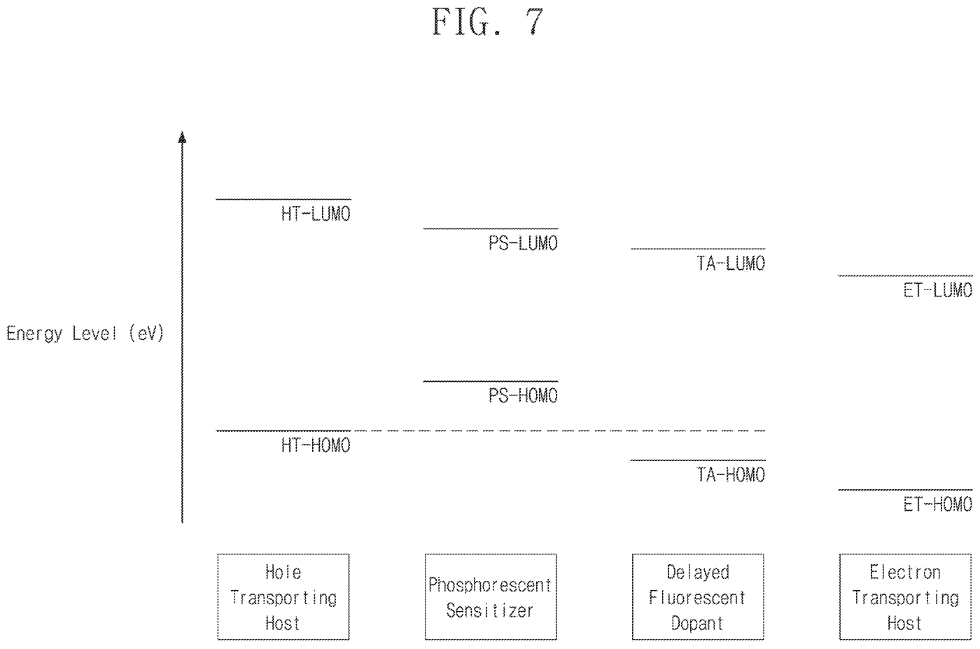

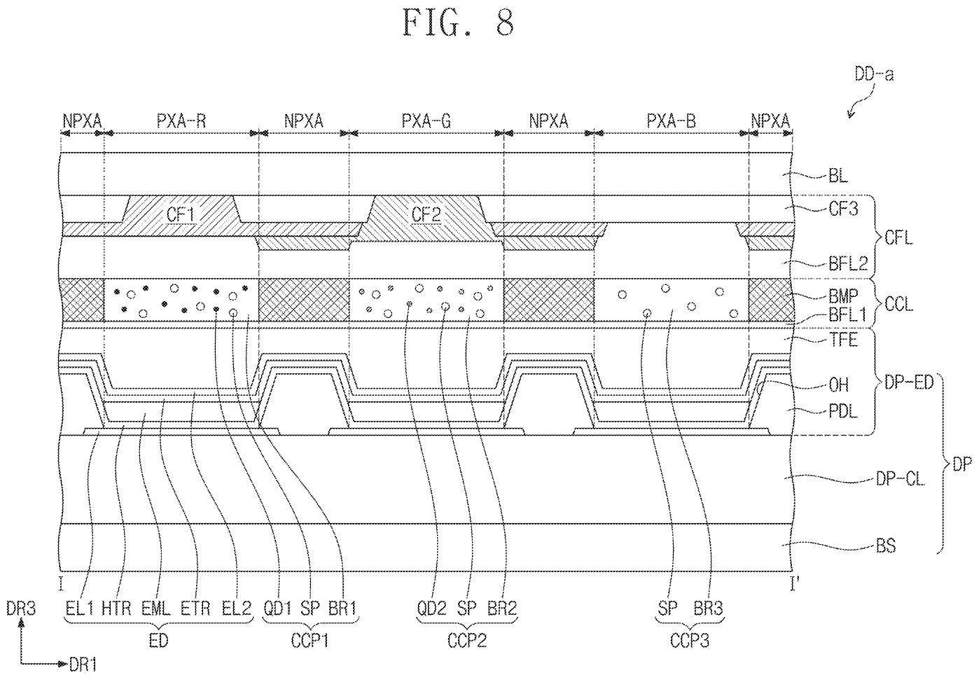

FIG. 7 is an energy diagram showing the HOMO energy level and the LUMO energy level for each of a hole transporting host, an electron transporting host, a phosphorescent sensitizer, and a delayed fluorescent dopant. In FIG. 7, the values of the HOMO energy level and the LUMO energy level are negative numbers.

In an embodiment, the delayed fluorescent dopant may have an absolute value of the HOMO energy level TA-HOMO greater than an absolute value of the HOMO energy level HT-HOMO of the hole transporting host. In some embodiments, the phosphorescent sensitizer may have an absolute value of the HOMO energy level PS-HOMO lower than an absolute value of the HOMO energy level HT-HOMO of the hole transporting host and lower than an absolute value of the HOMO energy level TA-HOMO of the delayed fluorescent dopant TA-HOMO.

For example, a difference between the absolute value of the HOMO energy level TA-HOMO of the delayed fluorescent dopant and the absolute value of the HOMO energy level HT-HOMO of the hole transporting host may be about 0.05 eV to about 0.22 eV. However, this is presented as an example, and the embodiment of the present disclosure is not limited thereto.

Referring to FIG. 7, the HOMO energy level TA-HOMO of the delayed fluorescent dopant may be positioned below the HOMO energy level HT-HOMO of the hole transporting host. The HOMO energy level PS-HOMO of the phosphorescent sensitizer may be positioned above the HOMO energy level TA-HOMO of the delayed fluorescent dopant and above the HOMO energy level HT-HOMO of the hole transporting host. The HOMO energy level ET-HOMO of the electron transporting host may be positioned below the HOMO energy level TA-HOMO of the delayed fluorescent dopant.

The LUMO energy level PS-LUMO of the phosphorescent sensitizer may be positioned below the LUMO energy level HT-LUMO of the hole transporting host. The LUMO energy level TA-LUMO of the delayed fluorescent dopant may be positioned below the LUMO energy level PS-LUMO of the phosphorescent sensitizer. The LUMO energy level ET-LUMO of the electron transporting host may be positioned below the LUMO energy level TA-LUMO of the delayed fluorescent dopant. For example, the absolute value of the LUMO energy level may increase in the order of the hole transporting host, the phosphorescent sensitizer, the delayed fluorescent dopant, and the electron transporting host. However, this is presented as an example, and the LUMO energy level for each of the hole transporting host, the phosphorescent sensitizer, the delayed fluorescent dopant, and the electron transporting host is not limited thereto.

A light emitting element ED including a hole transporting host, an electron transporting host, a phosphorescent sensitizer, and a delayed fluorescent dopant may exhibit a satisfactory current flow compared to a light emitting element including a hole transporting host, an electron transporting host, and a phosphorescent sensitizer but without a delayed fluorescent dopant. The light emitting element ED including the delayed fluorescent dopant according to an embodiment may exhibit a satisfactory current value compared to the light emitting element with no delayed fluorescent dopant. The light emitting element ED may satisfy Expression A-1.

E_{I}≥C_{I}×0.9 [Expression A-1]

In Expression A-1, E_{I} is a current value at a driving voltage of 7.5 V of a first hole only device (HOD) including a hole transporting host, an electron transporting host, and a first emission layer containing a delayed fluorescent dopant, and C_{I} is a current value at a driving voltage of 7.5 V of a second hole only device (HOD) including a hole transporting host, an electron transporting host, and a second emission layer free of the delayed fluorescent dopant. That is, the first hole only device and the second hole only device may differ only in whether the delayed fluorescent dopant is included, and the rest of the components may be the same.

The hole only device HOD is for measuring the extent of current flow depending on whether a delayed fluorescent dopant is included, and may include two hole transport regions. One of the two hole transport regions may be disposed between the first electrode EL1 and the emission layer, and the other hole transport region may be disposed between the emission layer and the second electrode EL2. Each of the two hole transport regions may include a hole injection layer HIL and a hole transport layer HTL. In the hole only device, the hole injection layer may be disposed adjacent to the first electrode EL1 or the second electrode EL2, and the hole transport layer may be disposed adjacent to the emission layer.

The first hole only device may include the first electrode, the second electrode disposed on the first electrode, a first emission layer disposed between the first electrode and the second electrode, a first hole transport region disposed between the first electrode and the first emission layer, and a second hole transport region disposed between the first emission layer and the second electrode. The first emission layer may include a hole transporting host, an electron transporting host, and a delayed fluorescent dopant according to an embodiment.

A second hole only device may include the first electrode, the second electrode disposed on the first electrode, a second emission layer disposed between the first electrode and the second electrode, a first hole transport region disposed between the first electrode and the second emission layer, and a second hole transport region disposed between the second emission layer and the second electrode. The second emission layer may include a hole transporting host and an electron transporting host, and may not include (e.g., may exclude) a delayed fluorescent dopant.

According to Expression A-1, the current value of the first hole only device including the delayed fluorescent dopant may be 90% or greater of the current value of the second hole only device without a delayed fluorescent dopant. Accordingly, the light emitting element ED according to an embodiment including a delayed fluorescent dopant having low hole trapping properties may exhibit active current flow.

In an embodiment, the emission layer EML may include a hole transporting host, an electron transporting host, a phosphorescent sensitizer, and a delayed fluorescent dopant. The delayed fluorescent dopant may include two or more substituted or unsubstituted carbazole groups. The delayed fluorescent dopant including two or more carbazole groups may exhibit reduced hole trapping properties. In some embodiments, the delayed fluorescent dopant including two or more carbazole groups may have a greater absolute value of the HOMO energy level than the hole transporting host. Accordingly, direct recombination in the delayed fluorescent dopant may be reduced, triplet exciton formation may be prevented or reduced, and thus, the delayed fluorescent dopant may be less deteriorated. Accordingly, the light emitting element ED including the delayed fluorescent dopant according to an embodiment may exhibit long lifespan.

The emission layer EML may have, for example, a thickness of about 100 Å to about 1000 Å or about 100 Å to about 300 Å. The emission layer EML may have a single layer formed of a single material, a single layer formed of a plurality of different materials, or a multilayer structure having a plurality of layers formed of a plurality of different materials.

The emission layer EML may include an anthracene derivative, a pyrene derivative, a fluoranthene derivative, a chrysene derivative, a dihydrobenzanthracene derivative, or a triphenylene derivative. In some embodiments, the emission layer EML may include an anthracene derivative or a pyrene derivative.

The emission layer EML may include a compound represented by Formula E-1. The compound represented by Formula E-1 may be utilized as a fluorescent host material.

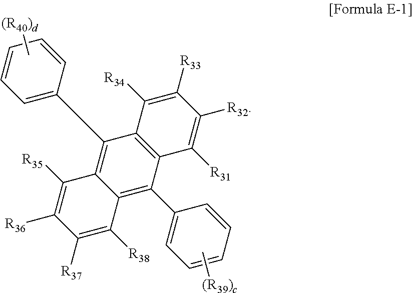

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

Formula E-1 may be represented by any one among compounds E1 to E19.

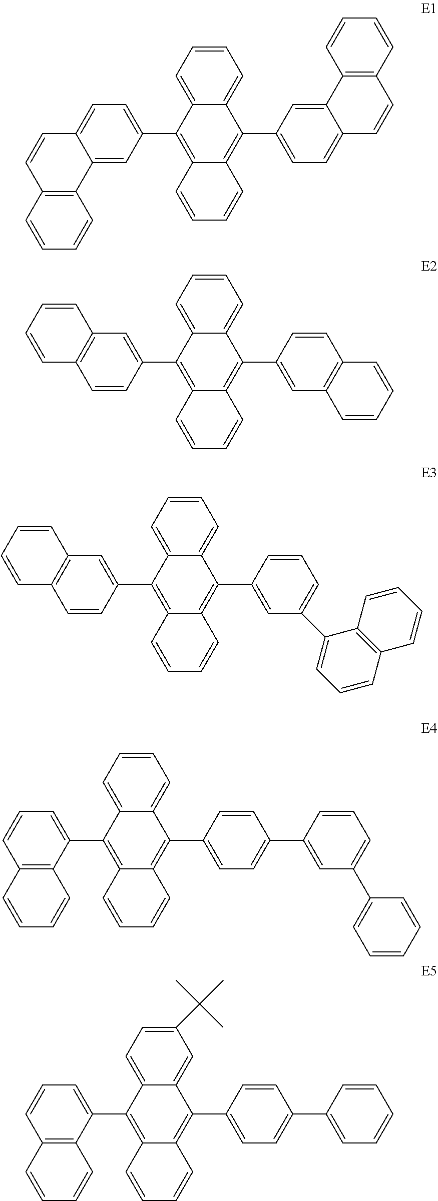

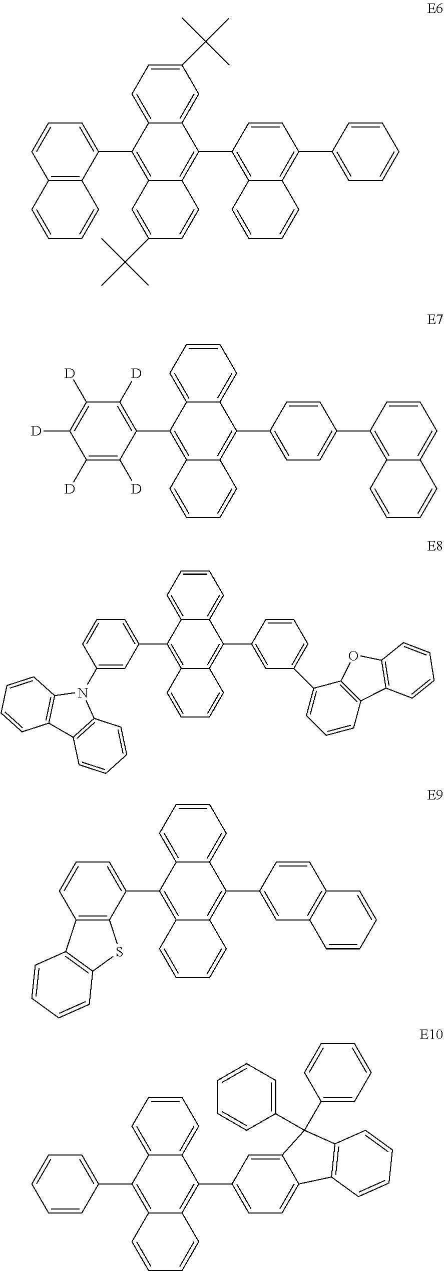

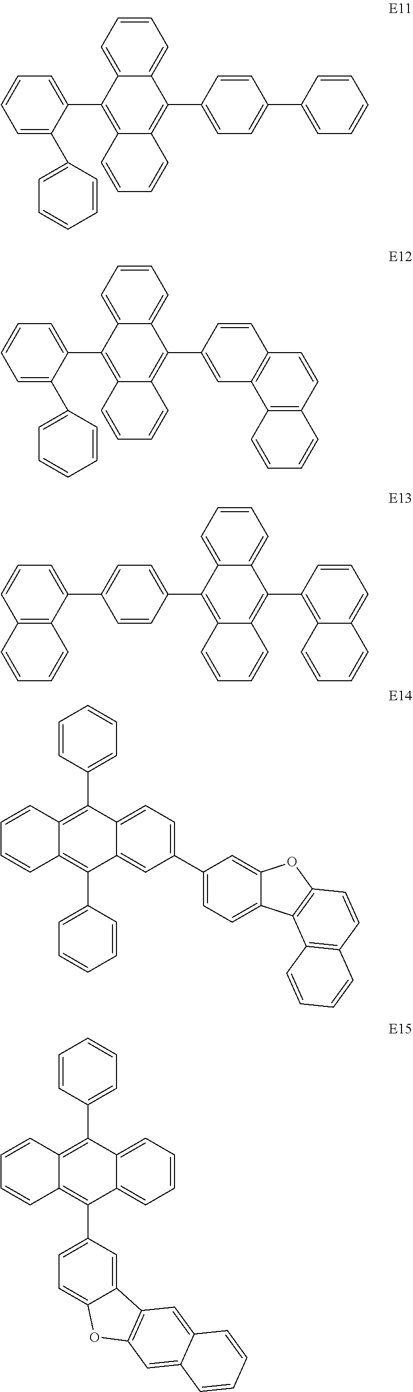

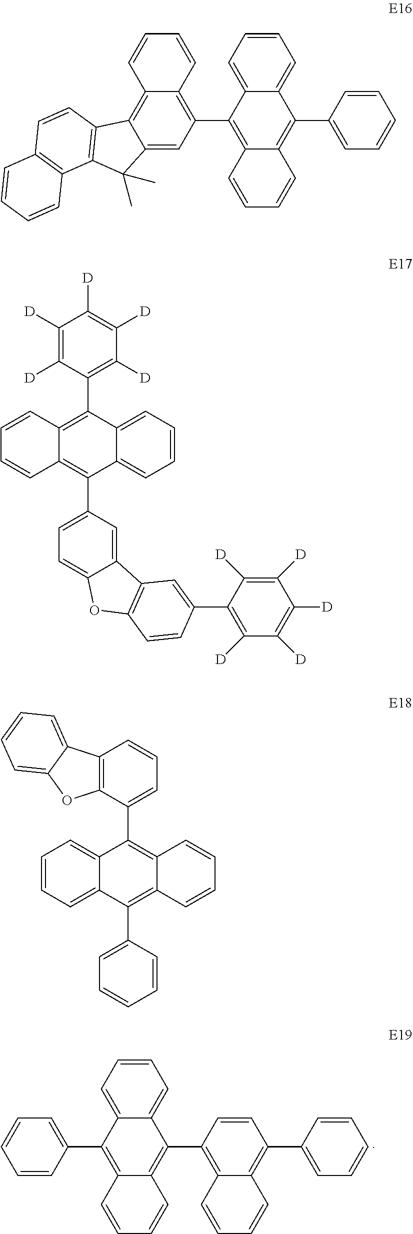

In an embodiment, the emission layer EML may include a compound represented by Formula E-2a or Formula E-2b. The compound represented by Formula E-2a or Formula E-2b may be utilized as a phosphorescent host material.

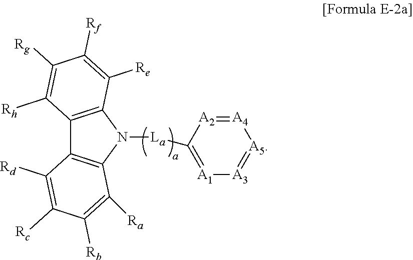

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. When a is an integer of 2 or greater, a plurality of La's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. Rₐ to Rᵢ may be bonded to an adjacent group to form a hydrocarbon ring or a heterocycle containing N, O, S, etc. as a ring-forming atom.

In Formula E-2a, two or three selected from A₁ to A₅ may be N, and the rest may be CRᵢ.

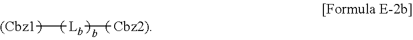

In Formula E-2b, Cbz1 and Cbz2 may each independently be an unsubstituted carbazole group or an aryl-substituted carbazole group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms, b may be an integer of 0 to 10, and when b is an integer of 2 or greater, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one of compounds from Compound Group E-2. However, the compounds listed in Compound Group E-2 are presented as an example, and the compound represented by Formula E-2a or Formula E-2b is not limited to those listed in Compound Group E-2.

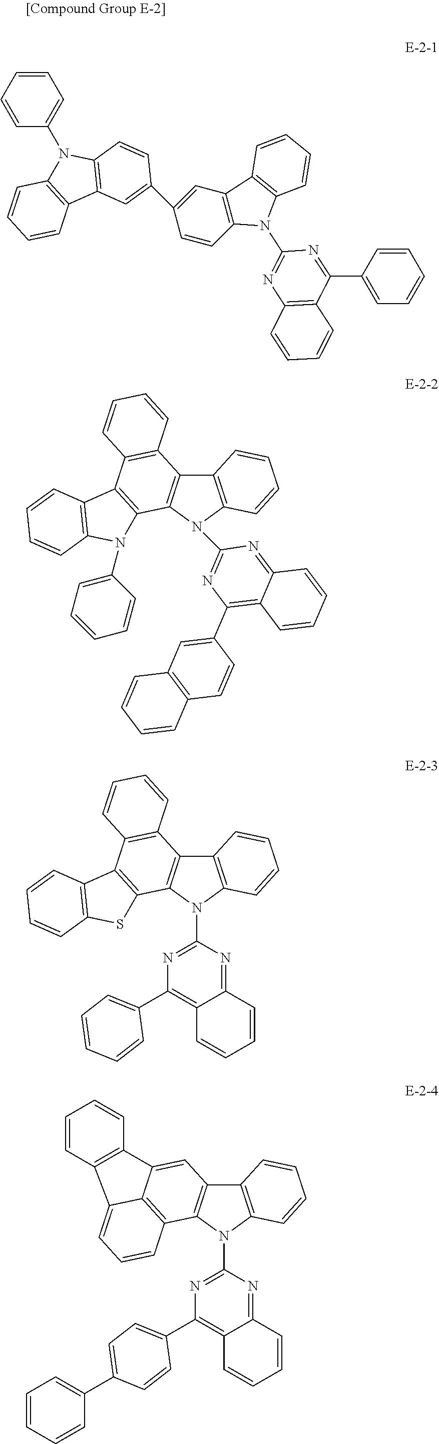

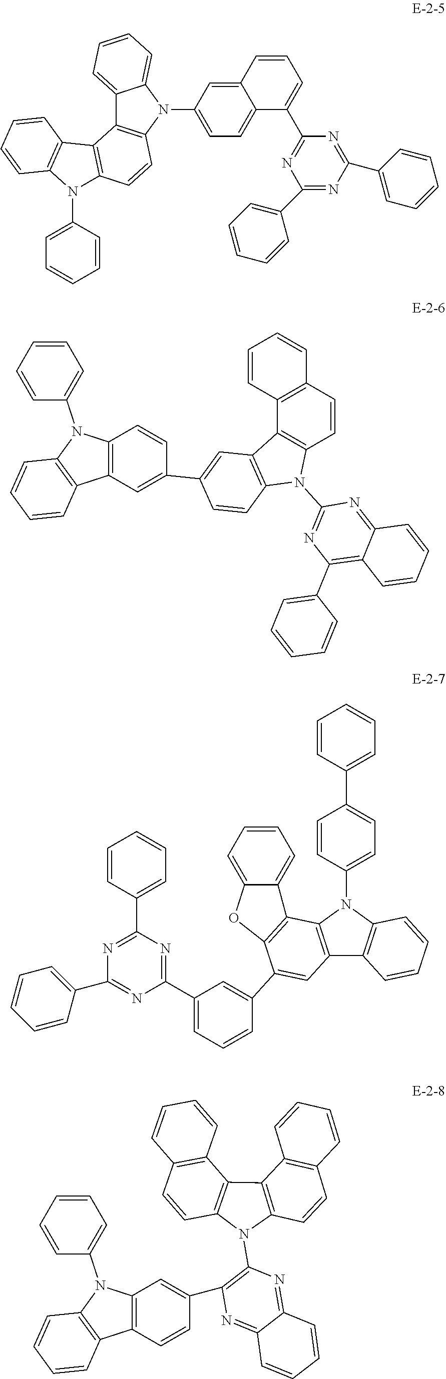 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

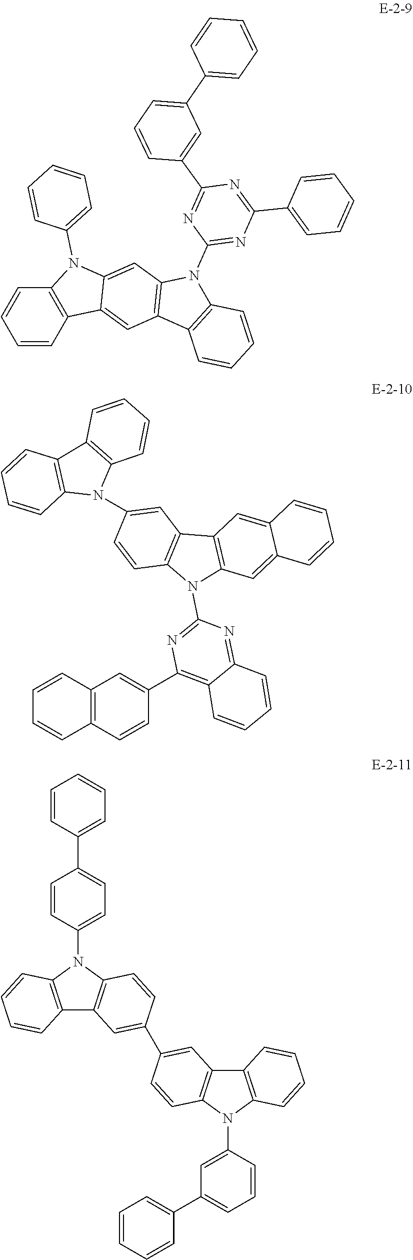

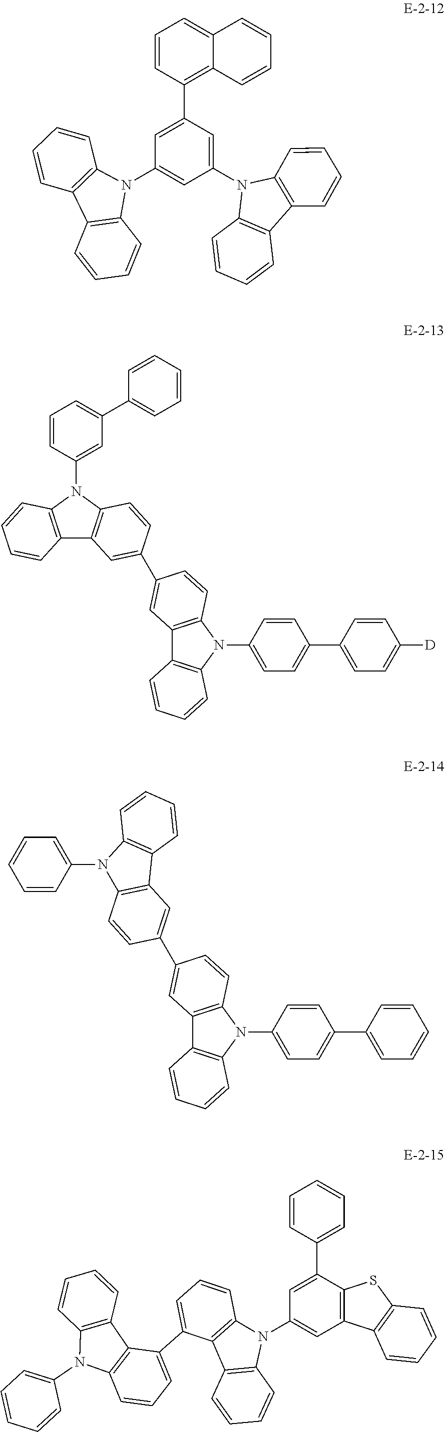

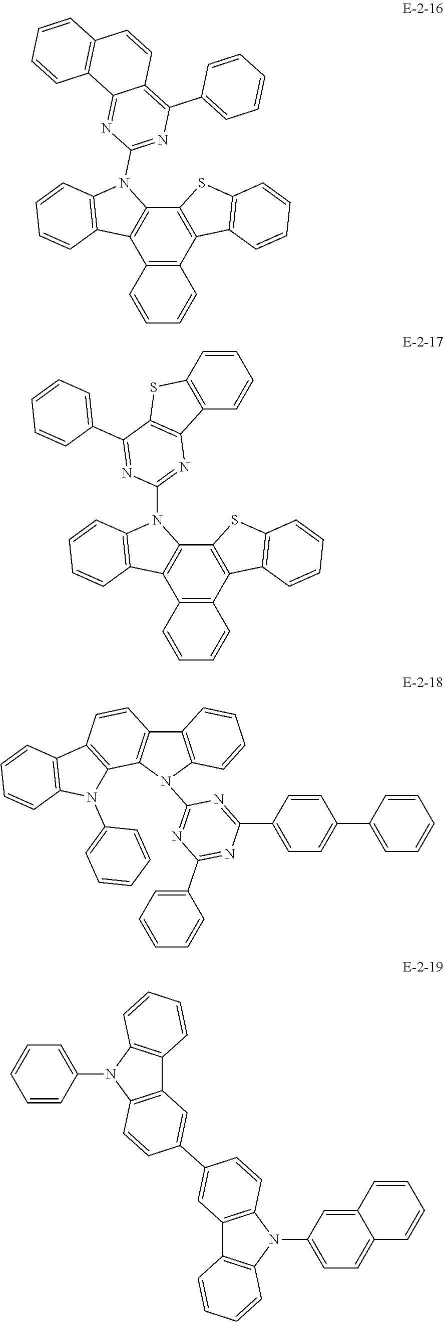

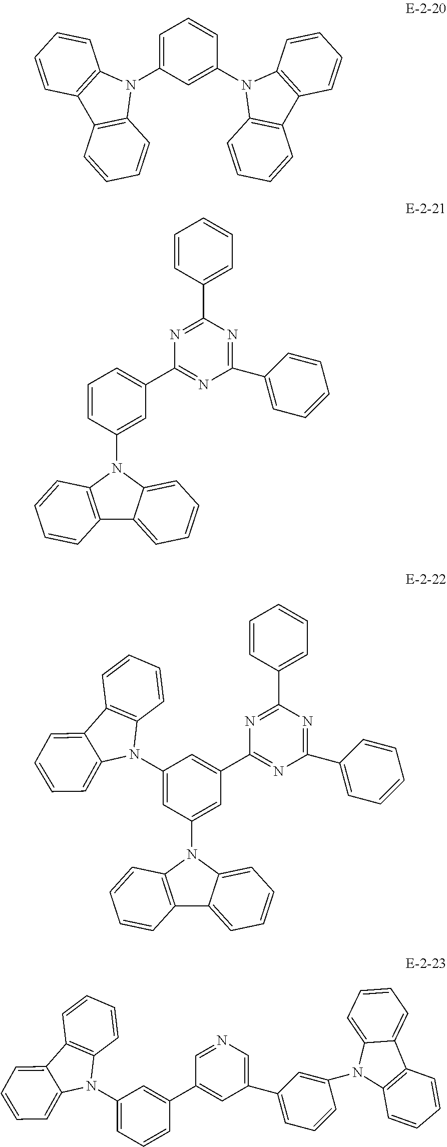 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

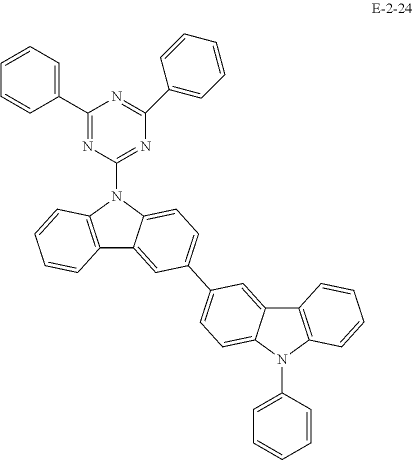 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one among bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazolyl-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi).

However, the embodiment of the present disclosure is not limited thereto, and for example, tris(8-hydroxyquinolino)aluminum (Alq₃), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be utilized as a host material.

The emission layer EML may include a compound represented by any one of Formulas F-a or F-b. The compounds represented by Formulas F-a or F-b may be utilized as a fluorescent dopant material.

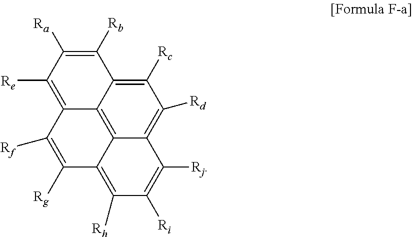

In Formula F-a above, two selected from Rₐ to Rⱼ may each independently be substituted with *—NAr₁Ar₂. The rest of Rₐ to Rⱼ which are not substituted with *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

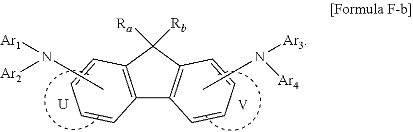

In Formula F-b above, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, In Formula F-b, when the number of U or V is 1, one ring forms a fused ring at the designated part (e.g., a portion indicated by U or V), and when the number of U or V is 0, it refers to that a ring indicated by U or V does not exist. For example, when the number of U is 0 and the number of V is 1, or when the number of U is 1 and the number of V is 0, a fused ring having a fluorene core of Formula F-b may be a cyclic compound having four rings. In some embodiments, when both (e.g., simultaneously) U and V are 0, the fused ring of Formula F-b may be a cyclic compound having three rings. In some embodiments, when both (e.g., simultaneously) U and V are 1, the fused ring having a fluorene core of Formula F-b may be a cyclic compound having five rings.

The emission layer EML may include, as a suitable dopant material, one or more styryl derivatives (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and/or N-(4-((E)-2-(6-((E)-4-(diphenylamino)styryl)naphthalen-2-yl)vinyl)phenyl)-N-phenylbenzenamine (N-BDAVBi)), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), etc.

The emission layer EML may include a suitable phosphorescent dopant material. For example, as a phosphorescent dopant, a metal complex including iridium (Ir), platinum (Pt), osmium (Os), gold (Au), titanium (Ti), zirconium (Zr), hafnium (Hf), europium (Eu), terbium (Tb), and/or thulium (Tm) may be utilized. In some embodiments, iridium(III) bis(4,6-difluorophenylpyridinato-N,C2′)picolinate (Firpic), bis(2,4-difluorophenylpyridinato)-tetrakis(1-pyrazolyl)borate iridium(III) (Fir6), platinum octaethyl porphyrin (PtOEP), etc. may be utilized as a phosphorescent dopant. However, the embodiment of the present disclosure is not limited thereto.

Referring back to FIGS. 3 to 6, the first electrode EL1 has conductivity (e.g., is a conductor). The first electrode EL1 may be formed of a metal material, a metal alloy or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode may include at least one selected from Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, or an oxide thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof (e.g., a mixture of Ag and Mg). In some embodiments, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the first electrode EL1 may have a three-layer structure of ITO/Ag/ITO, but the present disclosure is not limited thereto. In some embodiments, the embodiment of the present disclosure is not limited thereto, and the first electrode EL1 may include the above-described metal materials, a combination of two or more metal materials selected from the above-described metal materials, or oxides of the above-described metal materials. The first electrode EL1 may have a thickness of about 700 Å to about 10000 Å. For example, the first electrode EL1 may have a thickness of 1000 Å to about 3000 Å.

The hole transport region HTR is provided on the first electrode EL1. The hole transport region HTR may include at least one among a hole injection layer HIL, a hole transport layer HTL, a buffer layer, a light emitting auxiliary layer, and an electron blocking layer EBL. The hole transport region HTR may have, for example, a thickness of about 50 Å to about 15000 Å.

The hole transport region HTR may have a single layer formed of a single material, a single layer formed of a plurality of different materials, or a multilayer structure having a plurality of layers formed of a plurality of different materials.

For example, the hole transport region HTR may have a single-layer structure formed of the hole injection layer HIL or the hole transport layer HTL, or a single-layer structure formed of a hole injection material or a hole transport material. For example, the hole transport region HTR may have a single-layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include the hole transporting host according to an embodiment. For example, the hole transport region HTR may include a hole transporting host represented by Formula HT-1.

The hole transport region HTR may include any one among compounds of Compound Group HR. For example, the hole transport region HTR may include any one among compounds of Compound Group HR in the hole transport layer HTL.

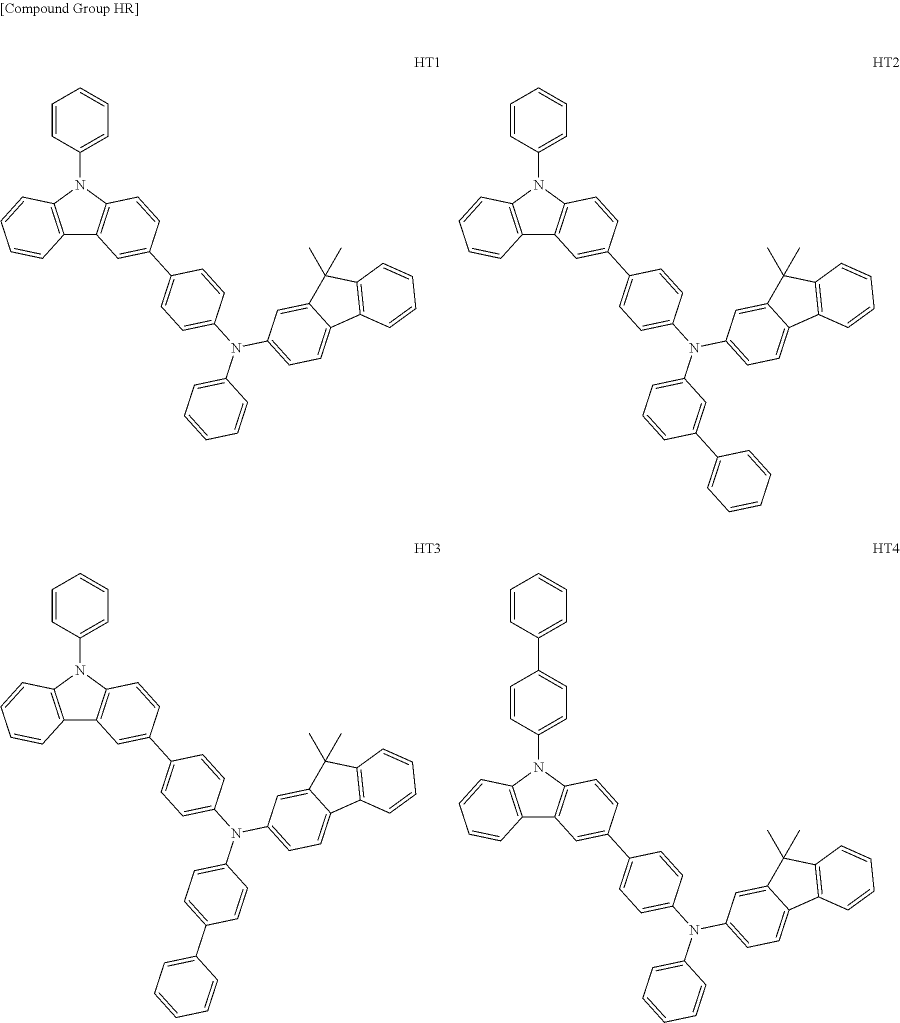

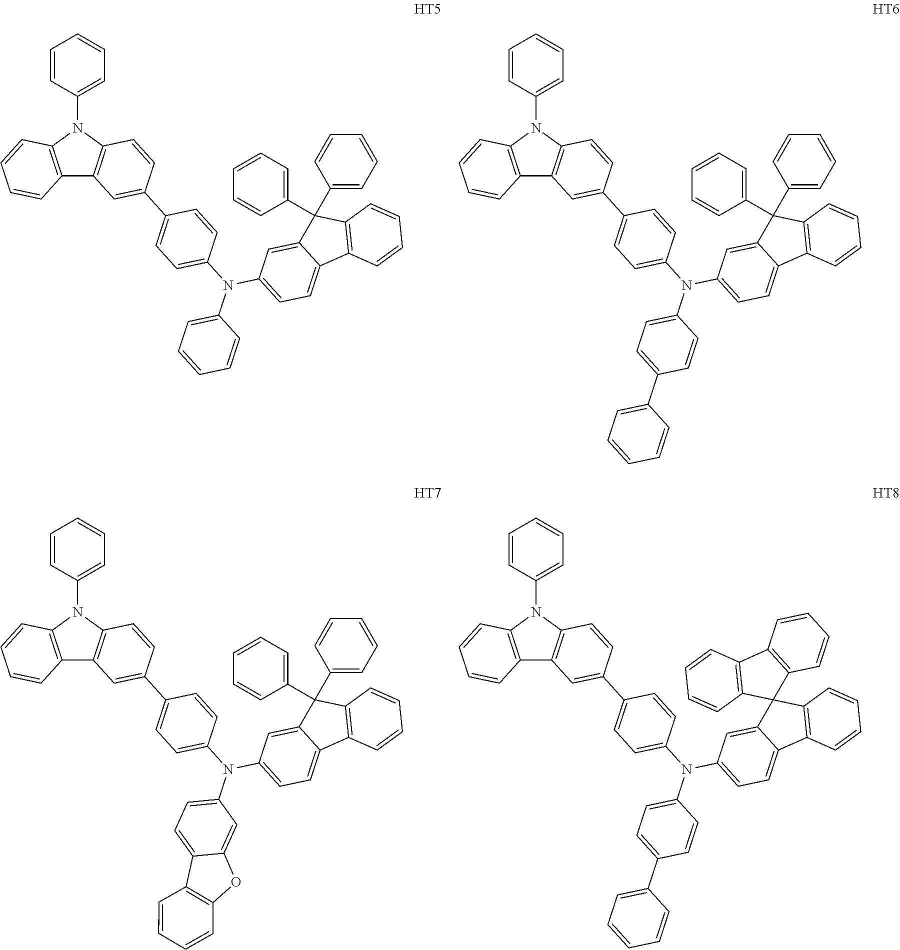 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

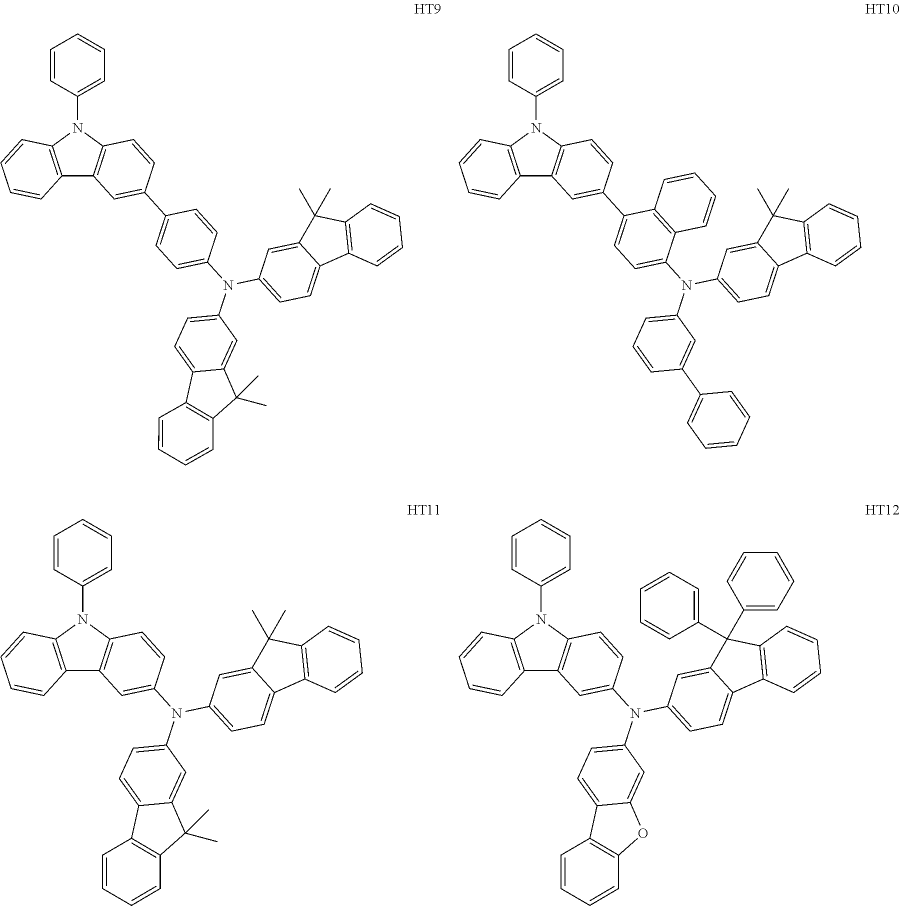 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

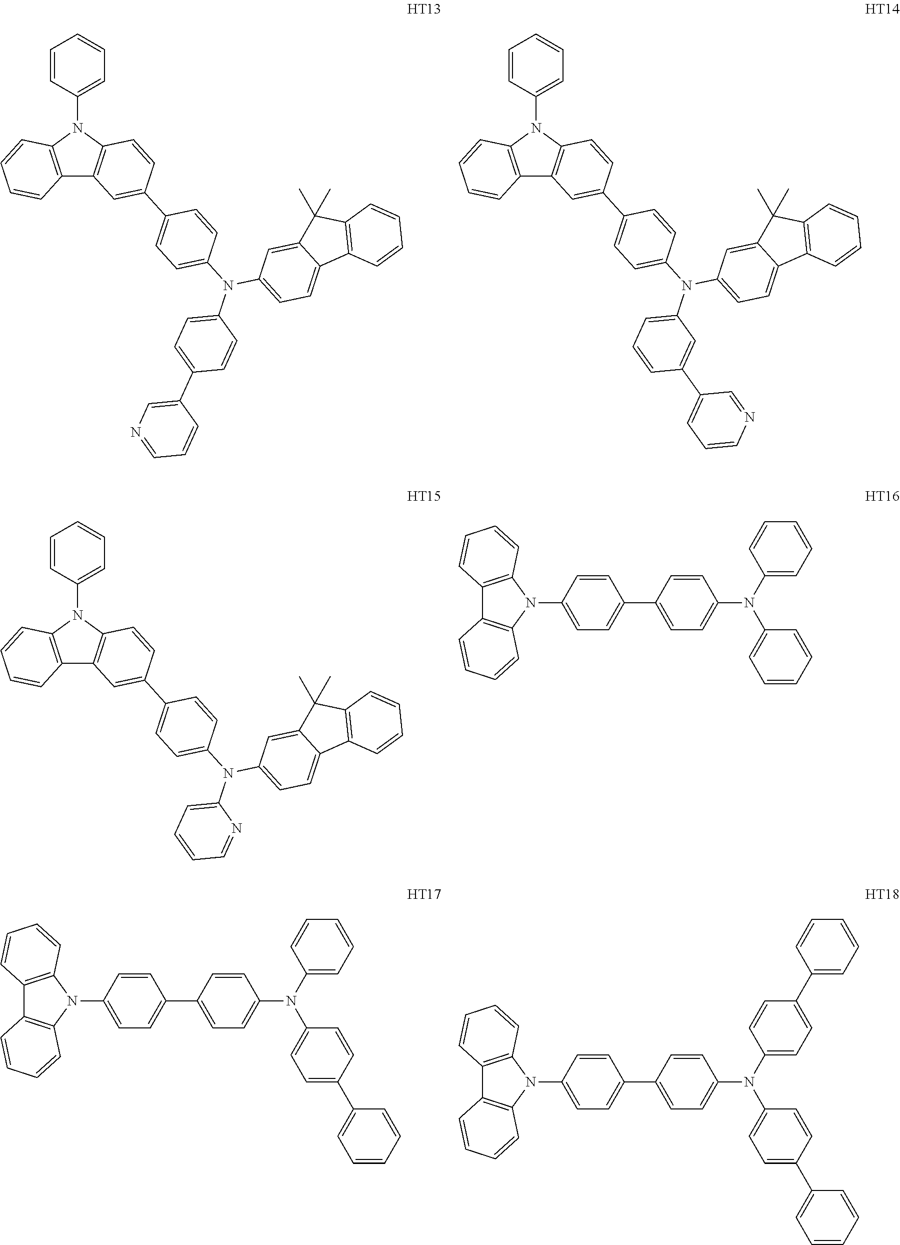 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

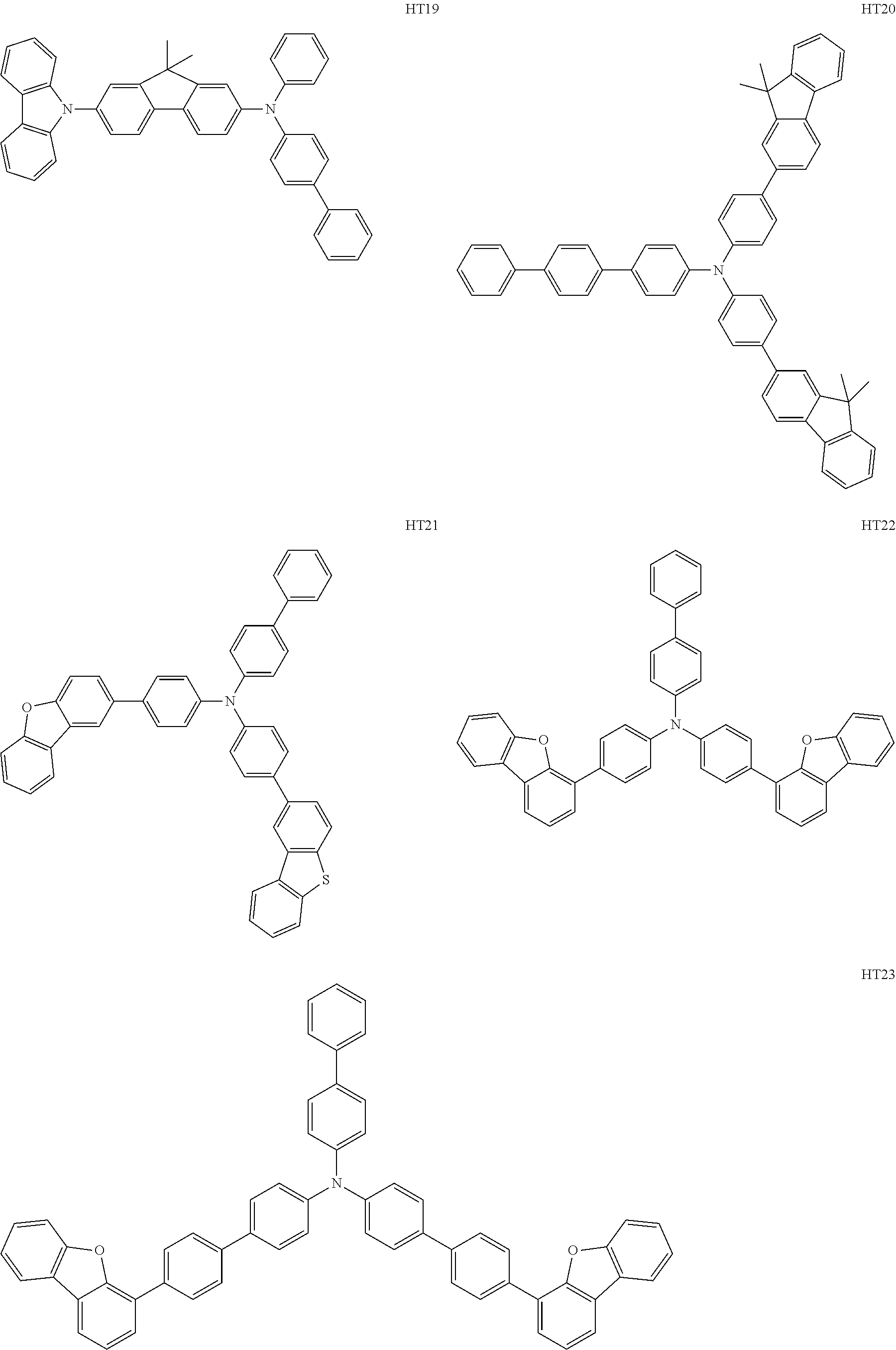 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

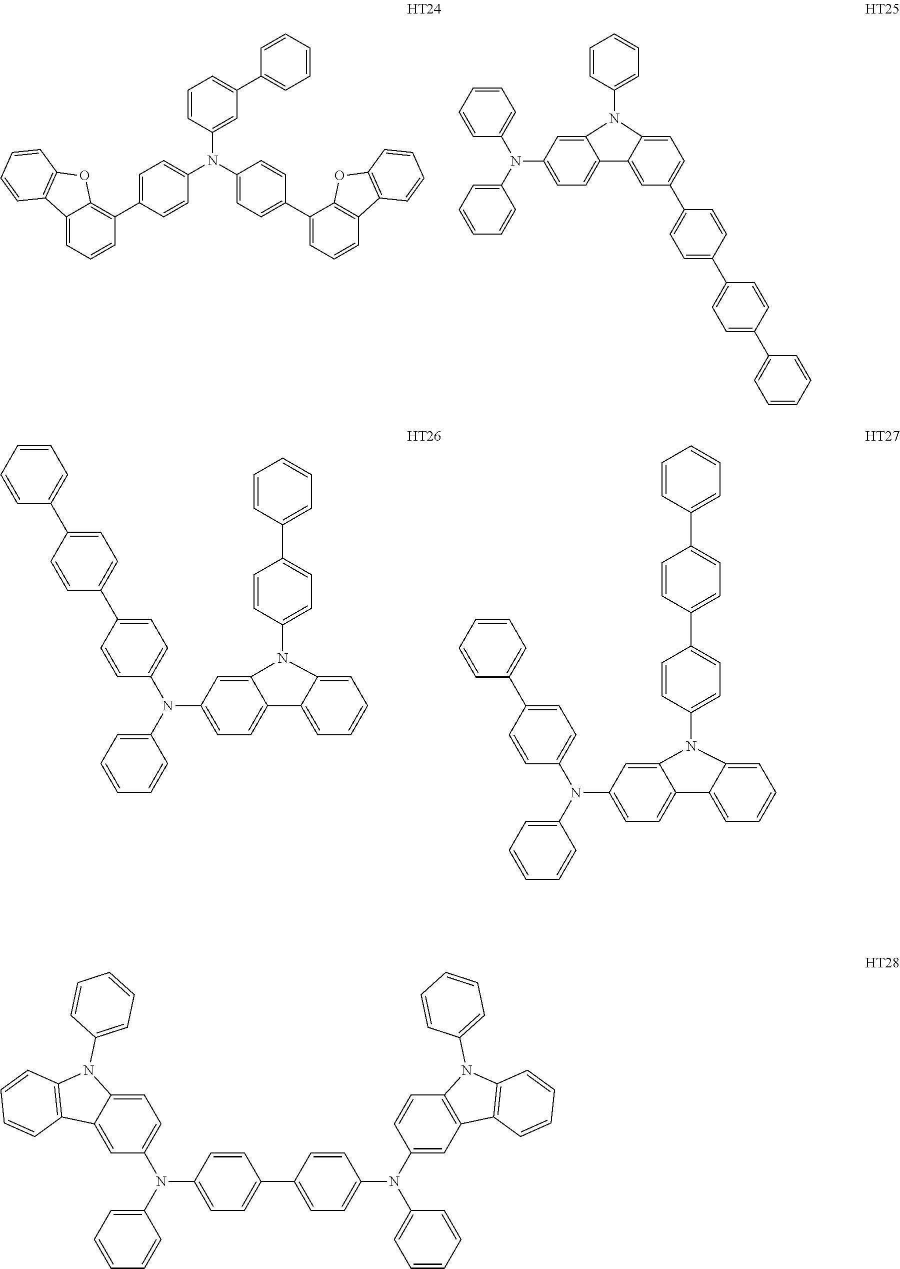 [SMILES: c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

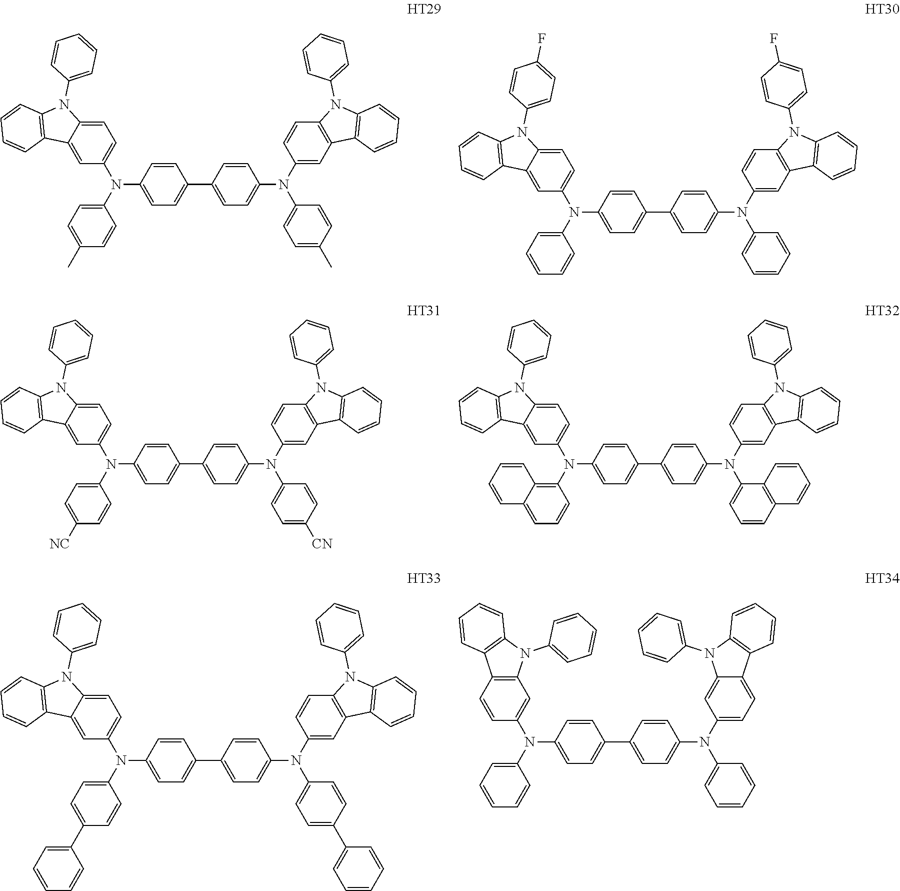

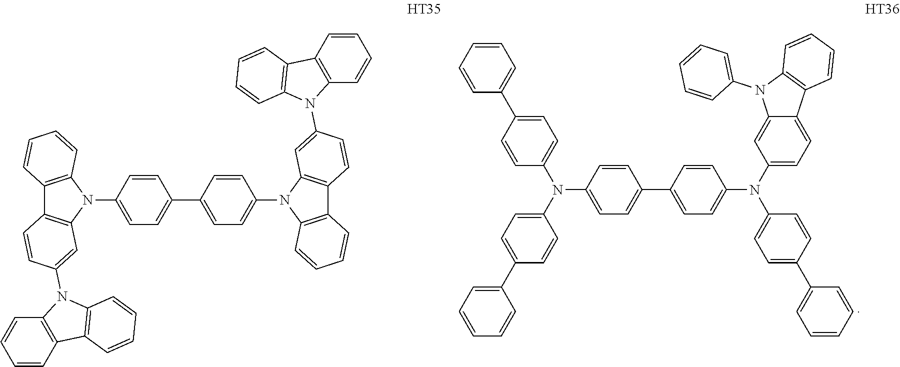 [SMILES: c1ccc2c(c1)c1ccccc1n2-c1ccc2c3ccccc3n(-c3ccc(-c4ccc(-n5c6ccccc6c6ccc(-n7c8ccccc8c8ccccc87)cc65)cc4)cc3)c2c1 ; c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1]

In some embodiments, the hole transport region HTR may include a compound represented by Formula H-1.

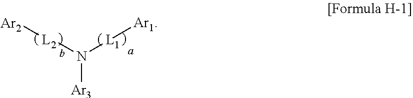

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. When a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In addition, in Formula H-1, Ar₃ may each independently be a substituted or unsubstituted aryl group having 6 to 30 ring-forming carbon atoms.

A compound represented by Formula H-1 may be a monoamine compound. In some embodiments, the compound represented by Formula H-1 may be a diamine compound in which at least one of Ar₁ to Ar₃ includes an amine group as a substituent.

In some embodiments, the compound represented by Formula H-1 may be a carbazole-based compound including a substituted or unsubstituted carbazole group in at least one of Ar₁ or Ar₂ or a substituted or unsubstituted fluorene-based group in at least one of Ar₁ or Ar₂.

The compound represented by Formula H-1 may be represented by any one among compounds of Compound Group H. However, the compounds listed in Compound Group H are presented as an example, and the compound represented by Formula H-1 is not limited to the those listed in Compound Group H.

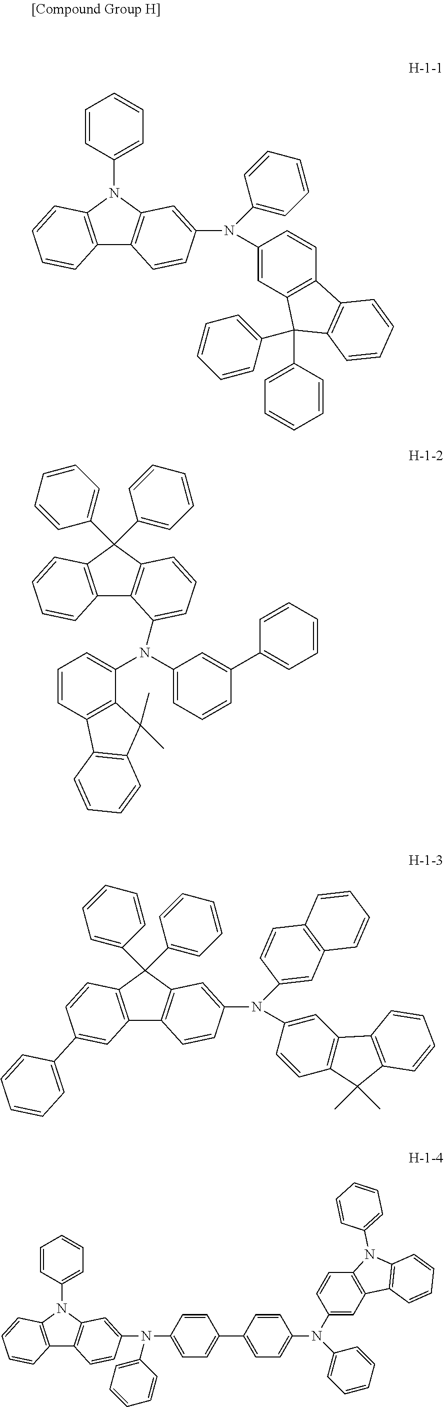 [SMILES: c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1]

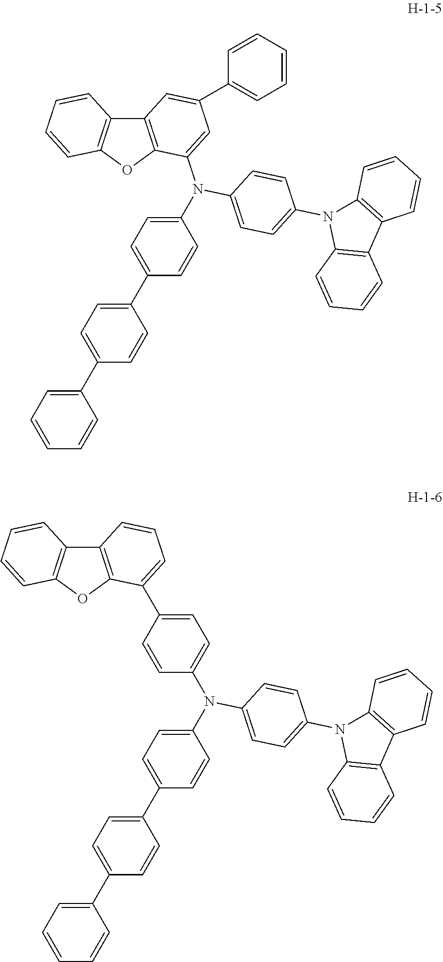 [SMILES: c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

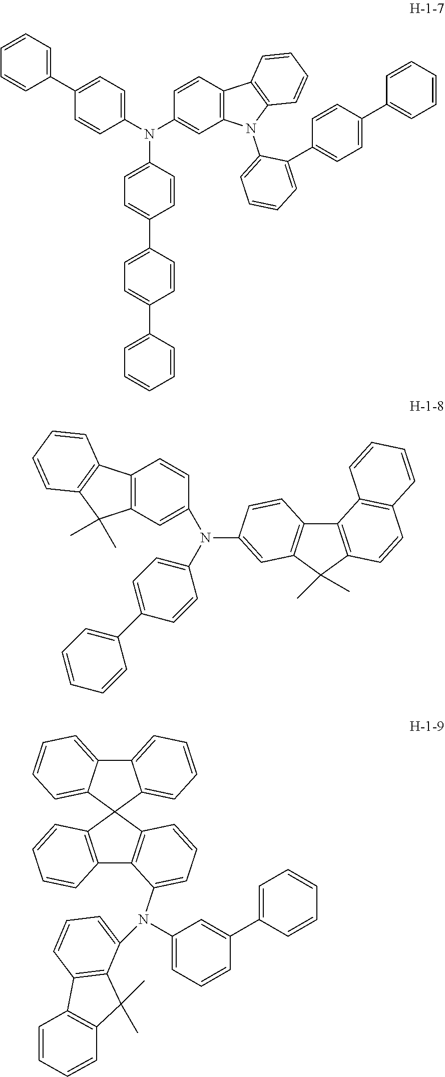 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21]

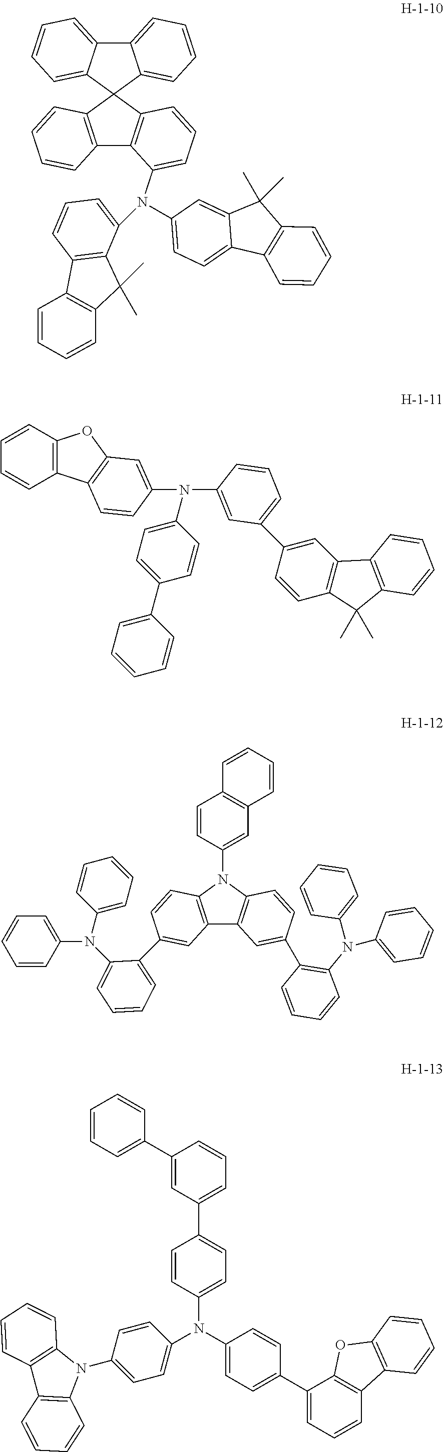 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

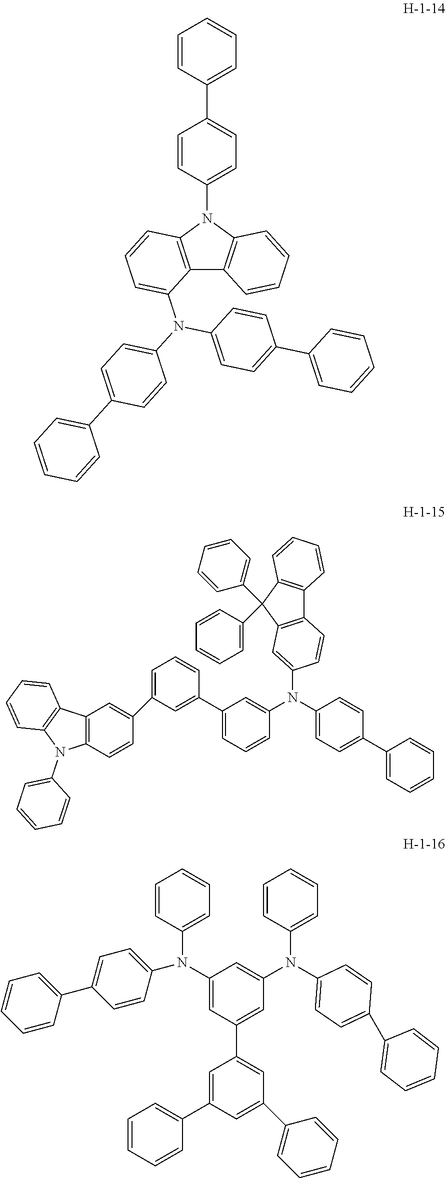 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

The hole transport region HTR may include a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4′-[tris(3-methylphenyl)phenylamino]triphenylamine] (m-MTDATA), 4,4′,4′-tris(N,N-diphenylamino)triphenylamine (TDATA), 4,4′,4′-tris{N,-(2-naphthyl)-N-phenylamino)-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-I-yl)-N,N′-diphenyl-benzidine (NPB), N,N′-bis(naphthalen-2-yl)-N,N′-bis(phenyl)benzidine (β-NPB), N2,N7-di(naphthalen-1-yl)-N2,N7-diphenyl-9,9′-spirobi[fluorene]-2,7-diamine (spiro-NPB), 2,2′-dimethyl-N4,N4′-di(naphthalen-1-yl)-N4,N4′-diphenyl-[1,1′-biphenyl]-4,4′-diamine (methylated-NPB), triphenylamine-containing polyetherketone (TPAPEK), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (HAT-CN), etc.

In some embodiments, the hole transport region HTR may include carbazole-based derivatives such as N-phenyl carbazole and/or polyvinyl carbazole, fluorene-based derivatives, triphenylamine-based derivatives such as N,N′-bis(3-methylphenyl)-N,N′-diphenyl-[1,1′-biphenyl]-4,4′-diamine (TPD), N2,N7-diphenyl-N2,N7-di-m-tolyl-9,9′-spirobi[fluorene]-2,7-diamine (spiro-TPD), and/or 4,4′,4″-tris(N-carbazolyl)triphenylamine (TCTA), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 9-(4-tert-Butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzenem (DCP), etc. The hole transport region HTR may include the compounds of the hole transport region described above in at least one among the hole injection layer HIL, the hole transport layer HTL, and the electron blocking layer EBL.

The hole transport region HTR may have a thickness of about 100 Å to about 10000 Å, for example, about 100 Å to about 5000 Å. When the hole transport region HTR includes the hole injection layer HIL, the hole injection layer HIL may have a thickness of, for example, about 30 Å to about 1000 Å. When the hole transport region HTR includes the hole transport layer HTL, the hole transport layer HTL may have a thickness of about 30 Å to about 1000 Å. When the hole transport region HTR includes the electron blocking layer EBL, the electron blocking layer EBL may have a thickness of, for example, about 10 Å to about 1000 Å. When the thicknesses of the hole transport region HTR, the hole injection layer HIL, the hole transport layer HTL, and the electron blocking layer EBL satisfy the above-described ranges, satisfactory hole transport properties may be obtained without a substantial increase in driving voltage.

The hole transport region HTR may further include, in addition to the above-described materials, a charge generation material to increase conductivity. The charge generation material may be uniformly or non-uniformly dispersed in the hole transport region HTR. The charge generation material may be, for example, a p-dopant. The p-dopant may include at least one of halogenated metal compounds, quinone derivatives, metal oxides, or cyano group-containing compounds, but the present disclosure is not limited thereto. For example, the p-dopant may include halogenated metal compounds such as CuI and/or RbI, quinone derivatives such as tetracyanoquinodimethane (TCNQ) and/or 2,3,5,6-tetrafluoro-7,7,8,8-tetracyanoquinodimethane (F4-TCNQ), metal oxides such as tungsten oxides and/or molybdenum oxides, and cyano group-containing compounds such as dipyrazino[2,3-f:2′,3′-h] quinoxaline-2,3,6,7,10,11-hexacarbonitrile (HAT-CN), 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or compound H-100, but the present disclosure is not limited thereto.

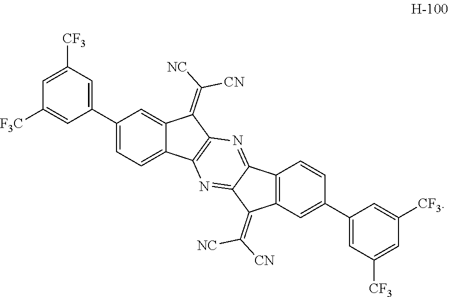 [SMILES: N#CC(C#N)=C1c2cc(-c3cc(C(F)(F)F)cc(C(F)(F)F)c3)ccc2-c2nc3c(nc21)-c1ccc(-c2cc(C(F)(F)F)cc(C(F)(F)F)c2)cc1C3=C(C#N)C#N]

As described above, the hole transport region HTR may further include at least one of a buffer layer or an electron blocking layer EBL in addition to the hole injection layer HIL and the hole transport layer HTL. The buffer layer may compensate a resonance distance according to wavelengths of light emitted from an emission layer EML, and may thus increase luminous efficiency. Materials which may be included in the hole transport region HTR may be utilized as materials included in the buffer layer. The electron blocking layer EBL may serve to prevent or reduce electrons from being injected from the electron transport region ETR to the hole transport region HTR.

The electron transport region ETR is provided on the emission layer EML. The electron transport region ETR may include at least one among a hole blocking layer HBL, an electron transport layer ETL, and an electron injection layer EIL, but the embodiment of the present disclosure is not limited thereto. In some embodiments, the electron transport region ETR may include a buffer layer.

The electron transport region ETR may have a single layer formed of a single material, a single layer formed of a plurality of different materials, or a multilayer structure having a plurality of layers formed of a plurality of different materials.

For example, the electron transport region ETR may have a single layer structure of an electron injection layer EIL or an electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL, or an electron transport layer ETL/buffer layer are stacked in order from the emission layer EML, but the present disclosure is not limited thereto. The electron transport region ETR may have a thickness of, for example, about 1000 Å to about 1500 Å.

The electron transport region ETR may be formed utilizing one or more suitable methods such as a vacuum deposition method, a spin coating method, a cast method, a Langmuir-Blodgett (LB) method, an inkjet printing method, a laser printing method, a laser induced thermal imaging (LITI) method, etc.

The electron transport region ETR may include the electron transporting host according to an embodiment. For example, the electron transport region ETR may include an electron transporting host represented by Formula ET-1.

The electron transport region ETR may include any one among compounds of Compound Group ER. For example, the electron transport region ETR may include any one among compounds of Compound Group ER in the electron transport layer ETL.

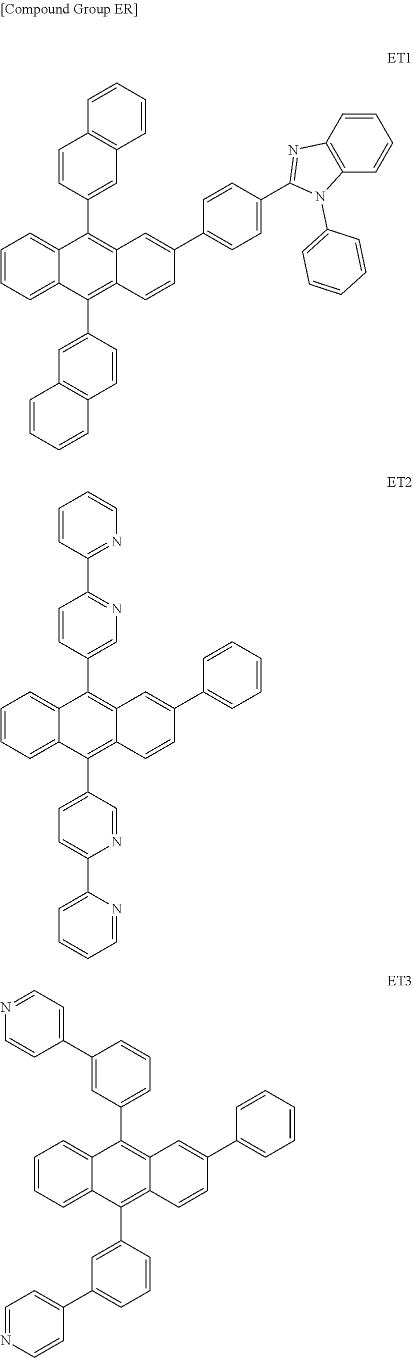 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

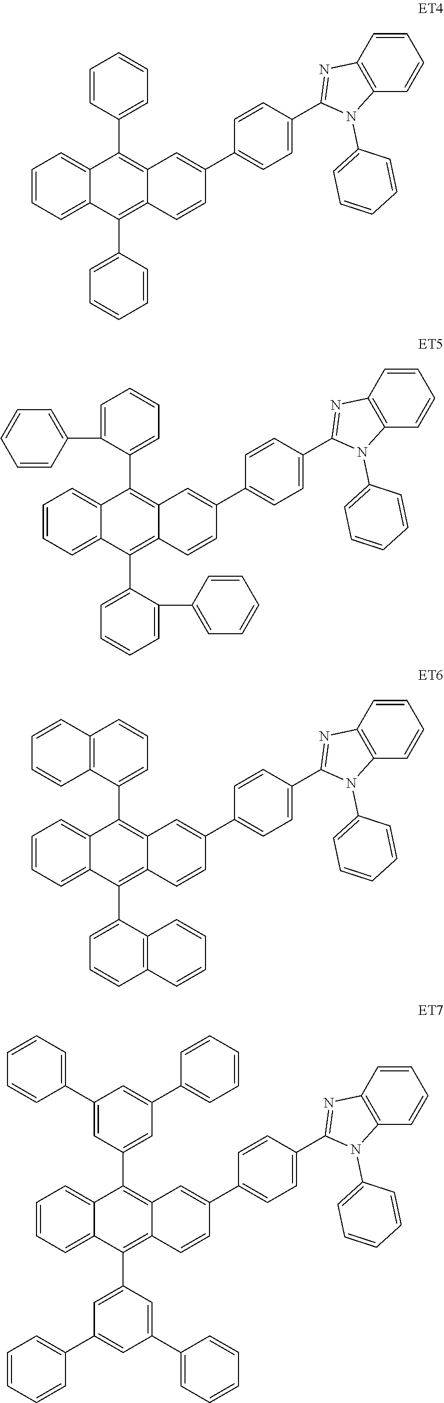 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

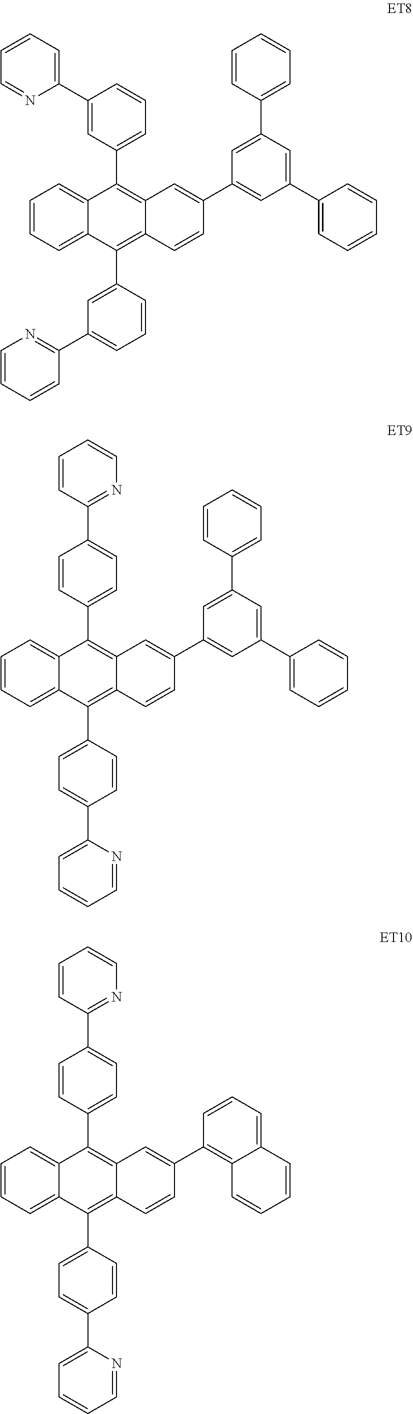

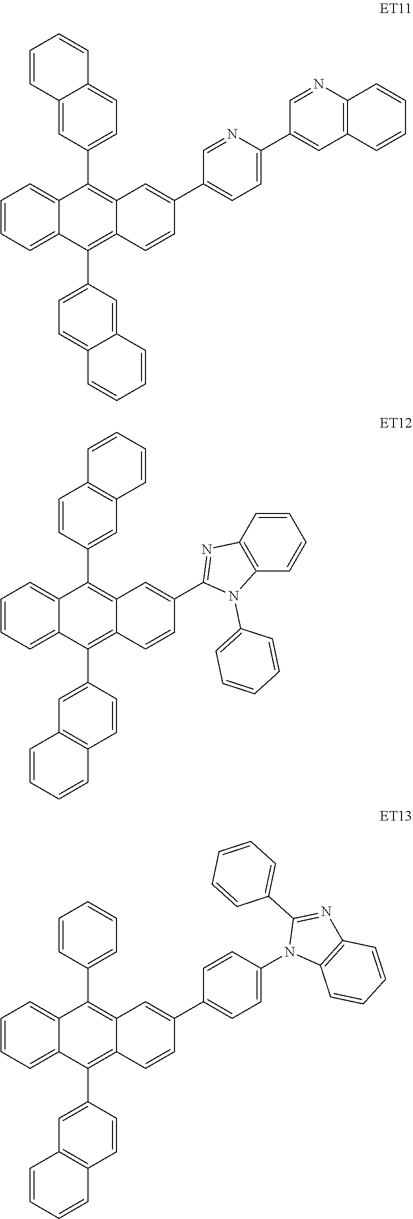

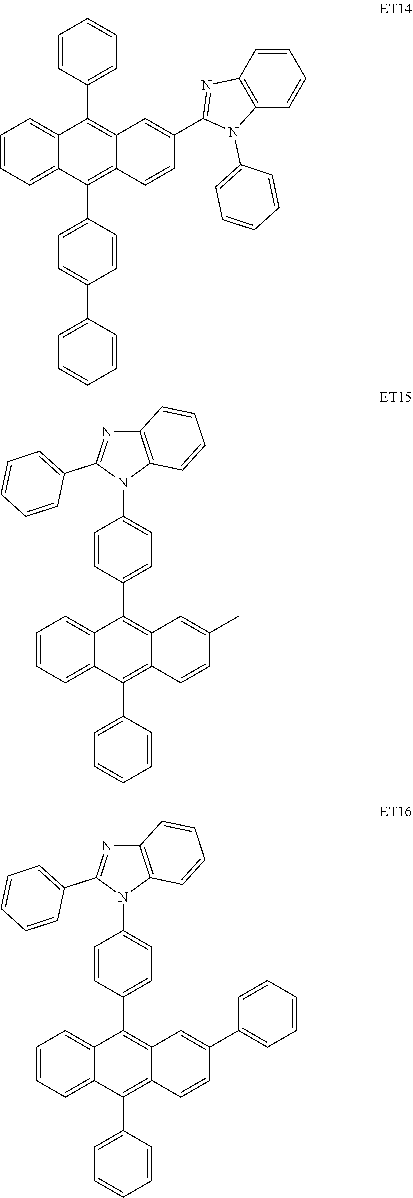 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

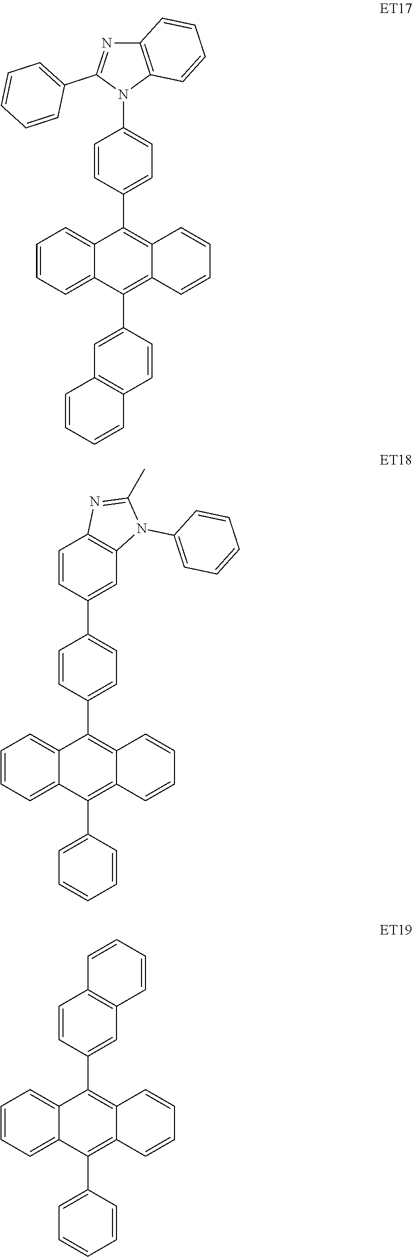

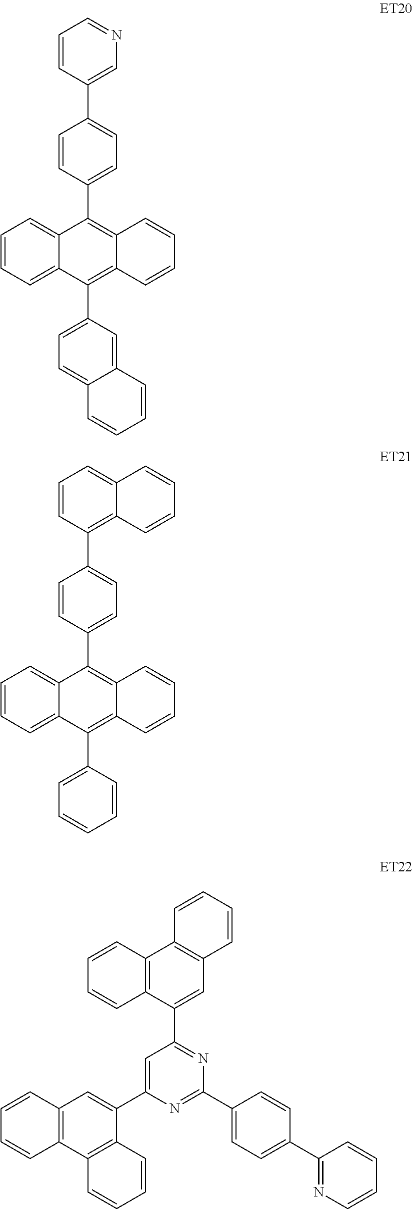

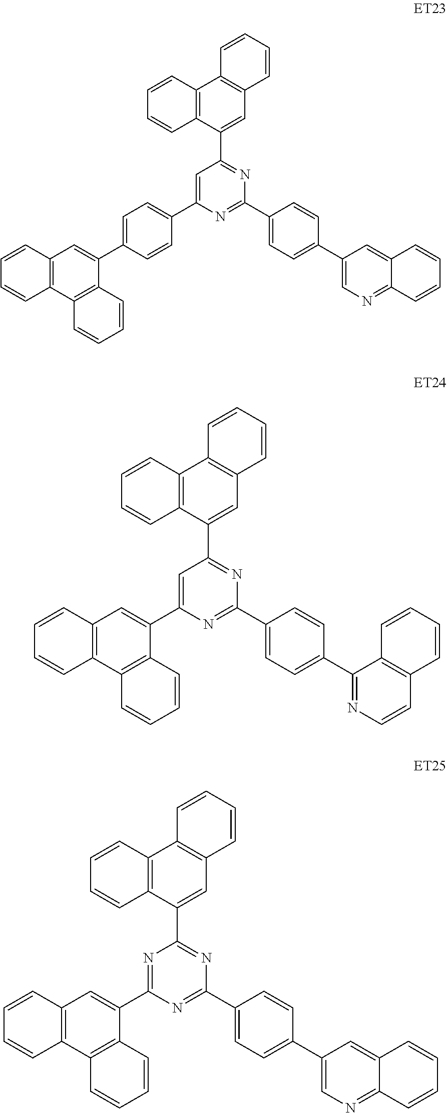 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

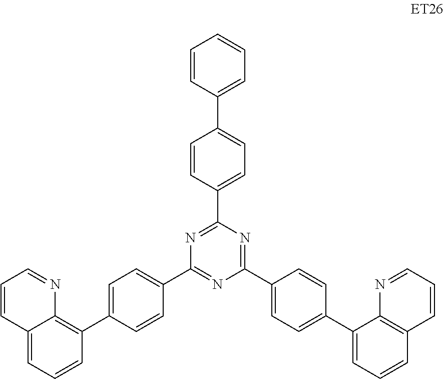 [SMILES: c1ccc(-c2ccc(-c3nc(-c4ccc(-c5cccc6cccnc56)cc4)nc(-c4ccc(-c5cccc6cccnc56)cc4)n3)cc2)cc1]

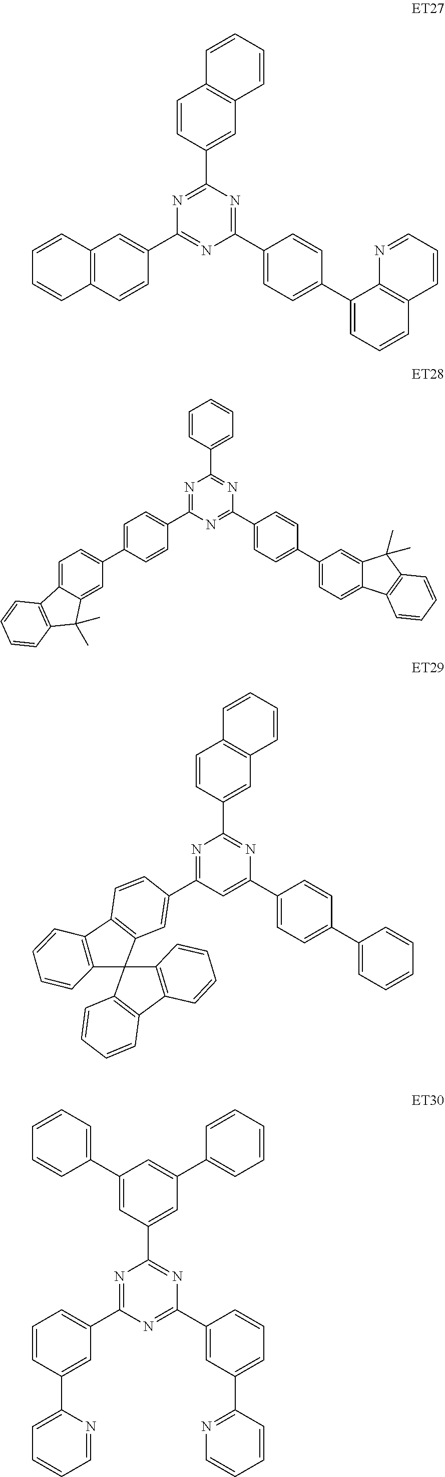 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

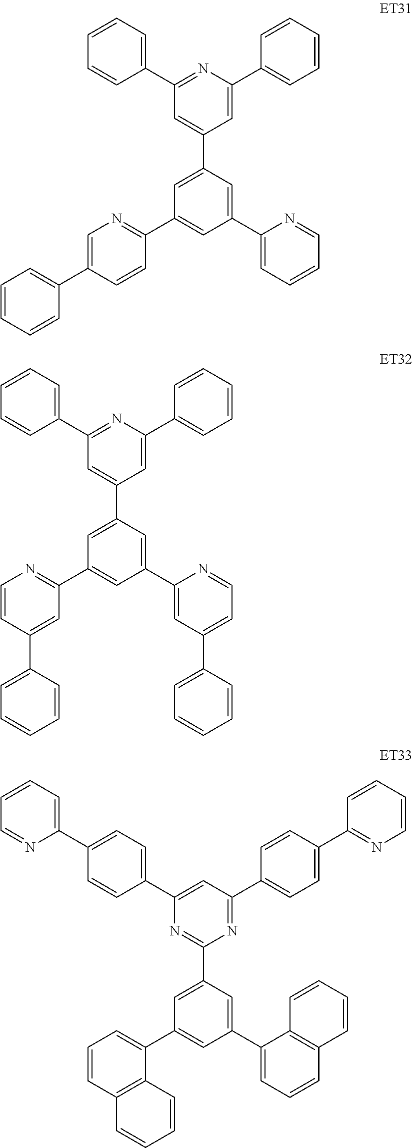

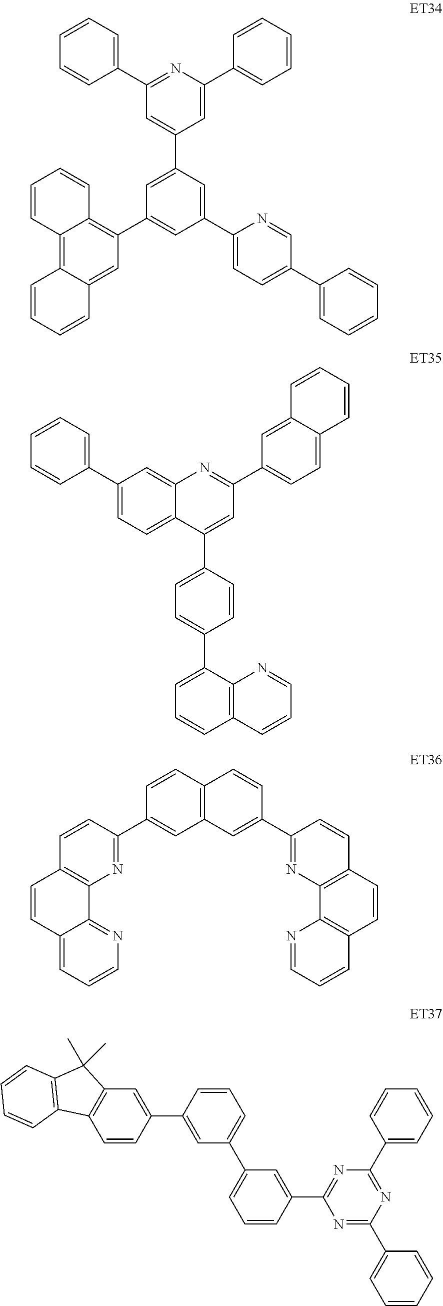

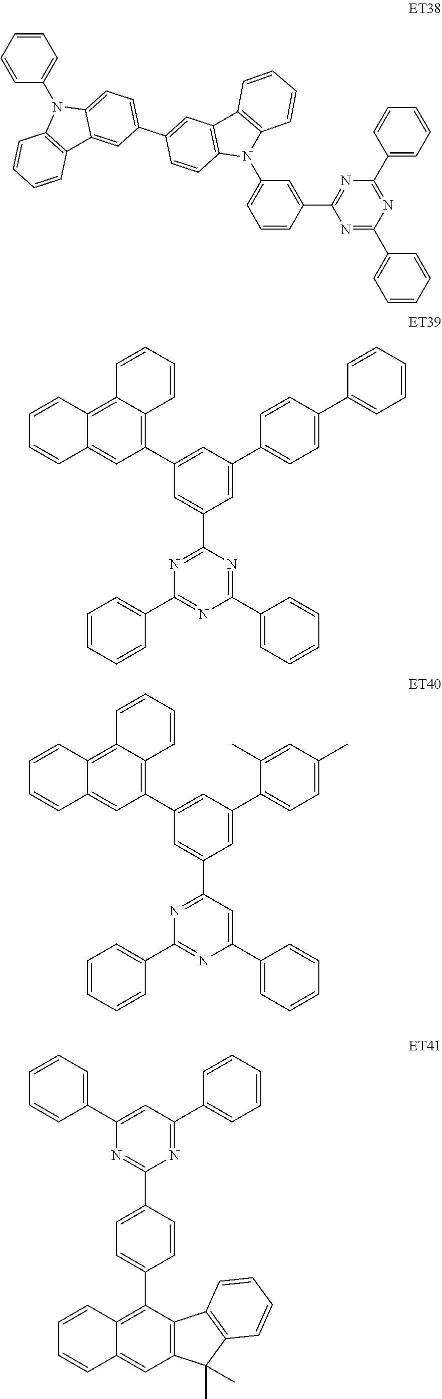

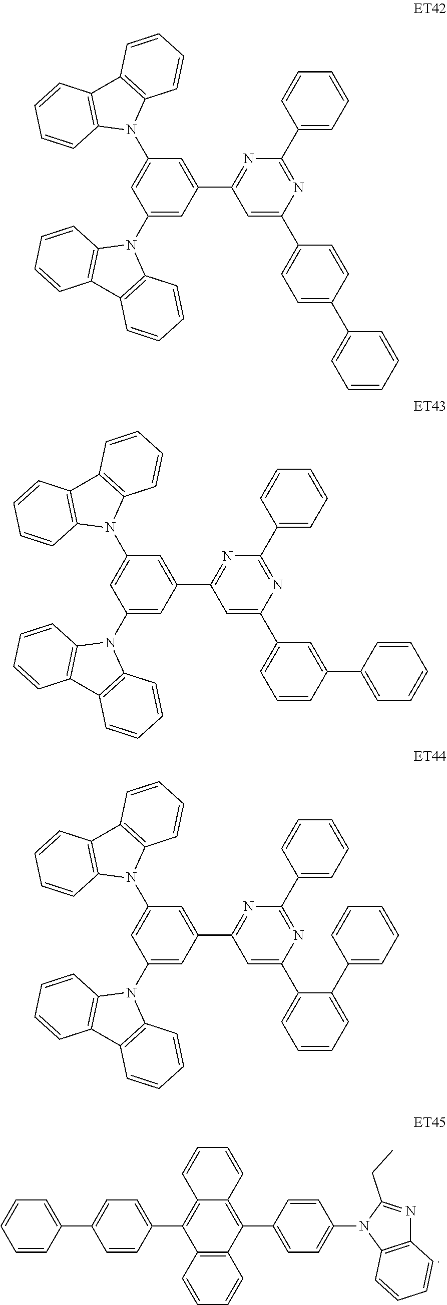 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), or a mixture thereof.

In some embodiments, the electron transport region ETR may include one or more halogenated metals such as LiF, NaCl, CsF, RbCl, RbI, CuI, and/or KI, lanthanide metals such as Yb, and/or co-deposition materials of a halogenated metal and a lanthanide metal. For example, the electron transport region ETR may include KI:Yb, RbI:Yb, LiF:Yb, etc. as a co-deposition material. For the electron transport region ETR, a metal oxide such as Li₂O and/or BaO, 8-hydroxyl-lithium quinolate (Liq), etc. may be utilized, but the embodiment of the present disclosure is limited thereto. The electron transport region ETR may also be formed of a mixture material of an electron transport material and an insulating organo-metal salt. The organo-metal salt may be a material having an energy band gap of about 4 eV or greater. For example, the organo-metal salt may include, for example, one or more metal acetates, metal benzoates, metal acetoacetates, metal acetylacetonates, and/or metal stearates.

The electron transport region ETR may further include, for example, at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the materials described above, but the embodiment of the present disclosure is not limited thereto. The electron transport region ETR may include the compounds of the electron transport region described above in at least one among the electron injection layer EIL, the electron transport layer ETL, and the hole blocking layer HBL.

When the electron transport region ETR includes the electron transport layer ETL, the electron transport layer ETL may have a thickness of about 100 Å to about 1000 Å, for example, about 150 Å to about 500 Å. When the thickness of the electron transport layer ETL satisfies the above-described range, satisfactory electron transport properties may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described ranges, satisfactory electron injection properties may be obtained without a substantial increase in driving voltage.

The second electrode EL2 is provided on the electron transport region ETR. The second electrode EL2 may be a common electrode. The second electrode EL2 may be a cathode or an anode but the embodiment of the present disclosure is not limited thereto. For example, when the first electrode EL1 is an anode, the second electrode EL2 may be a cathode, and when the first electrode EL1 is a cathode, the second electrode EL2 may be an anode. The second electrode EL2 may include at least one selected from Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, and/or an oxide thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In some embodiments, the second electrode EL2 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the second electrode EL2 may include the above-described metal materials, a combination of two or more metal materials selected from the above-described metal materials, and/or oxides of the above-described metal materials.

In some embodiments, the second electrode EL2 may be connected with an auxiliary electrode. When the second electrode EL2 is connected with the auxiliary electrode, the resistance of the second electrode EL2 may decrease.

In some embodiments, a capping layer CPL may be further disposed on the second electrode EL2 of the light emitting element ED of an embodiment. The capping layer CPL may include a multilayer or a single layer.

In an embodiment, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNₓ, SiOy, etc.

For example, when the capping layer CPL includes an organic material, the organic material may include α-NPD, NPB, TPD, m-MTDATA, Alq₃ CuPc, N4,N4,N4′,N4′-tetra(biphenyl-4-yl) biphenyl-4,4′-diamine (TPD15), 4,4′,4″-tris(carbazol-9-yl)triphenylamine (TCTA), etc., and/or may include epoxy resins and/or acrylates such as methacrylates. However, the embodiment of the present disclosure is not limited thereto, and the capping layer CPL may include compounds P1 to P5.

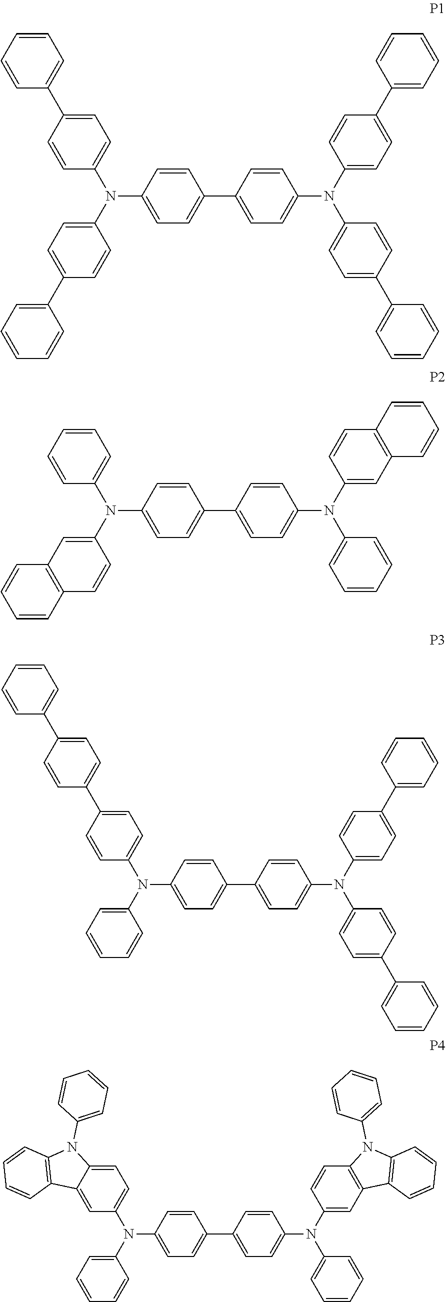 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

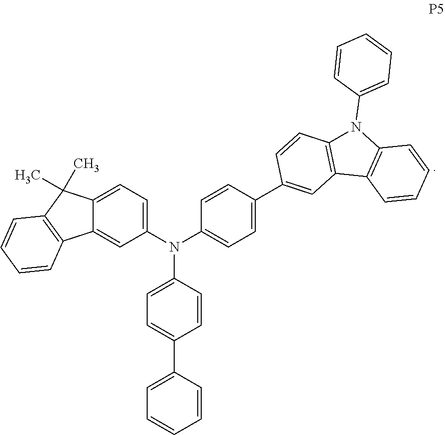 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the capping layer CPL may have a refractive index of about 1.6 or greater. For example, the capping layer CPL may have a refractive index of about 1.6 or greater in a wavelength range of about 550 nm to about 660 nm.

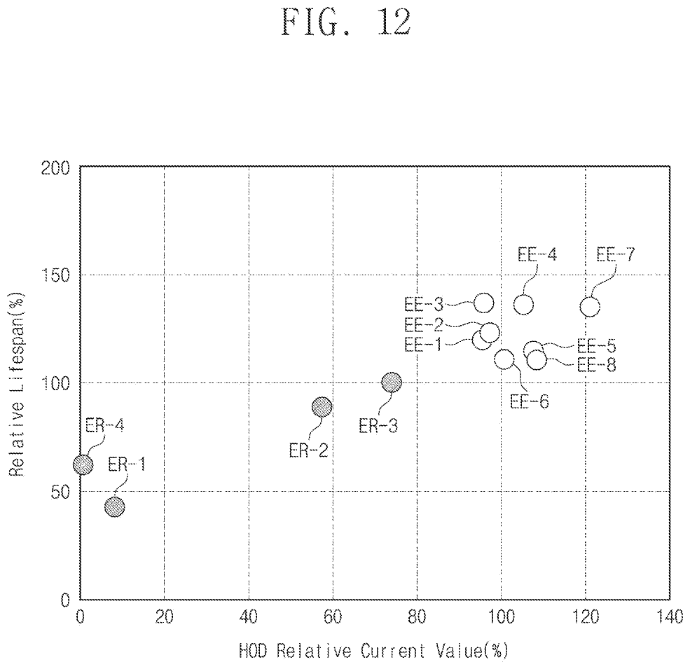

FIGS. 8 to 11 are each a cross-sectional view of a display device according to an embodiment. Hereinafter, in the description of the display device according to an embodiment with reference to FIGS. 8 and 11, content overlapping the one described above with reference to FIGS. 1 to 6 will not be described again, and the differences will be mainly described.

Referring to FIG. 8, a display device DD according to an embodiment may include a display panel DP having a display element layer DP-ED, a light control layer CCL disposed on the display panel DP, and a color filter layer CFL. In an embodiment illustrated in FIG. 8, the display panel DP may include a base layer BS, a circuit layer DP-CL provided on the base layer BS, and a display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. A structure of the light emitting element ED shown in FIG. 8 may be the same as the structure of the light emitting element of FIGS. 3 to 6 described above.

Referring to FIG. 8, the emission layer EML may be disposed in the openings OH defined in the pixel defining films PDL. For example, the emission layer EML separated by the pixel defining films PDL and provided corresponding to each of light emitting regions PXA-R, PXA-G, and PXA-B may be to emit light in substantially the same wavelength ranges. In the display device DD-a of an embodiment, the emission layer EML may be to emit blue light. Unlike the one illustrated, in an embodiment, the emission layer EML may be provided as a common layer throughout the light emitting regions PXA-R, PXA-G, and PXA-B.

The light control layer CCL may be disposed on the display panel DP. The light control layer CCL may include a photoconverter. The photoconverter may be a quantum dot or a phosphor. The photoconverter may convert the wavelength of received light, and emit the resulting light. For example, the light control layer CCL may be a layer containing quantum dots or phosphors.

The light control layer CCL may include a plurality of light control units CCP1, CCP2, and CCP3. The light control units CCP1, CCP2, and CCP3 may be spaced apart from each other.

Referring to FIG. 8, a division pattern BMP may be disposed between the light control units CCP1, CCP2, and CCP3 spaced apart from each other, but the embodiment of the present disclosure is not limited thereto. In FIG. 8, the division pattern BMP is shown to non-overlap the light control units CCP1, CCP2, and CCP3, but the present disclosure is not limited thereto and the edges of the light control units CCP1, CCP2, and CCP3 may overlap at least a portion of the division pattern BMP.

The light control layer CCL may include a first light control unit CCP1 including a first quantum dot QD1 for converting a first color light provided from the light emitting element ED into a second color light, a second light control unit CCP2 including a second quantum dot QD2 for converting the first color light into a third color light, and a third light control unit CCP3 for transmitting the first color light.

In an embodiment, the first light control unit CCP1 may provide red light, which is the second color light, and the second light control unit CCP2 may provide green light, which is the third color light. The third light control unit CCP3 may be to transmit and provide blue light, which is the first color light provided from the light emitting element ED. For example, the first quantum dot QD1 may be a red quantum dot and the second quantum dot QD2 may be a green quantum dot.

The core of a quantum dot may be selected from a Group II-VI compound, a Group III-VI compound, a Group I-III-VI compound, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may include a ternary compound selected from the group consisting of AgInS, AgInS₂, CuInS, CuInS₂, AgGaS₂, CuGaS₂ CuGaO₂, AgGaO₂, AgAlO₂, and any mixture thereof, and/or a quaternary compound such as AgInGaS₂ and/or CulnGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In one or more embodiments, the Group III-V compound may further include a Group II metal. For example, InZnP, etc. may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, a binary compound, a ternary compound, or a quaternary compound may be present in particles in a substantially uniform concentration distribution, or may be present in substantially the same particles in a partially different concentration distribution. In some embodiments, a core/shell structure in which one quantum dot surrounds another quantum dot may be present. The core/shell structure may have a concentration gradient in which the concentration of an element present in the shell becomes lower towards the core.

In some embodiments, a quantum dot may have the core/shell structure including a core having nano-crystals, and a shell around (e.g., surrounding) the core, which are described above. The shell of the quantum dot may serve as a protection layer to prevent or reduce the chemical deformation of the core so as to keep semiconductor properties, and/or as a charging layer to impart electrophoresis properties to the quantum dot. The shell may be a single layer or multiple layers. Examples of the shell of the quantum dot may include (e.g., may be) a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄, but the embodiment of the present disclosure is not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the embodiment of the present disclosure is not limited thereto.

A quantum dot may have a full width of half maximum (FWHM) of a light emitting wavelength spectrum of about 45 nm or less, about 40 nm or less, or about 30 nm or less, and color purity or color reproducibility may be enhanced in the above ranges. In addition, light emitted through such a quantum dot is emitted in all directions, and thus a wide viewing angle may be improved.

Although the form of a quantum dot is not particularly limited as long as it is a form commonly utilized in the art, and for example, a quantum dot in the form of spherical, pyramidal, multi-arm, or cubic nanoparticles may be utilized. In some embodiments, a quantum dot in the form of nanotubes, nanowires, nanofibers, nanoplatelets, etc. may be utilized.

The quantum dot may control the color of emitted light according to particle size thereof, and thus the quantum dot may have one or more suitable colors of emitted light such as blue, red, green, etc.

In some embodiments, the light control layer CCL may further include scatterers SP. The first light control unit CCP1 may include the first quantum dot QD1 and the scatterers SP, the second light control unit CCP2 may include the second quantum dot QD2 and the scatterers SP, and the third light control unit CCP3 may not include (e.g., may exclude) a quantum dot but may include the scatterers SP.

The scatterers SP may be inorganic particles. For example, the scatterers SP may include at least one among TiO₂, ZnO, Al₂O₃, SiO₂, and hollow silica. The scatterers SP may include any one among TiO₂, ZnO, Al₂O₃, SiO₂, and hollow silica, or may be a mixture of two or more materials selected from TiO₂, ZnO, Al₂O₃, SiO₂, and hollow silica.

The first light control unit CCP1, the second light control unit CCP2, and the third light control unit CCP3 may each include base resins BR1, BR2, and BR3, respectively, for dispersing the quantum dots QD1 and QD2 and the scatterers SP. In an embodiment, the first light control unit CCP1 may include the first quantum dot QD1 and the scatterers SP dispersed in the first base resin BR1, the second light control unit CCP2 may include the second quantum dot QD2 and the scatterers SP dispersed in the second base resin BR2, and the third light control unit CCP3 may include the scatterers SP dispersed in the third base resin BR3. The base resins BR1, BR2, and BR3 are a medium in which the quantum dots QD1 and QD2 and the scatterers SP are dispersed, and may be formed of one or more suitable resin compositions, which may be generally referred to as a binder. For example, the base resins BR1, BR2, and BR3 may be an acrylic-based resin, a urethane-based resin, a silicone-based resin, an epoxy-based resin, etc. The base resins BR1, BR2, and BR3 may be a transparent resin. In an embodiment, the first base resin BR1, the second base resin BR2, and the third base resin BR3 may each be the same as or different from each other.

The light control layer CCL may include a barrier layer BFL1. The barrier layer BFL1 may serve to prevent or reduce moisture and/or oxygen (hereinafter referred to as “moisture/oxygen”) from being introduced. The barrier layer BFL1 may prevent or substantially prevent the light control units CCP1, CCP2, and CCP3 from being exposed to moisture/oxygen. The barrier layer BFL1 may cover the light control units CCP1, CCP2, and CCP3. In some embodiments, a barrier layer BFL2 may be provided between the light control units CCP1, CCP2, and CCP3 and the color filter layer CFL.

The barrier layers BFL1 and BFL2 may include at least one inorganic layer. For example, the barrier layers BFL1 and BFL2 may be formed of an inorganic material. For example, the barrier layers BFL1 and BFL2 may be formed including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and/or a metal thin film in which light transmittance is secured, etc. In one or more embodiments, the barrier layers BFL1 and BFL2 may further include an organic film. The barrier layers BFL1 and BFL2 may be formed of a single layer or a plurality of layers.

In the display device DD-a of an embodiment, the color filter layer CFL may be disposed on the light control layer CCL. For example, the color filter layer CFL may be directly disposed on the light control layer CCL. In this case, the barrier layer BFL2 may not be provided.

The color filter layer CFL may include filters CF1, CF2, and CF3. For example, the color filter layer CFL may include a first filter CF1 for transmitting a second color light, a second filter CF2 for transmitting a third color light, and a third filter CF3 for transmitting a first color light. For example, the first filter CF1 may be a red filter, the second filter CF2 may be a green filter, and the third filter CF3 may be a blue filter. The filters CF1, CF2, and CF3 may each include a polymer photosensitive resin, a pigment and/or a dye. The first filter CF1 may include a red pigment and/or a red dye, the second filter CF2 may include a green pigment and/or a green dye, and the third filter CF3 may include a blue pigment and/or a blue dye. The embodiment of the present disclosure is not limited thereto, and the third filter CF3 may not include (e.g., may exclude) a pigment and/or a dye. The third filter CF3 may include a polymer photosensitive resin, but not include a pigment or a dye. The third filter CF3 may be transparent. The third filter CF3 may be formed of a transparent photosensitive resin.

In an embodiment, the first filter CF1 and the second filter CF2 may be yellow filters. In an embodiment, the first filter CF1 and the second filter CF2 may not be separated from each other and may be provided as a single body.

The first to third filters CF1, CF2, and CF3 may be disposed corresponding to the red light emitting region PXA-R, the green light emitting region PXA-G, and the blue light emitting region PXA-B, respectively.

The base substrate BL may be disposed on the color filter layer CFL. The base substrate BL may be a member providing a base surface on which the color filter layer CFL and the light control layer CCL are disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer (e.g., including an organic material and an inorganic material). In some embodiments, unlike what is shown, the base substrate BL may not be provided.

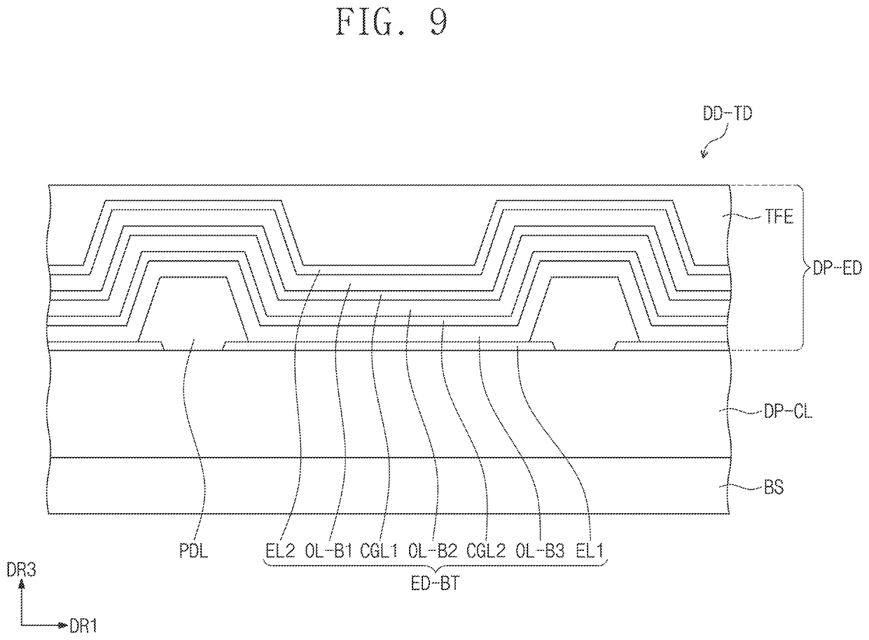

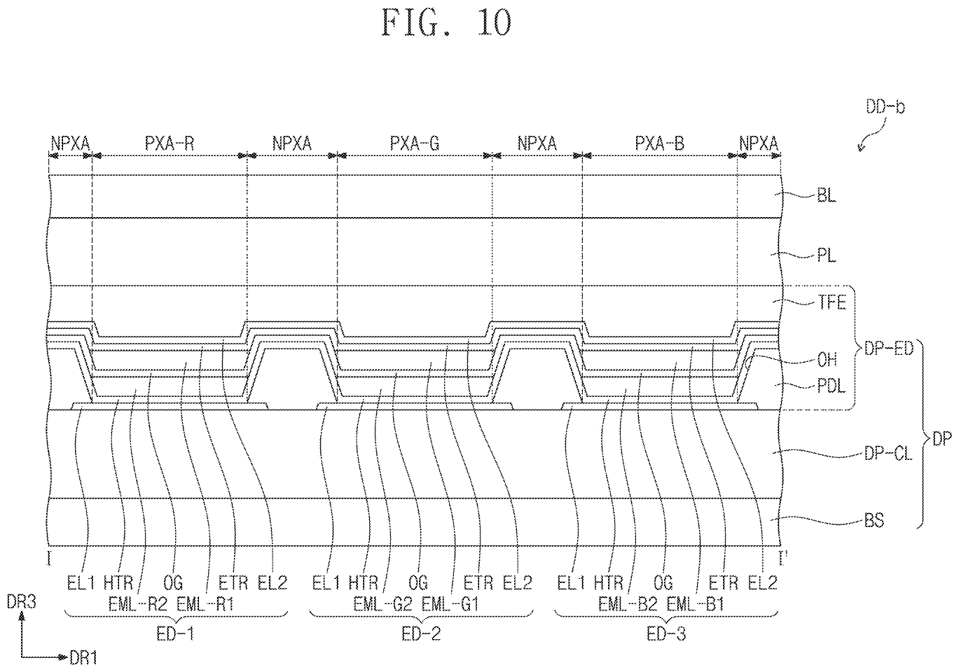

FIG. 9 is a cross-sectional view showing a portion of a display device according to an embodiment. FIG. 9 shows a cross-sectional view of a portion corresponding to the display panel DP of FIG. 8. In a display device DD-TD of an embodiment, a light emitting element ED-BT may include a plurality of light emitting structures OL-B1, OL-B2, and OL-B3. The light emitting element ED-BT may include the first electrode EL1 and the second electrode EL2 facing each other, and the plurality of light emitting structures OL-B1, OL-B2, and OL-B3 provided by being sequentially stacked in a thickness direction between the first electrode EL1 and the second electrode EL2. The light emitting structures OL-B1, OL-B2, and OL-B3 each may include the emission layer EML (FIG. 8), a hole transport region HTR and an electron transport region ETR disposed with the emission layer EML (FIG. 8) therebetween. For example, the light emitting element ED-BT included in the display device DD-TD of an embodiment may be a light emitting element having a tandem structure including a plurality of emission layers.

In an embodiment illustrated in FIG. 9, light emitted from each of the light emitting structures OL-B1, OL-B2, and OL-B3 may all be blue light. However, the embodiment of the present disclosure is not limited thereto, and wavelength ranges of light emitted from each of the light emitting structures OL-B1, OL-B2, and OL-B3 may be different from each other. For example, the light emitting element ED-BT including the plurality of light emitting structures OL-B1, OL-B2, and OL-B3 emitting light in different wavelength ranges may be to emit white light.

Charge generation layers CGL1 and CGL2 may be disposed between neighboring light emitting structures OL-B1, OL-B2, and OL-B3. The charge generation layers CGL1 and CGL2 may include a p-type or kind charge generation layer and/or an n-type or kind charge generation layer.

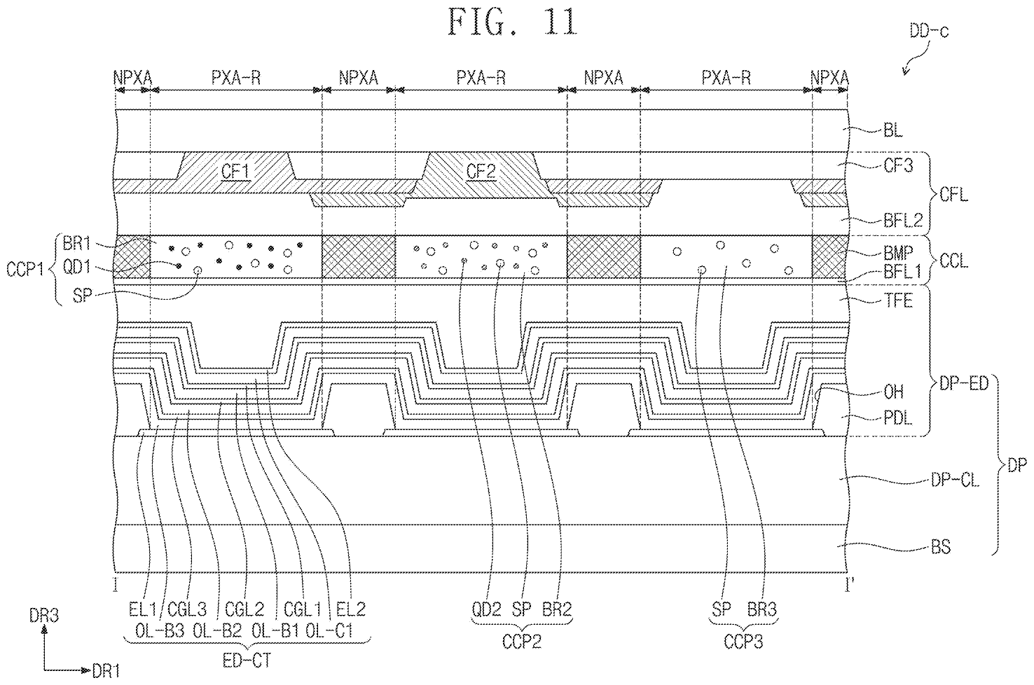

Referring to FIG. 10, the display device may include light emitting elements ED-1, ED-2, and ED-3 in which two emission layers are stacked. Unlike what is shown in FIG. 2, FIG. 10 illustrates that two emission layers are provided in each of the first to third light emitting elements ED-1, ED-2, and ED-3. In each of the first to third light emitting elements ED-1, ED-2, and ED-3, the two emission layers may be to emit light in substantially the same wavelength range.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary portion OG may be disposed between the first red emission layer EML-R1 and the second red emission layer EML-R2, between the first green emission layer EML-G1 and the second green emission layer EML-G2, and/or between the first blue emission layer EML-B1 and the second blue emission layer EML-B2.

The emission auxiliary portion OG may include a single layer or multiple layers. The emission auxiliary portion OG may include a charge generation layer. For example, the emission auxiliary portion OG may include an electron transport region, a charge generation layer, and a hole transport region that are sequentially stacked. The emission auxiliary portion OG may be provided as a common layer throughout the first to third light emitting elements ED-1, ED-2, and ED-3. However, the embodiment of the present disclosure is not limited thereto, and the emission auxiliary portion OG may be provided to be patterned inside the openings OH defined in the pixel defining films PDL.

The first red emission layer EML-R1, the first green emission layer EML-G1, and the first blue emission layer EML-B1 may be disposed between the hole transport region HTR and the emission auxiliary portion OG. The second red emission layer EML-R2, the second green emission layer EML-G2, and the second blue emission layer EML-B2 may be disposed between the emission auxiliary portion OG and the electron transport region ETR.

For example, the light emitting element ED-1 may include the first electrode EL1, the hole transport region HTR, the second red emission layer EML-R2, the emission auxiliary portion OG, the first red emission layer EML-R1, the electron transport region ETR, and the second electrode EL2, which are sequentially stacked in the stated order. The second light emitting element ED-2 may include the first electrode EL1, the hole transport region HTR, the second green emission layer EML-G2, the emission auxiliary portion OG, the first green emission layer EML-G1, the electron transport region ETR, and the second electrode EL2, which are sequentially stacked in the stated order. The third light emitting element ED-3 may include the first electrode EL1, the hole transport region HTR, the second blue emission layer EML-B2, the emission auxiliary portion OG, the first blue emission layer EML-B1, the electron transport region ETR, and the second electrode EL2, which are sequentially stacked in the stated order.

An optical auxiliary layer PL may be disposed on the display element layer DP-ED. The optical auxiliary layer PL may include a polarizing layer. The optical auxiliary layer PL may be disposed on the display panel DP to control reflected light in the display panel DP due to external light. In some embodiments, unlike what is illustrated, the optical auxiliary layer PL may not be provided in the display device.

Referring to FIG. 11, a display device DD-c according to an embodiment may include a plurality of light emitting structures OL-B1, OL-B2, OL-B3, and OL-C1. Unlike what is shown in FIGS. 8 and 9, the display device DD-c of FIG. 11 is illustrated to include four light emitting structures OL-B1, OL-B2, OL-B3, and OL-C1. The light emitting element ED-CT may include the first electrode EL1 and the second electrode EL2 facing each other, and the first to fourth light emitting structures OL-B1, OL-B2, OL-B3, and OL-C1 sequentially stacked between the first electrode EL1 and the second electrode EL2. Charge generation layers CGL1, CGL2, and CGL3 may be disposed between adjacent ones of the first to fourth light emitting structures OL-B1, OL-B2, OL-B3, and OL-C1. Among the four light emitting structures, the first to third light emitting structures OL-B1, OL-B2, and OL-B3 may be to emit blue light, and the fourth light emitting structure OL-C1 may be to emit green light. However, the embodiment of the present disclosure is not limited thereto, and the first to fourth light emitting structures OL-B1, OL-B2, OL-B3, and OL-C1 may each be to emit light having different wavelength ranges.

Hereinafter, with reference to Examples and Comparative Examples, a light emitting element according to an embodiment of the present disclosure will be specifically described. In addition, Examples shown below are illustrated only for the understanding of the present disclosure, and the scope of the present disclosure is not limited thereto.

### Examples

### 1. Manufacture and Evaluation of Light Emitting Element (HOD, Hole Only Device) 1

### (1) Manufacture of Light Emitting Element (HOD, Hole Only Device) 1

A light emitting element including a delayed fluorescent dopant according to an embodiment or one of the Comparative Example compounds was manufactured through a method below. The light emitting elements of Examples 1-1 to 1-8 were manufactured utilizing compounds 1 to 8 according to embodiments of the present disclosure as a delayed fluorescent dopant material of an emission layer. The light emitting element of Comparative Example 1-1 was manufactured utilizing only a host material without utilizing a dopant material. The light emitting elements of Comparative Examples 1-2 to 1-8 were each manufactured utilizing Comparative Example compounds C1 to C4 as a dopant material of an emission layer. The light emitting elements of Comparative Examples 1-1 to 1-8 and Examples 1-1 to 1-8 were hole only devices and were manufactured as devices including two hole transport regions.

As an anode, a glass substrate having an ITO electrode (Corning Incorporated, 15 Ω/cm², 1200 Å) formed thereon was cut to a size of about 50 mm×50 mm×0.7 mm, subjected to ultrasonic cleaning utilizing isopropyl alcohol and pure water for 5 minutes respectively and ultraviolet irradiation for 30 minutes, and then exposed to ozone for cleaning to be mounted on a vacuum deposition apparatus.

HAT-CN was deposited to be 100 Å thick on the anode to form a first hole injection layer. NPB was deposited to be 500 Å thick on the first hole injection layer to form a first hole transport layer, and compound HT-08 according to an embodiment of the present disclosure was deposited to be 100 Å thick on the first hole transport layer to form a buffer layer.

Then, a host and a dopant were co-deposited at a weight ratio of 95.5:0.5 to form an emission layer having a thickness of 400 Å. For the host, HT-08 and ET-05 were provided in a weight ratio of 1:1. For the light emitting element of Comparative Example 1-1 without utilizing a dopant, a host of HT-08 and a host of ET-05 were co-deposited at a weight ratio of 1:1 to form an emission layer having a thickness of 400 Å.

NPB was deposited to be 500 Å thick on the emission layer to form a second hole transport layer, and HAT-CN was deposited to be 100 Å thick on the second hole transport layer to form a second hole injection layer. Then, magnesium (Mg) was utilized to form a second electrode having a thickness of 1000 Å. In an embodiment, the hole injection layer, the hole transport layer, the buffer layer, the emission layer, and the second electrode were formed utilizing a vacuum deposition apparatus.

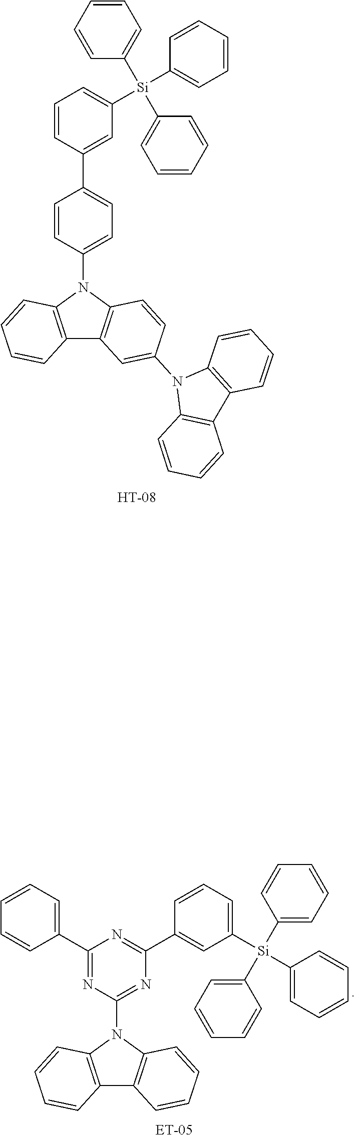 [SMILES: c1ccc([Si](c2ccccc2)(c2ccccc2)c2cccc(-c3ccc(-n4c5ccccc5c5cc(-n6c7ccccc7c7ccccc76)ccc54)cc3)c2)cc1 ; c1ccc(-c2nc(-c3cccc([Si](c4ccccc4)(c4ccccc4)c4ccccc4)c3)nc(-n3c4ccccc4c4ccccc43)n2)cc1]

The compounds utilized in the light emitting elements of Comparative Examples and Examples are shown in Table 1.

TABLE 1

| | |
|---|---|
| 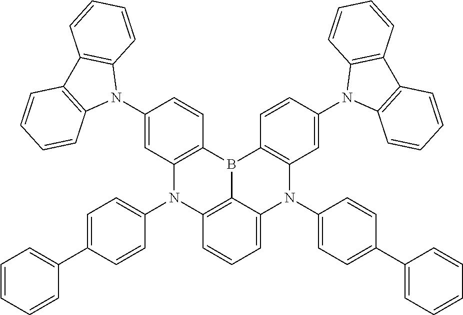 [SMILES: c1ccc(-c2ccc(N3c4cc(-n5c6ccccc6c6ccccc65)ccc4B4c5ccc(-n6c7ccccc7c7ccccc76)cc5N(c5ccc(-c6ccccc6)cc5)c5cccc3c54)cc2)cc1] 1 | Compound 1 |
| 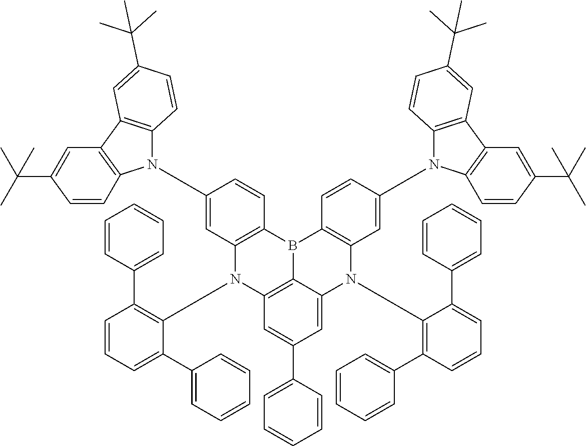 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1ccc(-n2c4ccc(C(C)(C)C)cc4c4cc(C(C)(C)C)ccc42)cc1N3c1c(-c2ccccc2)cccc1-c1ccccc1] 2 | Compound 2 |
| 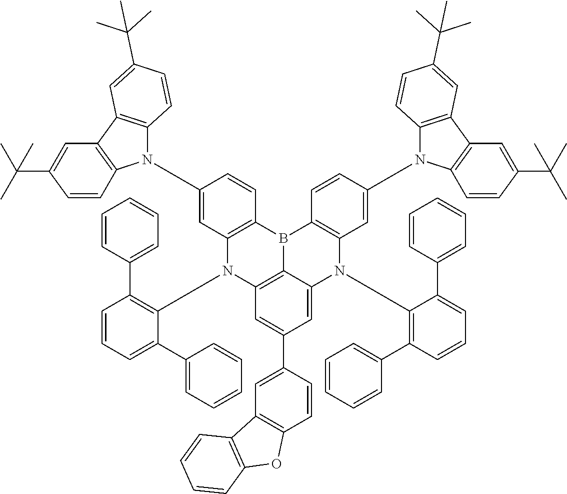 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-c3ccc4oc5ccccc5c4c3)cc3c1B2c1ccc(-n2c4ccc(C(C)(C)C)cc4c4cc(C(C)(C)C)ccc42)cc1N3c1c(-c2ccccc2)cccc1-c1ccccc1] 3 | Compound 3 |
| 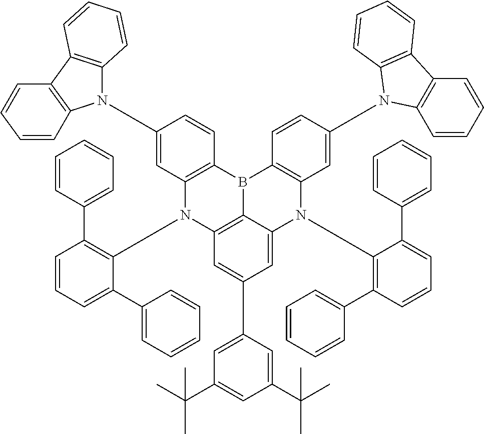 [SMILES: CC(C)(C)c1cc(-c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2N3c2c(-c3ccccc3)cccc2-c2ccccc2)cc(C(C)(C)C)c1] 4 | Compound 4 |
| 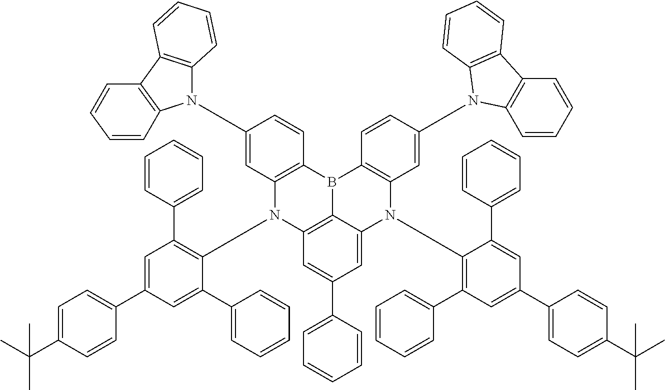 [SMILES: CC(C)(C)c1ccc(-c2cc(-c3ccccc3)c(N3c4cc(-n5c6ccccc6c6ccccc65)ccc4B4c5ccc(-n6c7ccccc7c7ccccc76)cc5N(c5c(-c6ccccc6)cc(-c6ccc(C(C)(C)C)cc6)cc5-c5ccccc5)c5cc(-c6ccccc6)cc3c54)c(-c3ccccc3)c2)cc1] 5 | Compound 5 |
| 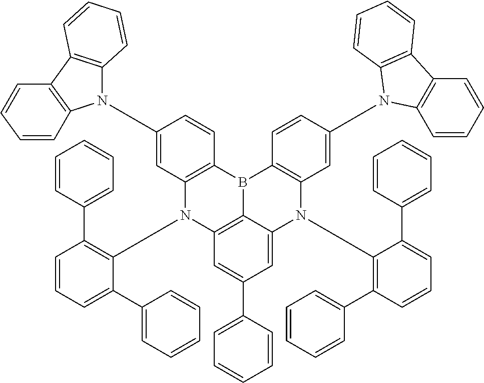 [SMILES: c1ccc(-c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2N3c2c(-c3ccccc3)cccc2-c2ccccc2)cc1] 6 | Compound 6 |
| 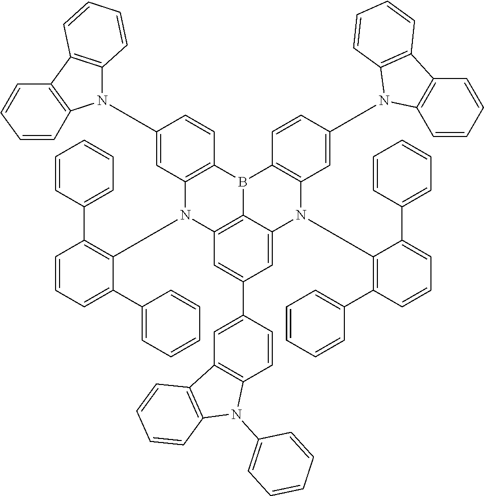 [SMILES: c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(-c5ccc6c(c5)c5ccccc5n6-c5ccccc5)cc2c43)cc1] 7 | Compound 7 |
| 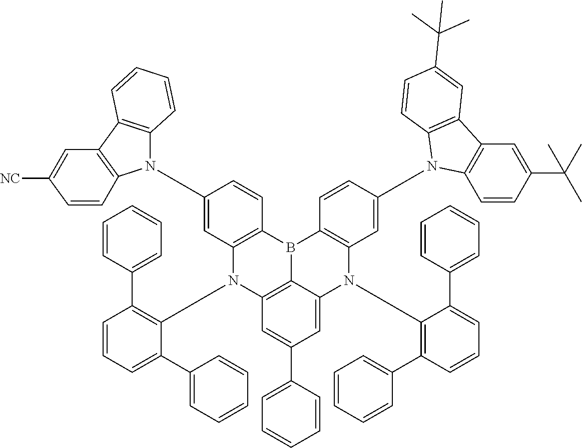 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1ccc(-n2c4ccccc4c4cc(C#N)ccc42)cc1N3c1c(-c2ccccc2)cccc1-c1ccccc1] 8 | Compound 8 |
| 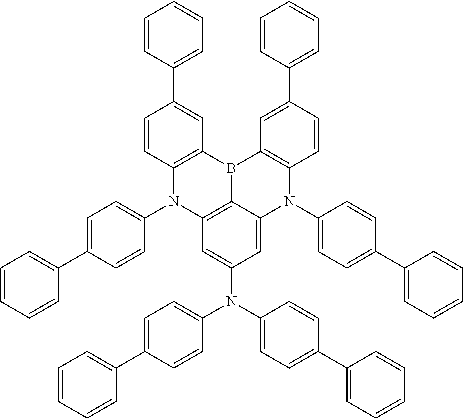 [SMILES: c1ccc(-c2ccc(N(c3ccc(-c4ccccc4)cc3)c3cc4c5c(c3)N(c3ccc(-c6ccccc6)cc3)c3ccc(-c6ccccc6)cc3B5c3cc(-c5ccccc5)ccc3N4c3ccc(-c4ccccc4)cc3)cc2)cc1] C1 | Comparative Example Compound C1 |
| 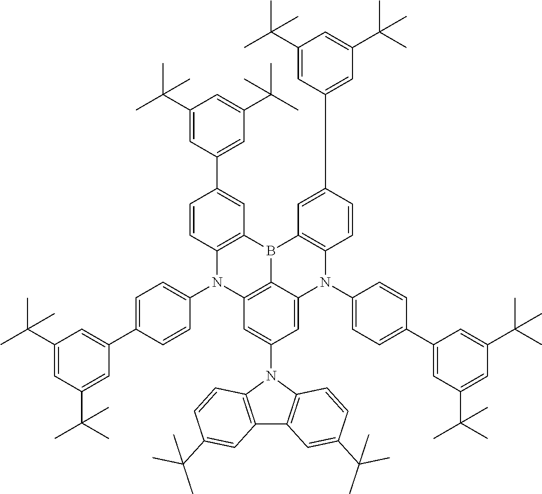 [SMILES: CC(C)(C)c1cc(-c2ccc(N3c4ccc(-c5cc(C(C)(C)C)cc(C(C)(C)C)c5)cc4B4c5cc(-c6cc(C(C)(C)C)cc(C(C)(C)C)c6)ccc5N(c5ccc(-c6cc(C(C)(C)C)cc(C(C)(C)C)c6)cc5)c5cc(-n6c7ccc(C(C)(C)C)cc7c7cc(C(C)(C)C)ccc76)cc3c54)cc2)cc(C(C)(C)C)c1] C2 | Comparative Example Compound C2 |
| 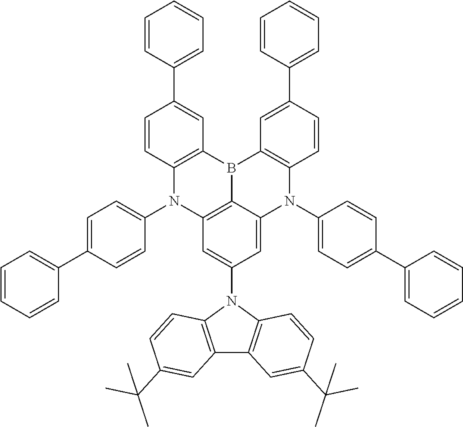 [SMILES: CC(C)(C)c1ccc2c(c1)c1cc(C(C)(C)C)ccc1n2-c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1] C3 | Comparative Example Compound C3 |
| 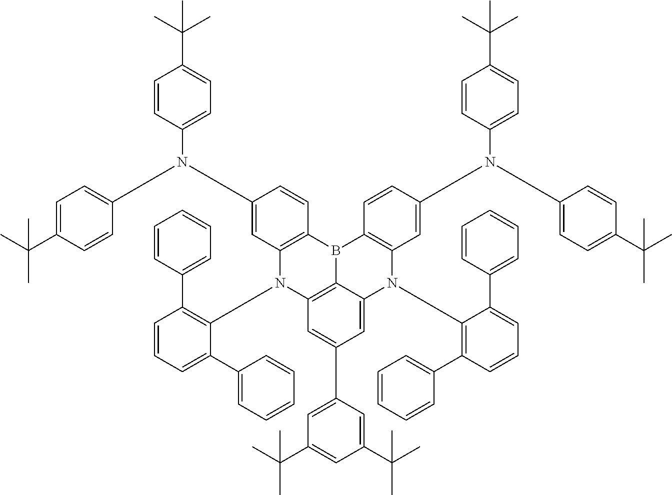 [SMILES: CC(C)(C)c1ccc(N(c2ccc(C(C)(C)C)cc2)c2ccc3c(c2)N(c2c(-c4ccccc4)cccc2-c2ccccc2)c2cc(-c4cc(C(C)(C)C)cc(C(C)(C)C)c4)cc4c2B3c2ccc(N(c3ccc(C(C)(C)C)cc3)c3ccc(C(C)(C)C)cc3)cc2N4c2c(-c3ccccc3)cccc2-c2ccccc2)cc1] C4 | Comparative Example Compound C4 |
| 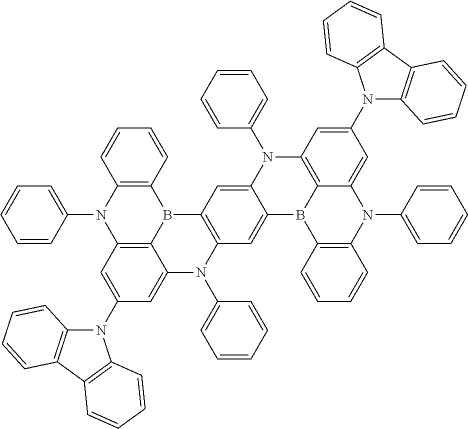 [SMILES: c1ccc(N2c3ccccc3B3c4cc5c(cc4N(c4ccccc4)c4cc(-n6c7ccccc7c7ccccc76)cc2c43)B2c3ccccc3N(c3ccccc3)c3cc(-n4c6ccccc6c6ccccc64)cc(c32)N5c2ccccc2)cc1] C5 | Comparative Example Compound C5 |
| 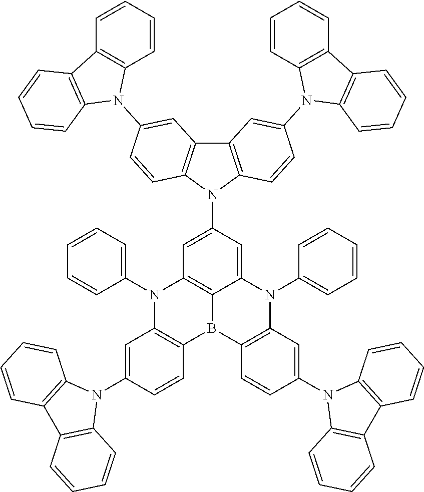 [SMILES: c1ccc(N2c3cc(-n4c5ccccc5c5ccccc54)ccc3B3c4ccc(-n5c6ccccc6c6ccccc65)cc4N(c4ccccc4)c4cc(-n5c6ccc(-n7c8ccccc8c8ccccc87)cc6c6cc(-n7c8ccccc8c8ccccc87)ccc65)cc2c43)cc1] C6 | Comparative Example Compound C6 |
| 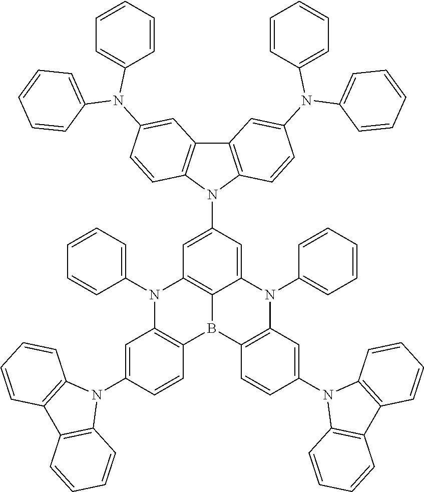 [SMILES: c1ccc(N(c2ccccc2)c2ccc3c(c2)c2cc(N(c4ccccc4)c4ccccc4)ccc2n3-c2cc3c4c(c2)N(c2ccccc2)c2cc(-n5c6ccccc6c6ccccc65)ccc2B4c2ccc(-n4c5ccccc5c5ccccc54)cc2N3c2ccccc2)cc1] C7 | Comparative Example Compound C7 |

—

### Evaluation of Light Emitting Element (HOD, Hole Only Device) 1

Table 2 shows the current values of the light emitting elements of Comparative Examples 1-1 to 1-8 and Examples 1-1 to 1-8 at a driving voltage of 7.5 V. When measuring current values in the light emitting elements of Comparative Examples and Examples, 2635A (Keithley Instruments, Inc.) device was utilized. Utilizing the current value measured in the light emitting element of Comparative Example 1-1 as the reference value, i.e., 100%, relative current values were shown in the light emitting elements of Comparative Examples and Examples. That is, Table 2 shows the current value of the light emitting elements of Comparative Examples and Examples as a relative percentage based on the current value of Comparative Example 1-1.

TABLE 2

| Example of element | | |
|---|---|---|
| manufacturing | Dopant | Current value (%) |
| Comparative Example 1- | None | 100 |
| 1 | | |
| Comparative Example 1- | Comparative Example | 8.4 |
| 2 | Compound C1 | |
| Comparative Example 1- | Comparative Example | 57.6 |
| 3 | Compound C2 | |
| Comparative Example 1- | Comparative Example | 74.1 |
| 4 | Compound C3 | |
| Comparative Example 1- | Comparative Example | 0.7 |
| 5 | Compound C4 | |
| Comparative Example 1- | Comparative Example | 55 |
| 6 | Compound C5 | |
| Comparative Example 1- | Comparative Example | 120 |
| 7 | Compound C6 | |
| Comparative Example 1- | Comparative Example | 20 |
| 8 | Compound C7 | |
| Example 1-1 | Compound 1 | 95.8 |
| Example 1-2 | Compound 2 | 97.5 |
| Example 1-3 | Compound 3 | 95.8 |
| Example 1-4 | Compound 4 | 105.4 |
| Example 1-5 | Compound 5 | 107.7 |
| Example 1-6 | Compound 6 | 100.9 |
| Example 1-7 | Compound 7 | 121.2 |
| Example 1-8 | Compound 8 | 108.5 |

Referring to Table 2, it is seen that compared to the light emitting elements of Comparative Examples 1-2 to 1-6 and 1-8, the light emitting elements of Comparative Examples 1-7 and Examples 1-1 to 1-8 each have a relative current value of 90% or more. In addition, it is seen that the light emitting element of Example 1-7 has a higher relative current value than the light emitting element of Comparative Example 1-7.

The light emitting elements of Examples 1-1 to 1-8 include compounds 1 to 8 according to embodiments of the present disclosure, and the compounds 1 to 8 are delayed fluorescent dopants including two or more carbazole groups. The delayed fluorescent dopants including two or more carbazole groups have relatively small hole trapping properties, and thus, current flow in the light emitting elements including the delayed fluorescent dopants may be relatively more active. Accordingly, the light emitting elements including the delayed fluorescent dopants according to the embodiments may each have a relative current value of 90% or more with reference to the light emitting element of Comparative Example 1.

The light emitting elements of Comparative Examples 1-2 to 1-8 include Comparative Example compounds C1 to C7 respectively. Comparative Example compounds C1 and C4 do not include a carbazole group, and Comparative Example compounds C2 and C3 each include just one carbazole group. Comparative Example compound C7 includes three carbazole groups. Comparative Example compound C5 includes two carbazole groups, but include a fused ring of nine rings containing four nitrogen atoms and two boron atoms as ring-forming atoms, as a central structure. Without being bound by any particular theory, it is believed that the light emitting elements of Comparative Examples 1-2 to 1-6 and 1-8 exhibited a relative current value of 75% or less due to the relatively large hole trapping properties of the Comparative Example compounds C1 to C5 and C7.

### 2. Manufacture and Evaluation of Light Emitting Elements 2

### (2) Manufacture of Light Emitting Elements 2

A light emitting element including a delayed fluorescent dopant according to an embodiment or one of the Comparative Example compounds was manufactured through a method below. The light emitting elements of Examples 2-1 to 2-8 were manufactured utilizing compounds 1 to 8 according to embodiments of the present disclosure as a delayed fluorescent dopant material of an emission layer. The light emitting elements of Comparative Examples 2-1 to 2-7 were manufactured utilizing Comparative Example compounds C1 to C7 as a dopant material of an emission layer, respectively.

As an anode, a glass substrate having an ITO electrode (Corning Incorporated, 15 Ω/cm², 1200 Å) formed thereon was cut to a size of about 50 mm×50 mm×0.7 mm, subjected to ultrasonic cleaning utilizing isopropyl alcohol and pure water for 5 minutes respectively and ultraviolet irradiation for 30 minutes, and then exposed to ozone for cleaning to be mounted on a vacuum deposition apparatus.

HAT-CN was deposited to be 100 Å thick on the anode to form a hole injection layer. NPB was deposited to be 500 Å thick on the hole injection layer to form a hole transport layer, and Compound HT-08 according to an embodiment of the present disclosure was deposited to be 100 Å thick on the hole transport layer to form a buffer layer of a hole transport region.

Then, a host, a phosphorescent sensitizer, and a dopant were co-deposited at a weight ratio of 89.5:10.0:0.5 to form an emission layer having a thickness of 400 Å. For the host, compounds HT-08 and ET-05 according to an embodiment of the present disclosure were provided in a weight ratio of 1:1. For the phosphorescent sensitizer, compound PD-8 according to an embodiment of the present disclosure was utilized.

Compound ET-05 according to an embodiment of the present disclosure was deposited to be 100 Å thick on the emission layer to form a buffer layer of an electron transport region, and Liq and compound ET2 according to an embodiment of the present disclosure were co-deposited on the buffer layer in a weight ratio of 5:5 to form an electron transport layer having a thickness of 300 Å. Then, magnesium (Mg) was utilized to form a second electrode having a thickness of 1000 Å. In an embodiment, the hole injection layer, the hole transport layer, the buffer layer in the hole transport region, the emission layer, the electron transport layer, the buffer layer in the electron transport region, and the second electrode were formed utilizing a vacuum deposition apparatus.

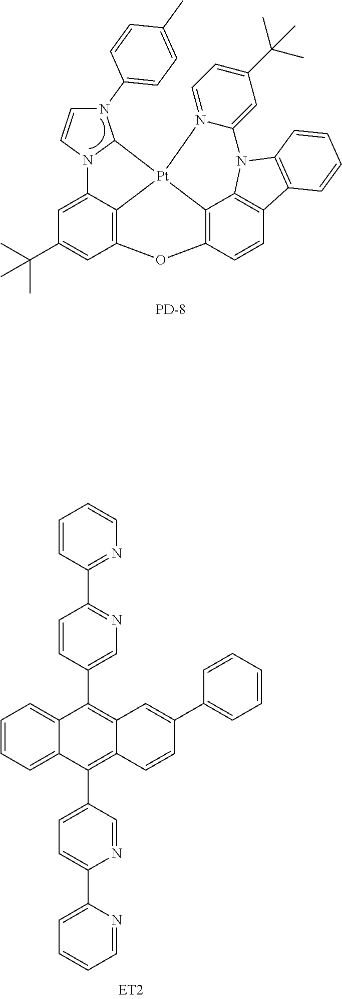

### (3) Evaluation of Light Emitting Elements 2

Table 3 shows the lifespan measured for the light emitting elements of Comparative Examples 2-1 to 2-7 and Examples 2-1 to 2-8. For the lifespan of the light emitting elements, the time taken for the initial luminance to decrease to 95% of the initial luminance was measured with respect to a luminance of 1000 cd/m2. Utilizing the lifespan of Comparative Example 2-3 as the reference value, i.e., 100%, Table 3 shows the relative lifespan of Comparative Examples and Examples. That is, Table 3 shows the lifespan of the light emitting elements of Comparative Examples and Examples as a relative percentage based on the lifespan of Comparative Example 2-3.

TABLE 3

| Example of element | | |
|---|---|---|
| manufacturing | Dopant | Lifespan (%) |
| Comparative | Comparative | 43 |
| Examples 2-1 | Example Compound | |
| | C1 | |
| Comparative | Comparative | 88 |
| Examples 2-2 | Example Compound | |
| | C2 | |
| Comparative | Comparative | 100 |
| Examples 2-3 | Example Compound | |
| | C3 | |
| Comparative | Comparative | 62 |
| Examples 2-4 | Example Compound | |
| | C4 | |
| Comparative | Comparative | 56 |
| Examples 2-5 | Example Compound | |
| | C5 | |
| Comparative | Comparative | 120 |
| Examples 2-6 | Example Compound | |
| | C6 | |
| Comparative | Comparative | 50 |
| Examples 2-7 | Example Compound | |
| | C7 | |
| Example 2-1 | Compound 1 | 119 |
| Example 2-2 | Compound 2 | 123 |
| Example 2-3 | Compound 3 | 137 |
| Example 2-4 | Compound 4 | 136 |
| Example 2-5 | Compound 5 | 115 |
| Example 2-6 | Compound 6 | 111 |
| Example 2-7 | Compound 7 | 135 |
| Example 2-8 | Compound 8 | 111 |

Referring to Table 3, it is seen that compared to the light emitting elements of Comparative Examples 2-1 to 2-5 and 2-7, the light emitting elements of Comparative Examples 2-6 and Examples 2-1 to 2-8 each have excellent or suitable lifespan. In addition, it is be seen that the light emitting elements of Examples 2-2 to 2-4 and 2-7 have excellent or suitable element lifespan compared to the light emitting element of Comparative Example 2-6.

The light emitting elements of Examples 2-1 to 2-8 include compounds 1 to 8 according to embodiments of the present disclosure, respectively, and the compounds 1 to 8 according to embodiments of the present disclosure are delayed fluorescent dopants including two or more substituted or unsubstituted carbazole groups. The delayed fluorescent dopant including two or more substituted or unsubstituted carbazole groups may prevent or reduce deterioration of the dopant. Accordingly, the light emitting element including the delayed fluorescent dopant according to an embodiment may exhibit long lifespan.

### 3. Evaluation of Compound Characteristics

Table 4 shows the HOMO energy level values of Comparative Example compounds C1 to C7, compounds 1 to 8 according to embodiments of the present disclosure, and compound HT-08 according to an embodiment of the present disclosure. The HOMO energy level values were calculated through a non-empirical molecular orbital method. Specifically, the HOMO energy level values were calculated with B3LYP/6-31 G(d) utilizing Gaussian 09 from Gaussian.

TABLE 4

| Compound | HOMO(eV) |
|---|---|
| HT-08 | −5.13 |
| Comparative Example Compound C1 | −5.01 |
| Comparative Example Compound C2 | −5.03 |
| Comparative Example Compound C3 | −5.12 |
| Comparative Example Compound C4 | −4.78 |
| Comparative Example Compound C5 | −4.87 |
| Comparative Example Compound C6 | −5.47 |
| Comparative Example Compound C7 | −4.91 |
| Compound 1 | −5.25 |
| Compound 2 | −5.18 |
| Compound 3 | −5.19 |
| Compound 4 | −5.24 |
| Compound 5 | −5.23 |
| Compound 6 | −5.27 |
| Compound 7 | −5.21 |
| Compound 8 | −5.35 |

Referring to Table 4, it is be seen that the compounds 1 to 8 according to an embodiment of the present disclosure have a greater absolute value of the HOMO energy level than HT-08, which is a material of a hole transporting host. In addition, it is seen that a difference in absolute values of the HOMO energy level between the compounds 1 to 8 according to embodiments of the present disclosure and the hole transporting host HT-08 is 0.05 eV to 0.22 eV. The compounds 1 to 8 according to embodiments of the present disclosure are delayed fluorescent dopants containing two or more substituted or unsubstituted carbazole groups. Accordingly, the delayed fluorescent dopant including two or more carbazole groups may have a greater absolute value of the HOMO energy level than the hole transporting host.

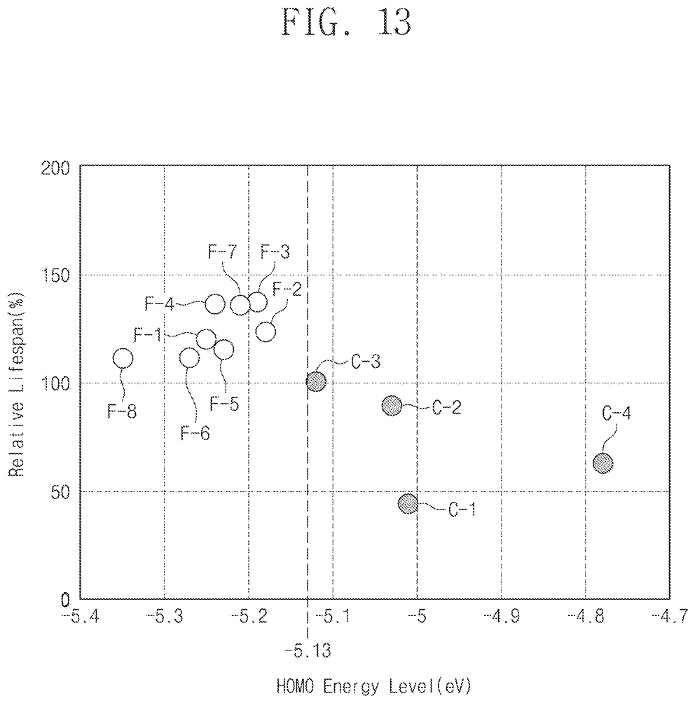

A difference in absolute values of the HOMO energy level between Comparative Example compound C6 and the hole transporting host HT-08 is 0.34. It is seen that Comparative Example compounds C1 to C5, and C7 have an absolute value of the HOMO energy level which is the same as or smaller than that of HT-08, a hole transporting host material. Comparative Example compounds C1 and C4 do not include a carbazole group, and Comparative Example compounds C2 and C3 each include only one carbazole group. Unlike the compounds according to embodiments of the present disclosure including a fused ring of five rings as a central structure, Comparative Example compound C5 includes a fused ring of nine rings as a central structure, and Comparative Example compound C7 includes three carbazole groups. Accordingly, it is believed and confirmed that the compounds C1 to C5 and C7 of Comparative Examples have small absolute values of the HOMO energy levels. FIG. 12 shows current values and lifespan of light emitting elements of Comparative Examples and Examples. More specifically, FIG. 12 shows the current values of Table 2 and the lifespans of Table 3, and light emitting elements of Comparative Examples and Examples having the same dopant material are each indicated as a single circle (as explained in more detail below).

In FIG. 12, ER-1 to ER-4 correspond to the light emitting elements of Comparative Examples. EE-1 to EE-8 correspond to the light emitting elements of Examples.

ER-1 corresponds to the light emitting elements of Comparative Example 1-2 of Table 2 and Comparative Example 2-1 of Table 3 including Comparative Example compound C1. ER-2 corresponds to the light emitting elements of Comparative Example 1-3 of Table 2 and Comparative Example 2-2 of Table 3 including Comparative Example compound C2. ER-3 corresponds to the light emitting elements of Comparative Example 1-4 of Table 2 and Comparative Example 2-3 of Table 3 including Comparative Example compound C3. ER-4 corresponds to the light emitting elements of Comparative Example 1-5 of Table 2 and Comparative Example 2-4 of Table 3 including Comparative Example compound C4.

EE-1 corresponds to the light emitting elements of Example 1-1 of Table 2 and Example 2-1 of Table 3 including compound 1 according to an embodiment of the present disclosure. EE-2 corresponds to the light emitting elements of Example 1-2 of Table 2 and Example 2-2 of Table 3 including compound 2 according to embodiments of the present disclosure. EE-3 corresponds to the light emitting elements of Example 1-3 of Table 2 and Example 2-3 of Table 3 including compound 3 according to embodiments of the present disclosure. EE-4 corresponds to the light emitting elements of Example 1-4 of Table 2 and Example 2-4 of Table 3 including compound 4 according to embodiments of the present disclosure.

EE-5 corresponds to the light emitting elements of Example 1-5 of Table 2 and Example 2-5 of Table 3 including compound 5 according to embodiments of the present disclosure. EE-6 corresponds to the light emitting elements of Example 1-6 of Table 2 and Example 2-6 of Table 3 including compound 6 according to embodiments of the present disclosure. EE-7 corresponds to the light emitting elements of Example 1-7 of Table 2 and Example 2-7 of Table 3 including compound 7 according to embodiments of the present disclosure. EE-8 corresponds to the light emitting elements of Example 1-8 of Table 2 and Example 2-8 of Table 3 including compound 8 according to embodiments of the present disclosure.

In FIG. 12, it was confirmed that R² (indicating the correlation between the current value and the lifespan) was 0.86. When R² is closer to 1, the correlation becomes higher, and it is seen that there is a high correlation between the current value and the lifespan. Accordingly, the light emitting element according to an embodiment exhibiting a current value of 90% or more may have increased lifespan.

FIG. 13 shows the HOMO energy level value of compounds and the lifespan of light emitting elements. More specifically, FIG. 13 shows the lifespan of the light emitting elements of Table 3 and the HOMO energy level value of the compounds of Table 4, and a light emitting elements including the compound of Table 4 and the same dopant material as the compound of Table 4 are each shown as a single circle.

In FIG. 13, C-1 to C-4 correspond to the light emitting elements of Comparative Example compounds and light emitting elements. F-1 to F-8 correspond to the light emitting elements of Compounds of an embodiment of the present disclosure and light emitting elements of Examples.

C-1 corresponds to compound C1 of Comparative Example of Table 4 and the light emitting element of Comparative Example 2-1 of Table 3. C-2 corresponds to compound C2 of Comparative Example of Table 4 and the light emitting element of Comparative Example 2-2 of Table 3. C-3 corresponds to the compound C3 of Comparative Example of Table 4 and the light emitting element of Comparative Example 2-3 of Table 3. C-4 corresponds to the compound C4 of Comparative Example of Table 4 and the light emitting element of Comparative Example 2-4 of Table 3.

F-1 corresponds to compound 1 of Table 4 and the light emitting element of Example 2-1 of Table 3. F-2 corresponds to compound 2 of Table 4 and the light emitting element of Example 2-2 of Table 3. F-3 corresponds to compound 3 of Table 4 and the light emitting element of Example 2-3 of Table 3. F-4 corresponds to compound 4 of Table 4 and the light emitting element of Example 2-4 of Table 3.

F-5 corresponds to compound 5 of Table 4 and the light emitting element of Example 2-5 of Table 3. F-6 corresponds to compound 6 of Table 4 and the light emitting element of Example 2-6 of Table 3. F-7 corresponds to compound 7 of Table 4 and the light emitting element of Example 2-7 of Table 3. F-8 corresponds to compound 8 of Table 4 and the light emitting element of Example 2-8 of Table 3.

In FIG. 13, it was confirmed that R² (indicating the correlation between the HOMO energy level and the lifespan) was 0.56. When R² is closer to 1, the correlation becomes higher, and it is seen that there is a satisfactory correlation between the HOMO energy level and the lifespan. Accordingly, the light emitting element of an embodiment including the delayed fluorescent dopant having an absolute value of the HOMO energy level greater than that of the hole transporting host should exhibit increased lifespan.

A light emitting element according to an embodiment may include a hole transporting host, an electron transporting host, a phosphorescent sensitizer, and a delayed fluorescent dopant in an emission layer. The hole transporting host may include a carbazole derivative, and the electron transporting host may include a heterocyclic group containing a nitrogen atom as a ring-forming atom. The phosphorescent sensitizer may include a metal complex containing platinum or iridium. The delayed fluorescent dopant may include two or more substituted or unsubstituted carbazole groups. The substituted or unsubstituted carbazole group may be directly or indirectly bonded to a fused ring of five rings including two N's and one B as ring-forming atoms. The delayed fluorescent dopant may have a greater absolute value of the HOMO energy level than the hole transporting host. Accordingly, the delayed fluorescent dopant according to an embodiment may have reduced hole trapping properties, and the light emitting element including the delayed fluorescent dopant may exhibit increased lifespan.

A light emitting element according to an embodiment may include a delayed fluorescent dopant having a large absolute value of the HOMO energy level to exhibit long lifespan.

In addition, a light emitting element according to an embodiment includes a delayed fluorescent dopant having a plurality of (e.g., two or more) carbazole groups to exhibit long lifespan.

As used herein, expressions such as “at least one of”, “one of”, and “selected from”, when preceding a list of elements, modify the entire list of elements and do not modify the individual elements of the list. For example, “at least one of a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the terms “substantially,” “about,” and similar terms are used as terms of approximation and not as terms of degree, and are intended to account for the inherent deviations in measured or calculated values that would be recognized by those of ordinary skill in the art. Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic apparatus and/or any other relevant devices or components according to embodiments of the present invention described herein may be implemented utilizing any suitable hardware, firmware (e.g. an application-specific integrated circuit), software, or a combination of software, firmware, and hardware. For example, the various components of the apparatus may be formed on one integrated circuit (IC) chip or on separate IC chips. Further, the various components of the [device] may be implemented on a flexible printed circuit film, a tape carrier package (TCP), a printed circuit board (PCB), or formed on one substrate. Further, the various components of the apparatus may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments.

Although the present disclosure has been described with reference to a preferred embodiment of the present disclosure, it will be understood that the present disclosure should not be limited to these preferred embodiments but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A light emitting element comprising:
a first electrode;
a second electrode on the first electrode; and
an emission layer between the first electrode and the second electrode and comprising a hole transporting host, an electron transporting host, a phosphorescent sensitizer, and a delayed fluorescent dopant,
wherein the hole transporting host has a lower absolute value of a Highest Occupied Molecular Orbital (HOMO) energy level than the delayed fluorescent dopant.

2. The light emitting element of claim 1, wherein the delayed fluorescent dopant is represented by Formula 1: 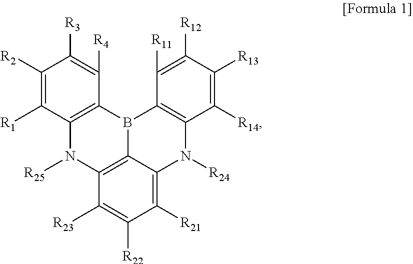
wherein in Formula 1,
two or more of R₁ to R₄, R₁₁ to R₁₄, and R₂₁ to R₂₅ each independently comprise a substituted or unsubstituted carbazole group, and the rest of R₁ to R₄, R₁₁ to R₁₄, and R₂₁ to R₂₅ are each independently a hydrogen atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms, and
when R₁ to R₄, R₁₁ to R₁₄, and/or R₂₁ to R₂₅ each independently comprises a substituted carbazole group, a substituent of the substituted carbazole group is selected from a cyano group, a substituted or unsubstituted alkyl group having 1 to 10 carbon atoms, and a substituted or unsubstituted aryl group having 6 to 30 ring-forming carbon atoms.

3. The light emitting element of claim 2, wherein R₁ to R₄, R₁₁ to R₁₄, and R₂₁ to R₂₅ are each independently represented by any one among groups R₁-1 to R₁-13:

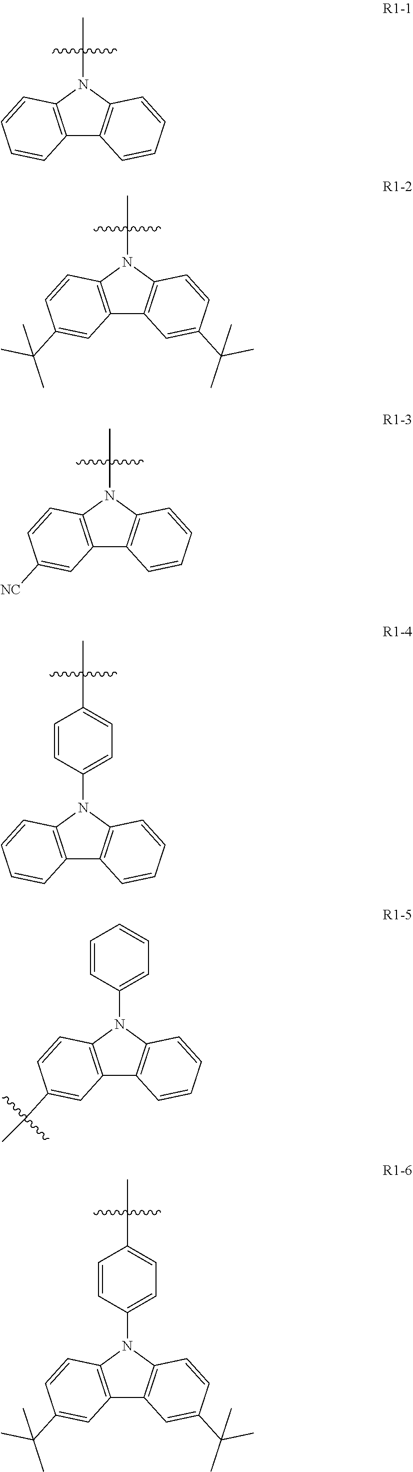

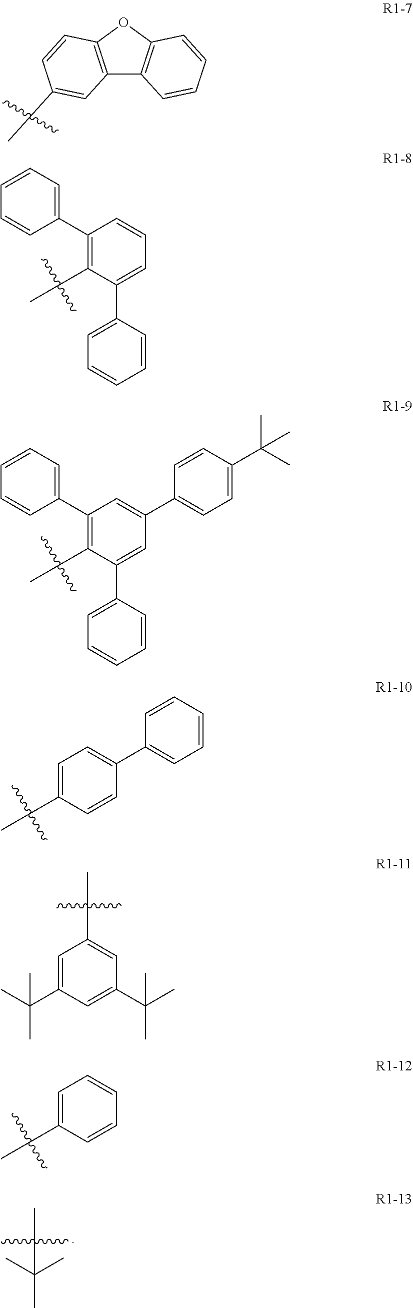

4. The light emitting element of claim 1, wherein the delayed fluorescent dopant is a multiple resonance (MR) delayed fluorescent dopant.

5. The light emitting element of claim 1, wherein the phosphorescent sensitizer has a lower absolute value of the HOMO energy level than each of the hole transporting host and the delayed fluorescent dopant.

6. The light emitting element of claim 1, wherein a difference in absolute value of the HOMO energy level between the hole transporting host and the delayed fluorescent dopant is about 0.05 eV to about 0.22 eV.

7. The light emitting element of claim 1, wherein the light emitting element satisfies Expression A-1:
E_{I}≥C_{I}×0.9 [Expression A-1]
wherein in Expression A-1,
E_{I} is a current value at a driving voltage of 7.5 V of a first hole only device (HOD) comprising a first emission layer containing the hole transporting host, the electron transporting host, and the delayed fluorescent dopant,
C_{I} is a current value at a driving voltage of 7.5 V of a second hole only device (HOD) comprising a second emission layer containing the hole transporting host and the electron transporting host without the delayed fluorescent dopant,
the first hole only device comprises the first electrode, the second electrode on the first electrode, the first emission layer between the first electrode and the second electrode, a first hole transport region between the first electrode and the first emission layer, and a second hole transport region between the first emission layer and the second electrode, and
the second hole only device comprises the first electrode, the second electrode on the first electrode, the second emission layer between the first electrode and the second electrode, the first hole transport region between the first electrode and the second emission layer, and the second hole transport region between the second emission layer and the second electrode.

8. The light emitting element of claim 1, wherein the delayed fluorescent dopant comprises any one among compounds of Compound Group 1:

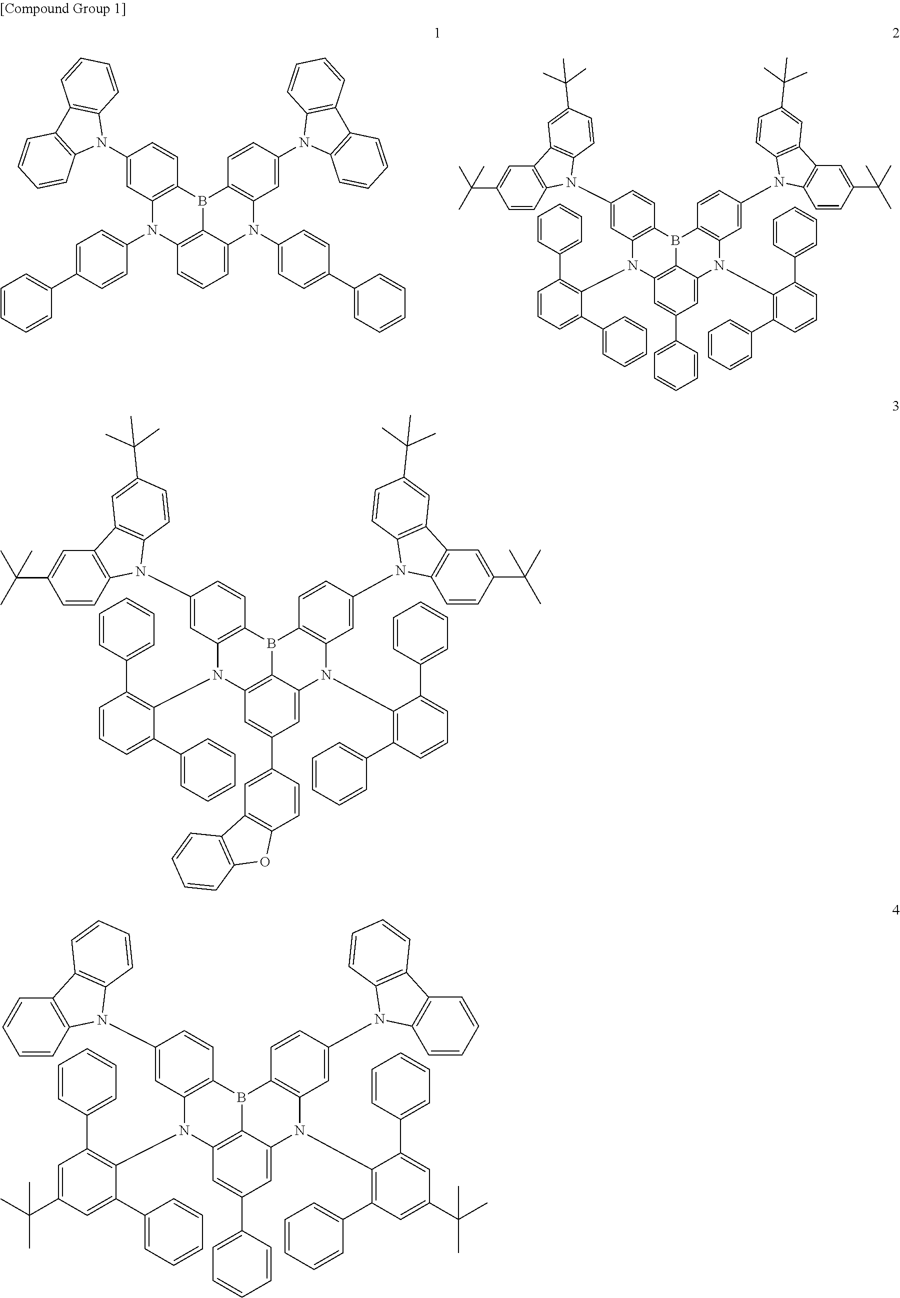

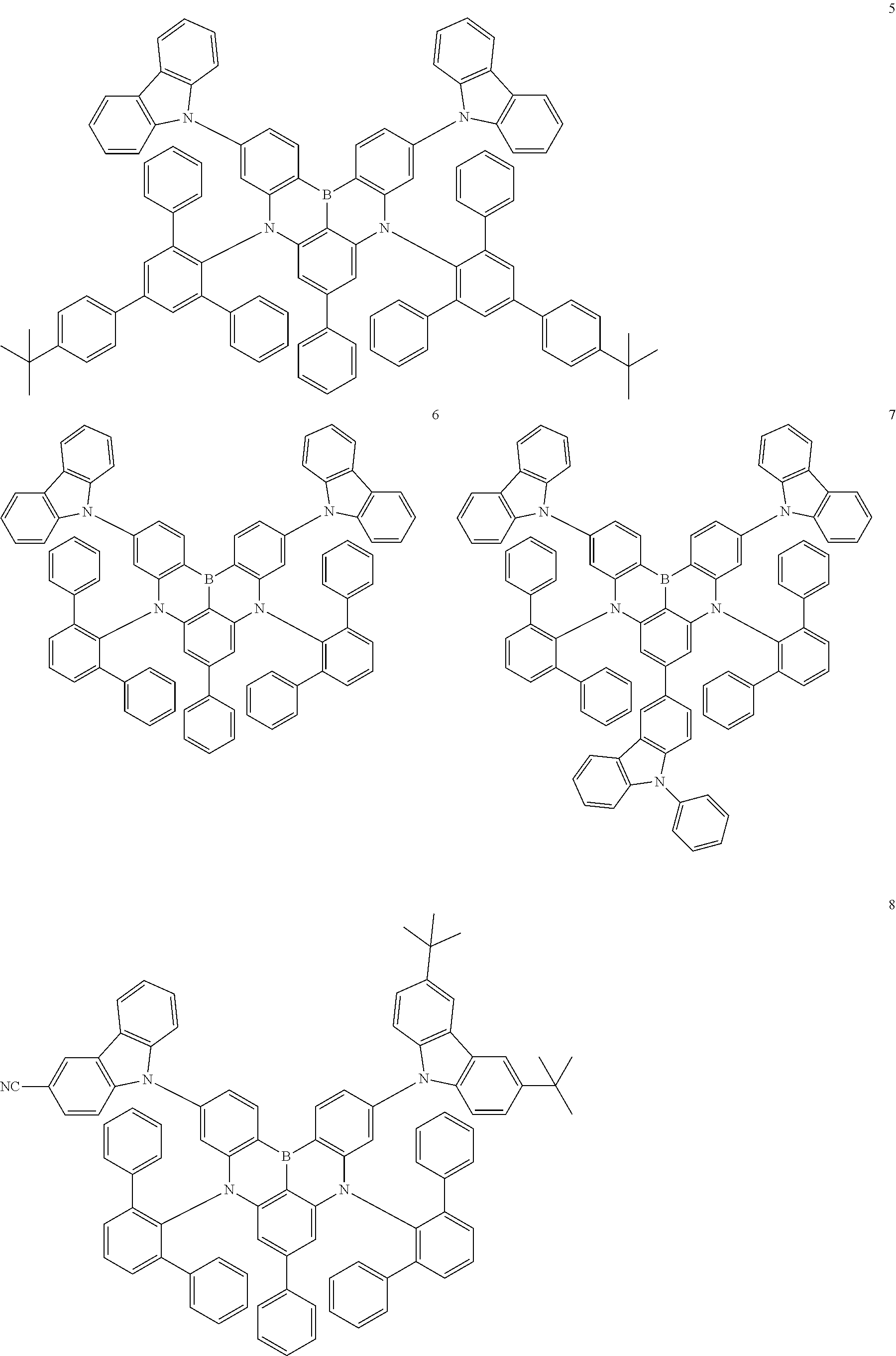

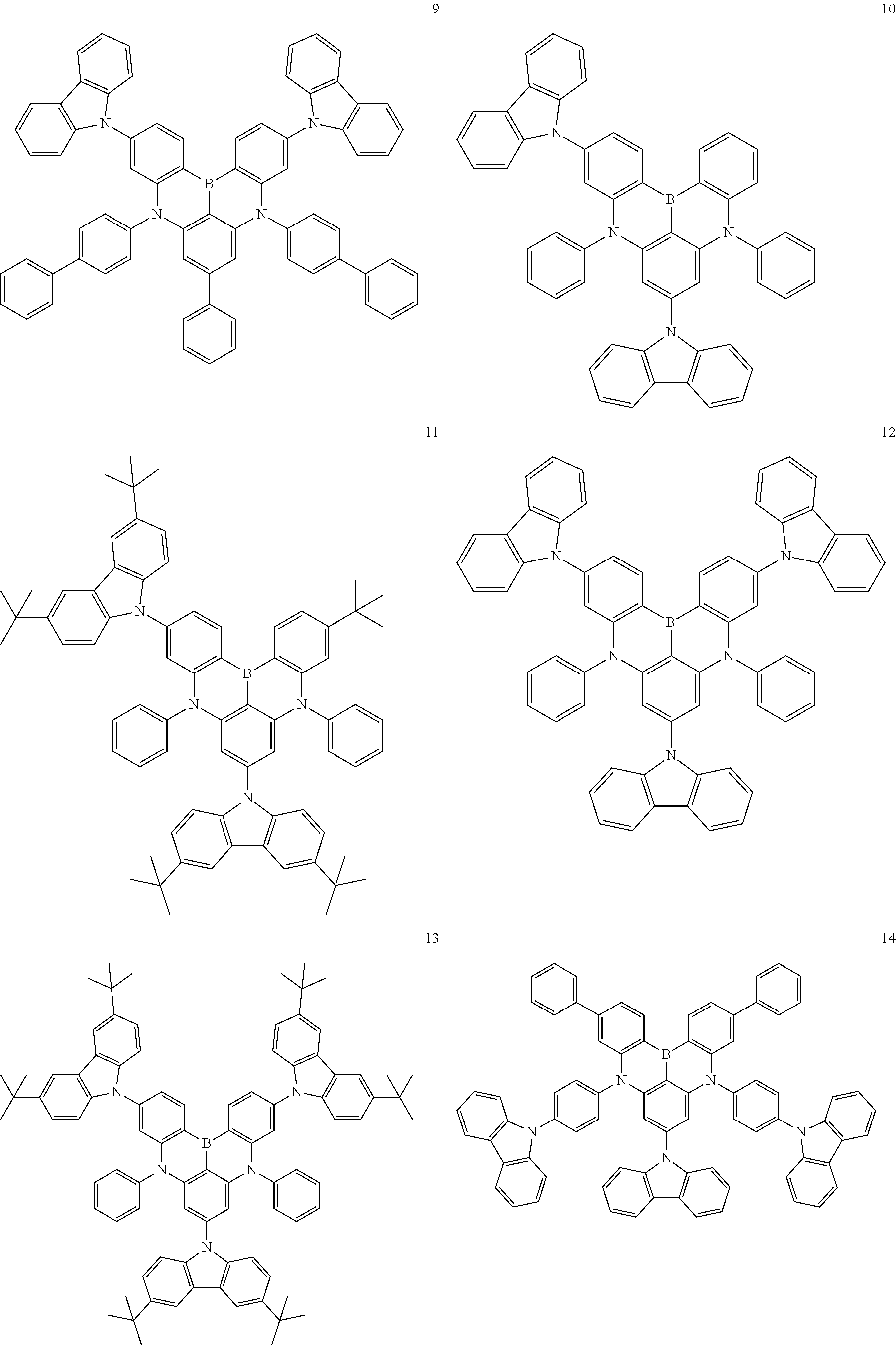

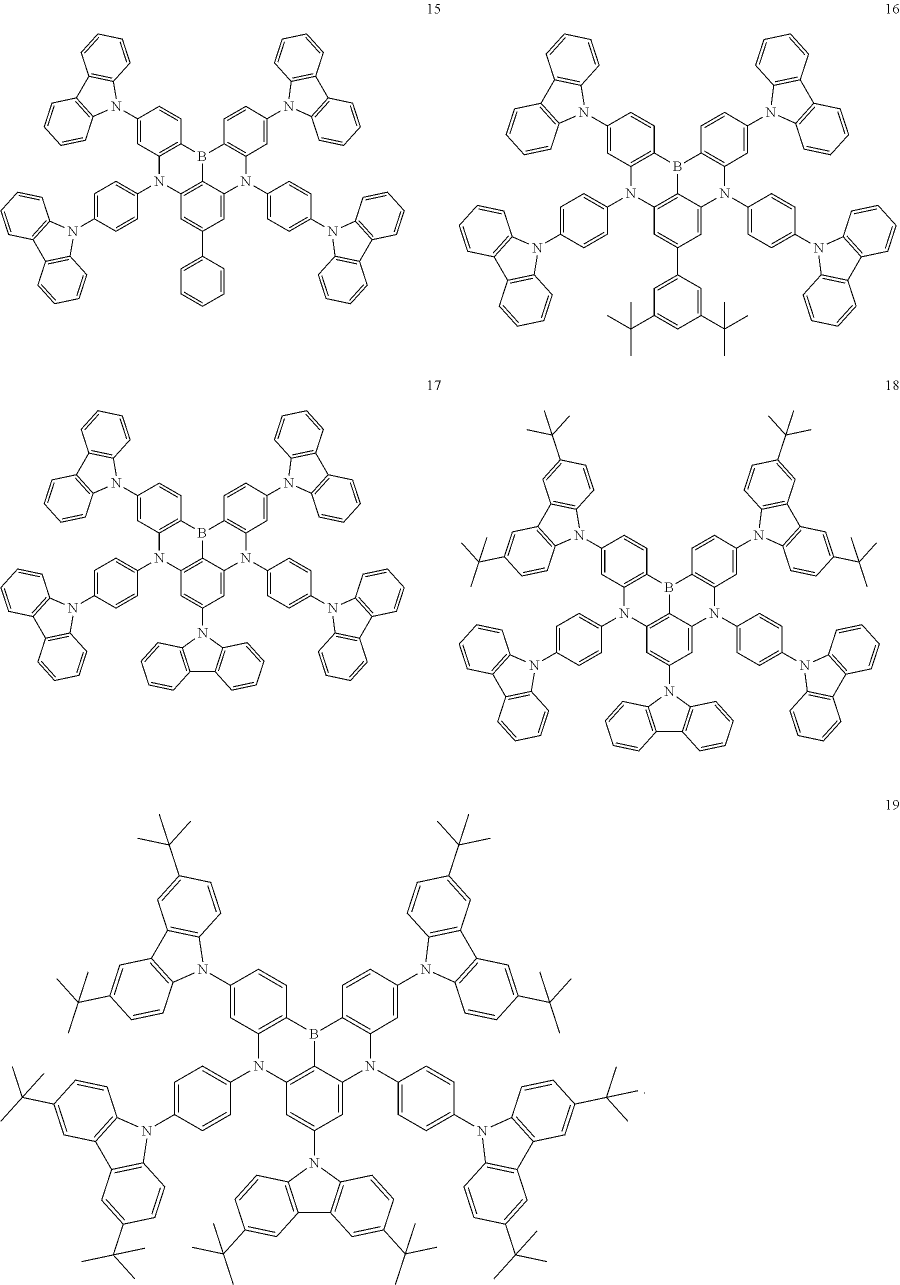

9. The light emitting element of claim 1, wherein the hole transporting host is represented by Formula HT-1: 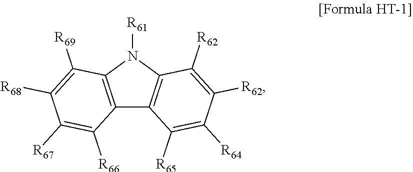
wherein in Formula HT-1,
one among R₆₁ to R₆₉ comprises a substituted or unsubstituted carbazole group, and the rest among R₆₁ to R₆₉ are each independently a hydrogen atom, a substituted or unsubstituted aryl group having 6 to 20 ring-forming carbon atoms, or a substituted or unsubstituted heteroaryl group having 2 to 20 ring-forming carbon atoms.

10. The light emitting element of claim 1, wherein the electron transporting host is represented by Formula ET-1: 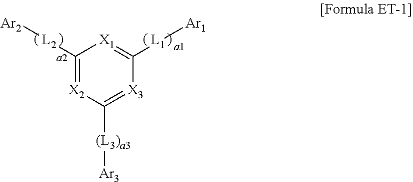
wherein in Formula ET-1,
at least one of X₁ to X₃ is N and the rest of X₁ to X₃ are each independently CRₐ,
Rₐ is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a1 to a3 are each independently an integer of 0 to 10,
L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₁ to Ar₃ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

11. The light emitting element of claim 1, wherein the hole transporting host comprises any one among compounds of Compound Group 2, and the electron transporting host comprises any one among compounds of Compound Group 3:

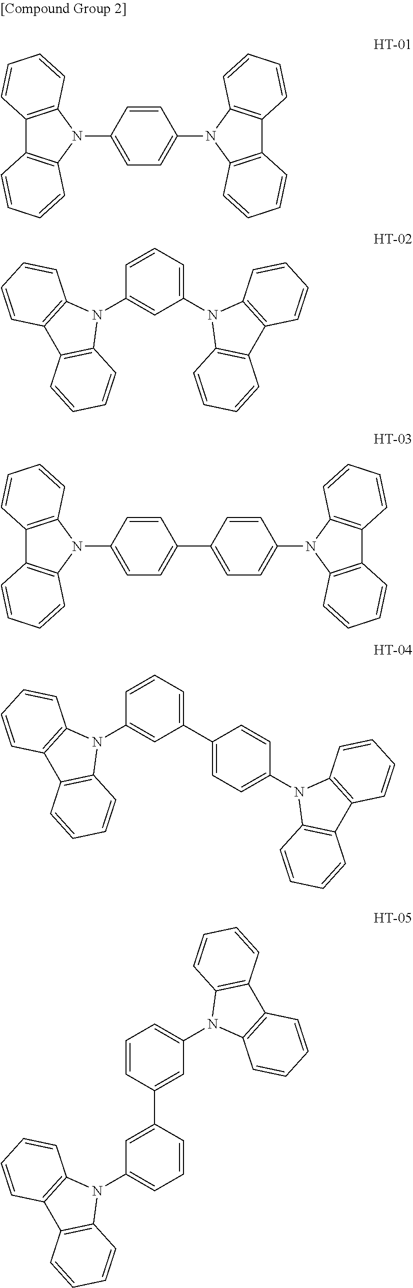 [SMILES: c1ccc2c(c1)c1ccccc1n2-c1ccc(-n2c3ccccc3c3ccccc32)cc1 ; c1cc(-n2c3ccccc3c3ccccc32)cc(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-c2ccc(-n3c4ccccc4c4ccccc43)cc2)cc(-n2c3ccccc3c3ccccc32)c1 ; c1cc(-c2cccc(-n3c4ccccc4c4ccccc43)c2)cc(-n2c3ccccc3c3ccccc32)c1]

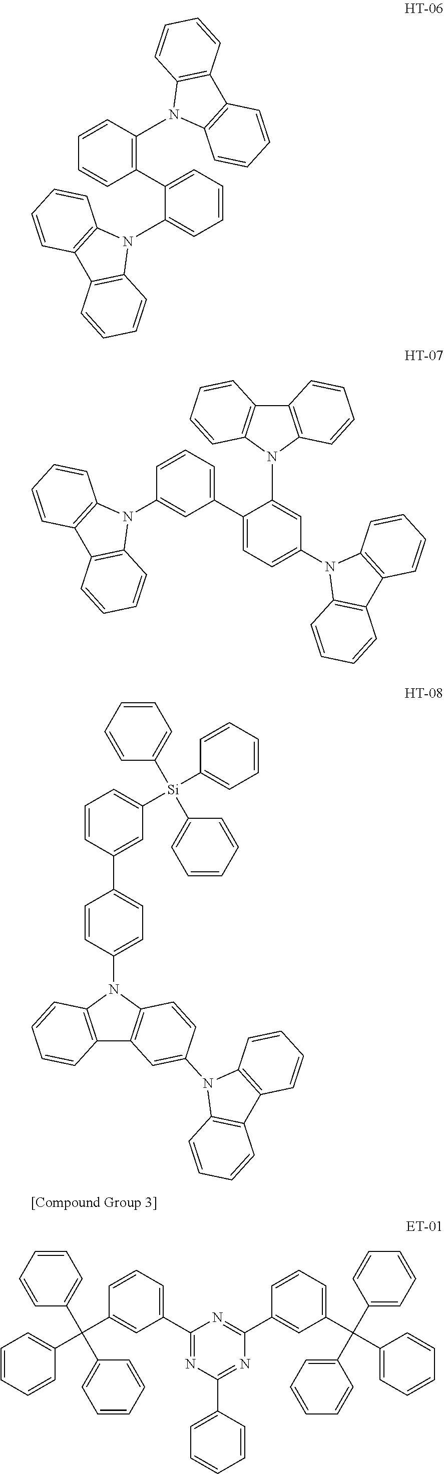 [SMILES: c1ccc(-n2c3ccccc3c3ccccc32)c(-c2ccccc2-n2c3ccccc3c3ccccc32)c1 ; c1cc(-c2ccc(-n3c4ccccc4c4ccccc43)cc2-n2c3ccccc3c3ccccc32)cc(-n2c3ccccc3c3ccccc32)c1 ; c1ccc([Si](c2ccccc2)(c2ccccc2)c2cccc(-c3ccc(-n4c5ccccc5c5cc(-n6c7ccccc7c7ccccc76)ccc54)cc3)c2)cc1 ; c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1]

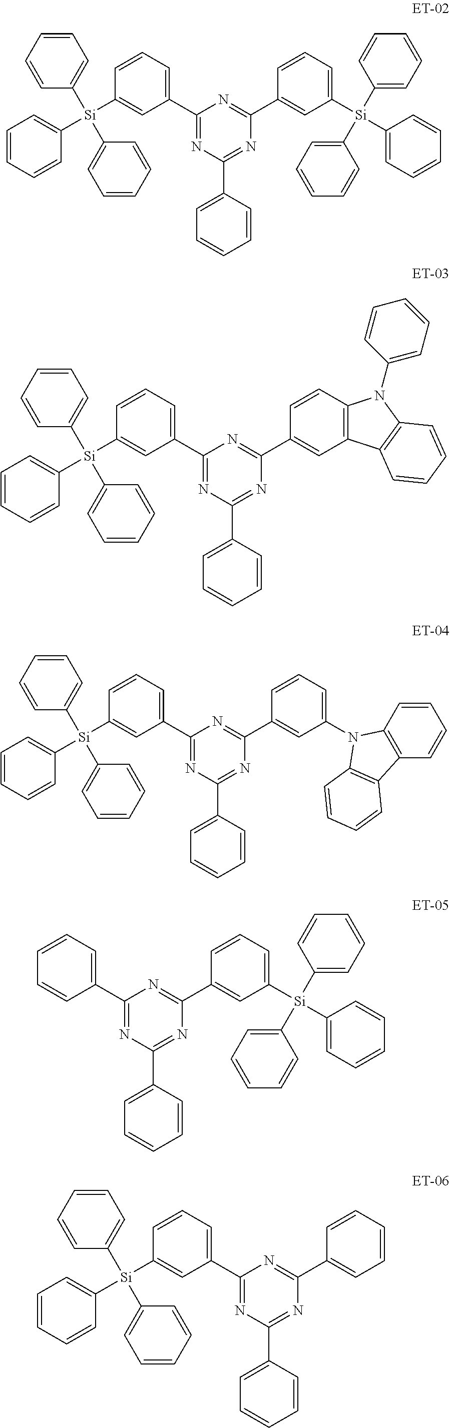 [SMILES: c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3ccc4c(c3)c3ccccc3n4-c3ccccc3)n2)cc1 ; c1ccc(-c2nc(-c3cccc(-n4c5ccccc5c5ccccc54)c3)nc(-c3cccc([Si](c4ccccc4)(c4ccccc4)c4ccccc4)c3)n2)cc1 ; c1ccc(-c2nc(-c3ccccc3)nc(-c3cccc([Si](c4ccccc4)(c4ccccc4)c4ccccc4)c3)n2)cc1 ; c1ccc(-c2nc(-c3ccccc3)nc(-c3cccc([Si](c4ccccc4)(c4ccccc4)c4ccccc4)c3)n2)cc1]

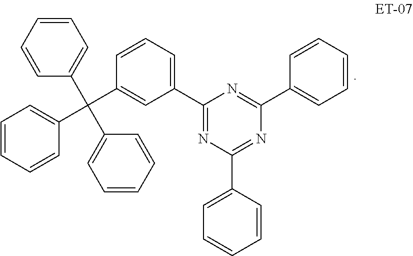 [SMILES: c1ccc(-c2nc(-c3ccccc3)nc(-c3cccc(C(c4ccccc4)(c4ccccc4)c4ccccc4)c3)n2)cc1]

12. The light emitting element of claim 1, wherein the phosphorescent sensitizer is represented by Formula M-a or Formula M-b: 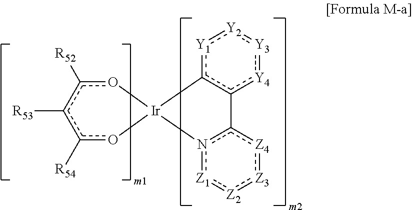
wherein in Formula M-a,
Y₁ to Y₄, and Z₁ to Z₄ are each independently CR₅₁ or N,
R₅₁ to R₅₄ are each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
m1 is 0 or 1,
m2 is 2 or 3,
when m1 is 0, m2 is 3, and
when m1 is 1, m2 is 2, 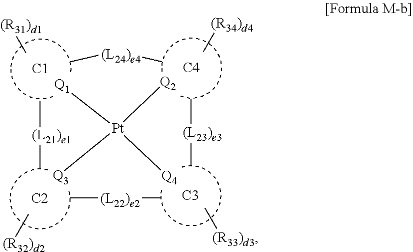
wherein in Formula M-b,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
e1 to e4 are each independently 0 or 1,
L₂₁ to L₂₄ are each independently a direct linkage, 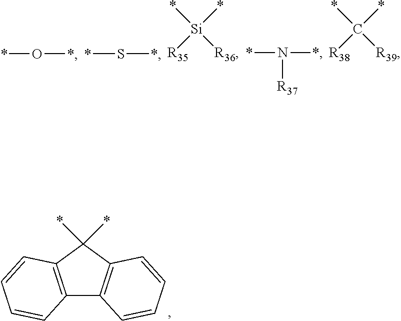
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer of 0 to 4, and
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

13. The light emitting element of claim 1, wherein the phosphorescent sensitizer comprises any one among compounds of Compound Group 4 or Compound Group 5:

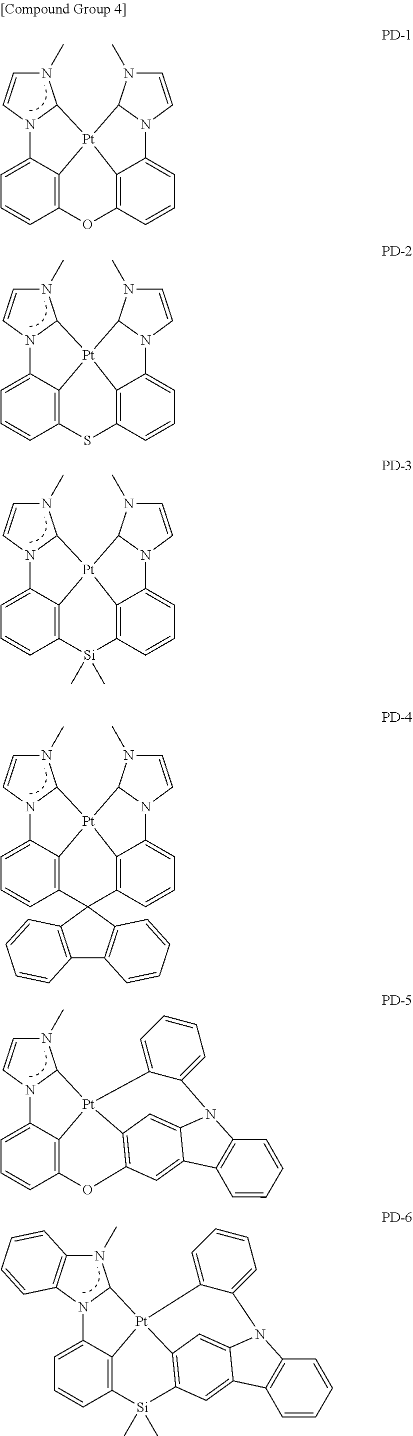

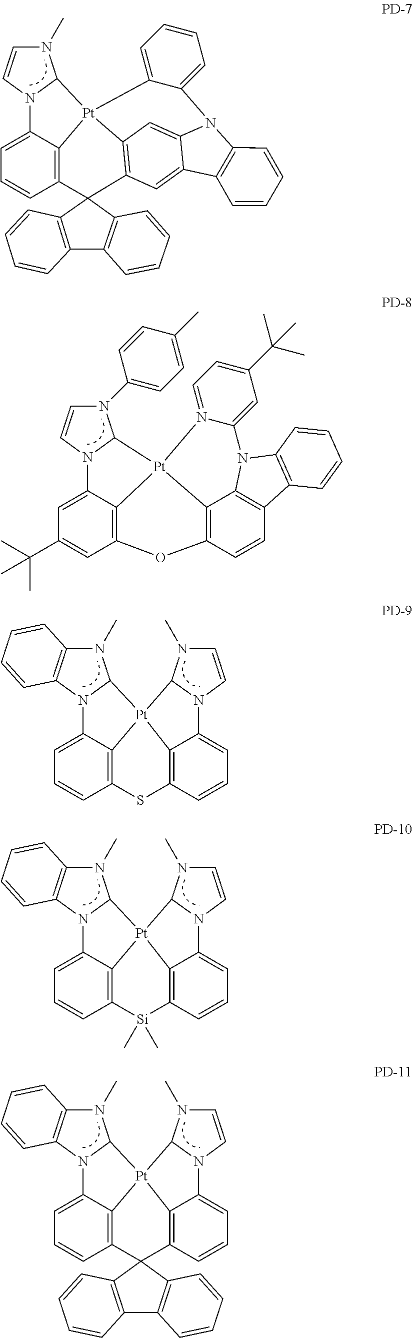

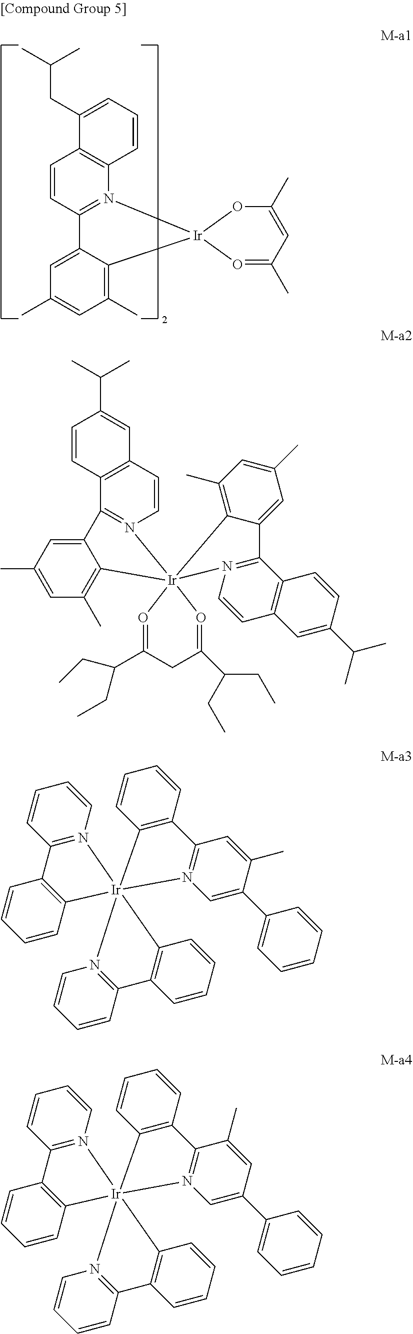

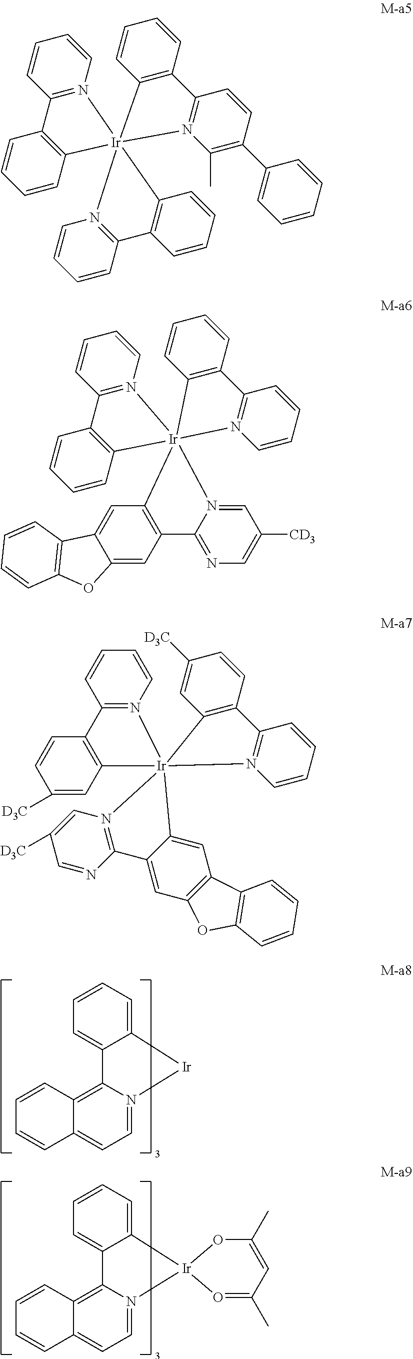

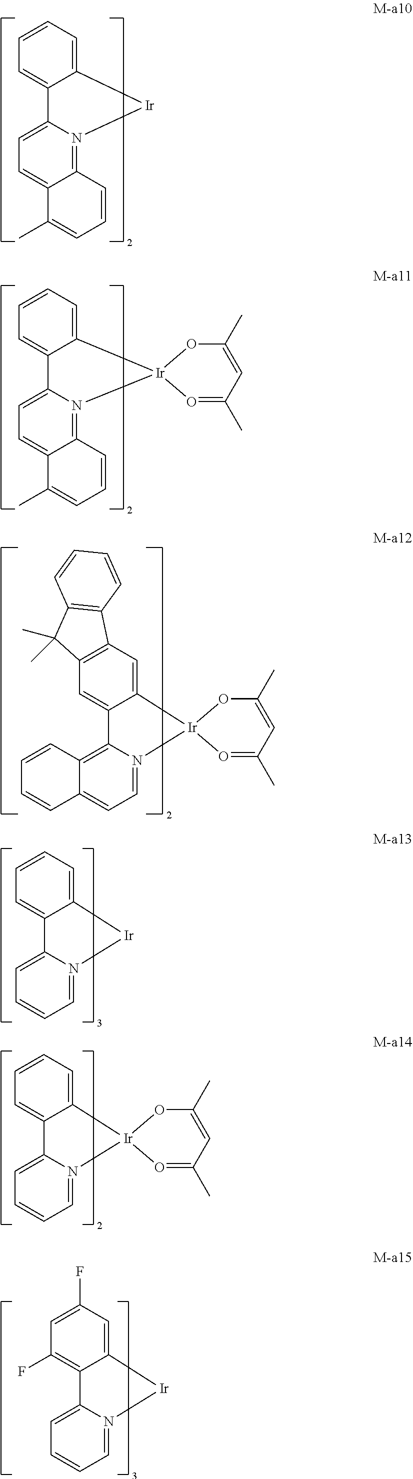

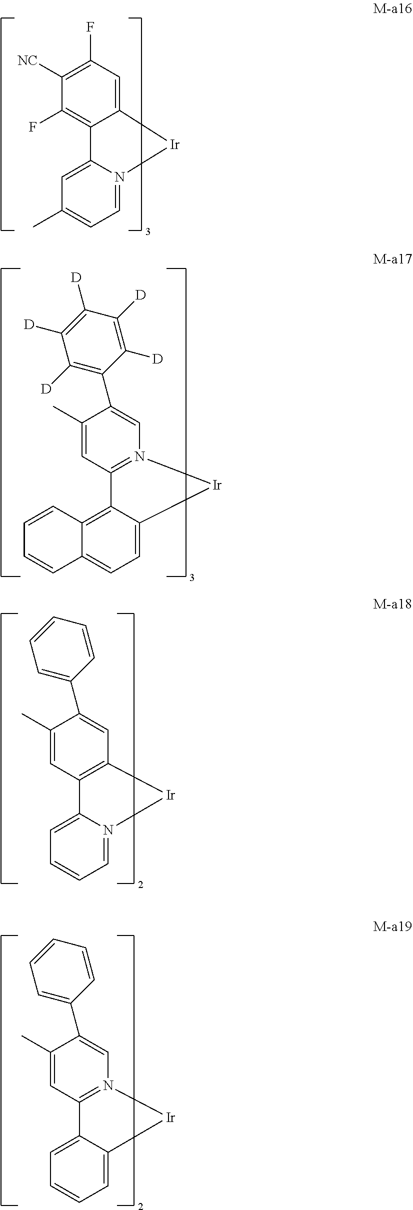

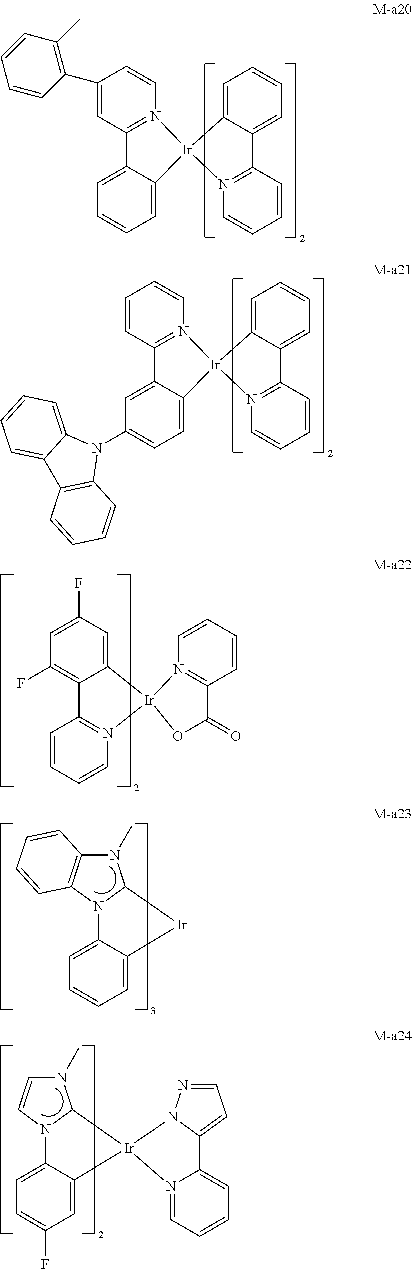

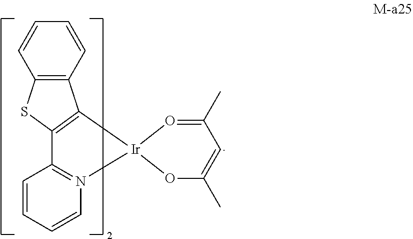

14. The light emitting element of claim 1, further comprising a hole transport region between the first electrode and the emission layer, and an electron transport region between the emission layer and the second electrode.

15. The light emitting element of claim 14, wherein the hole transport region comprises any one among compounds of Compound Group HR:

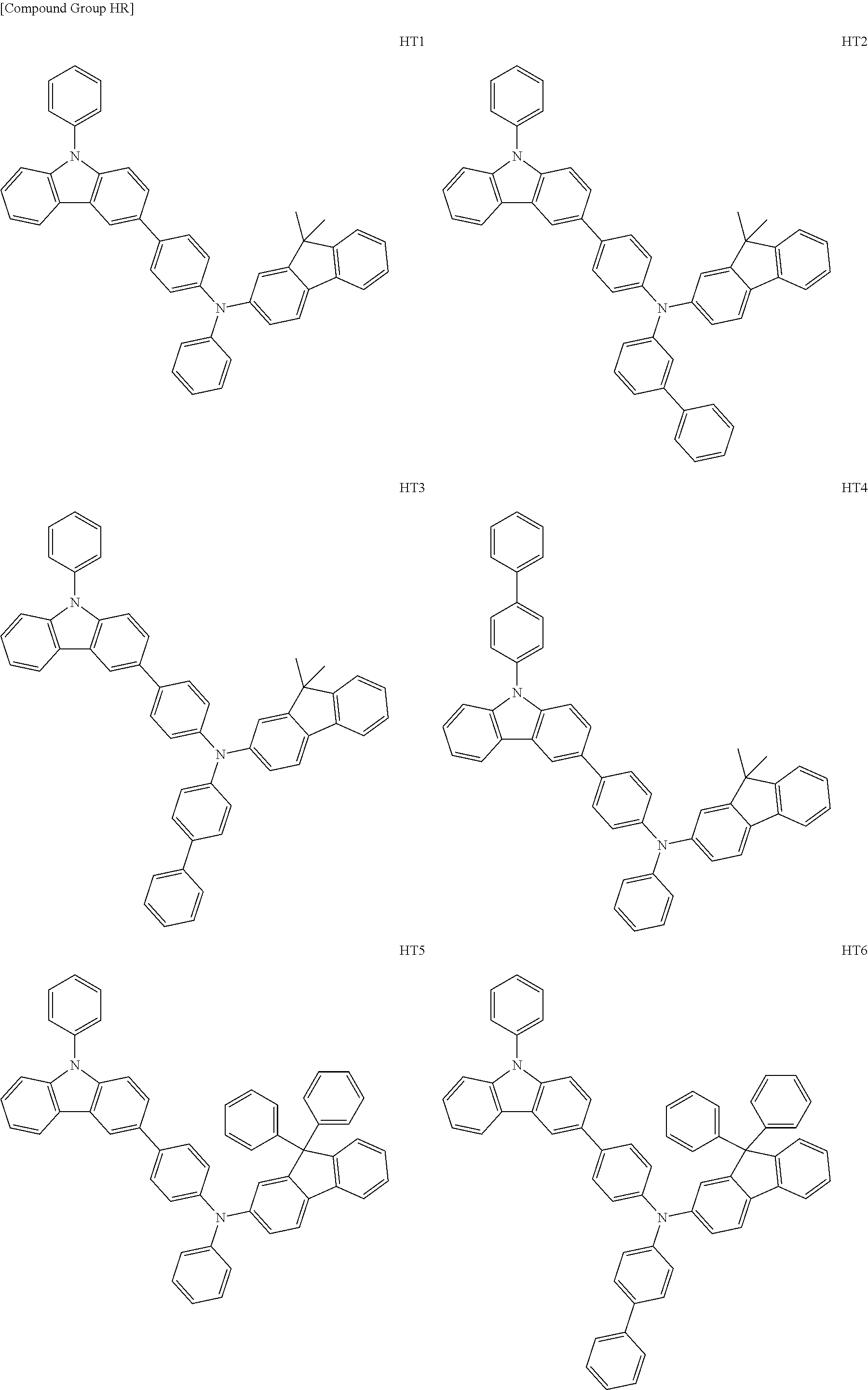

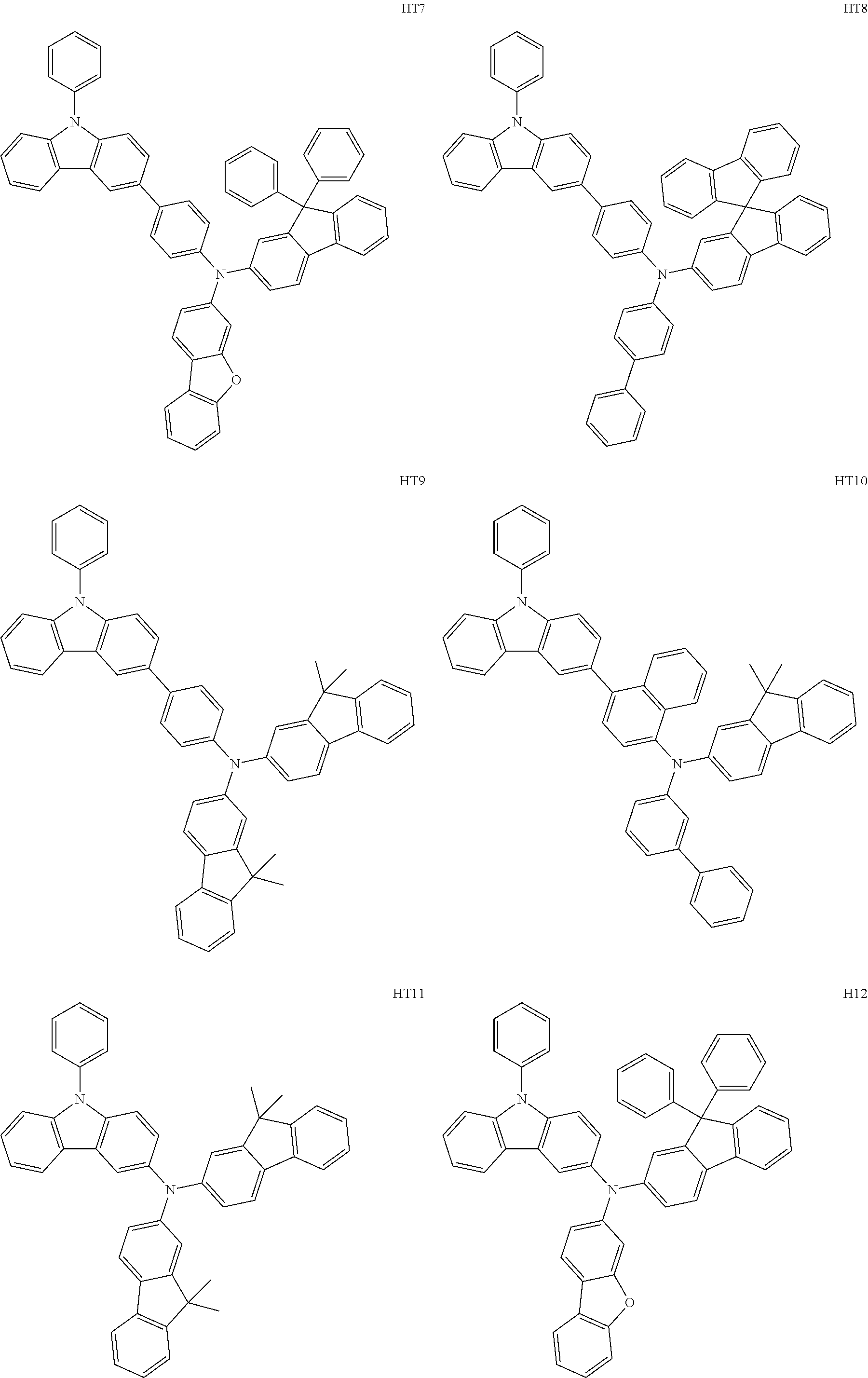

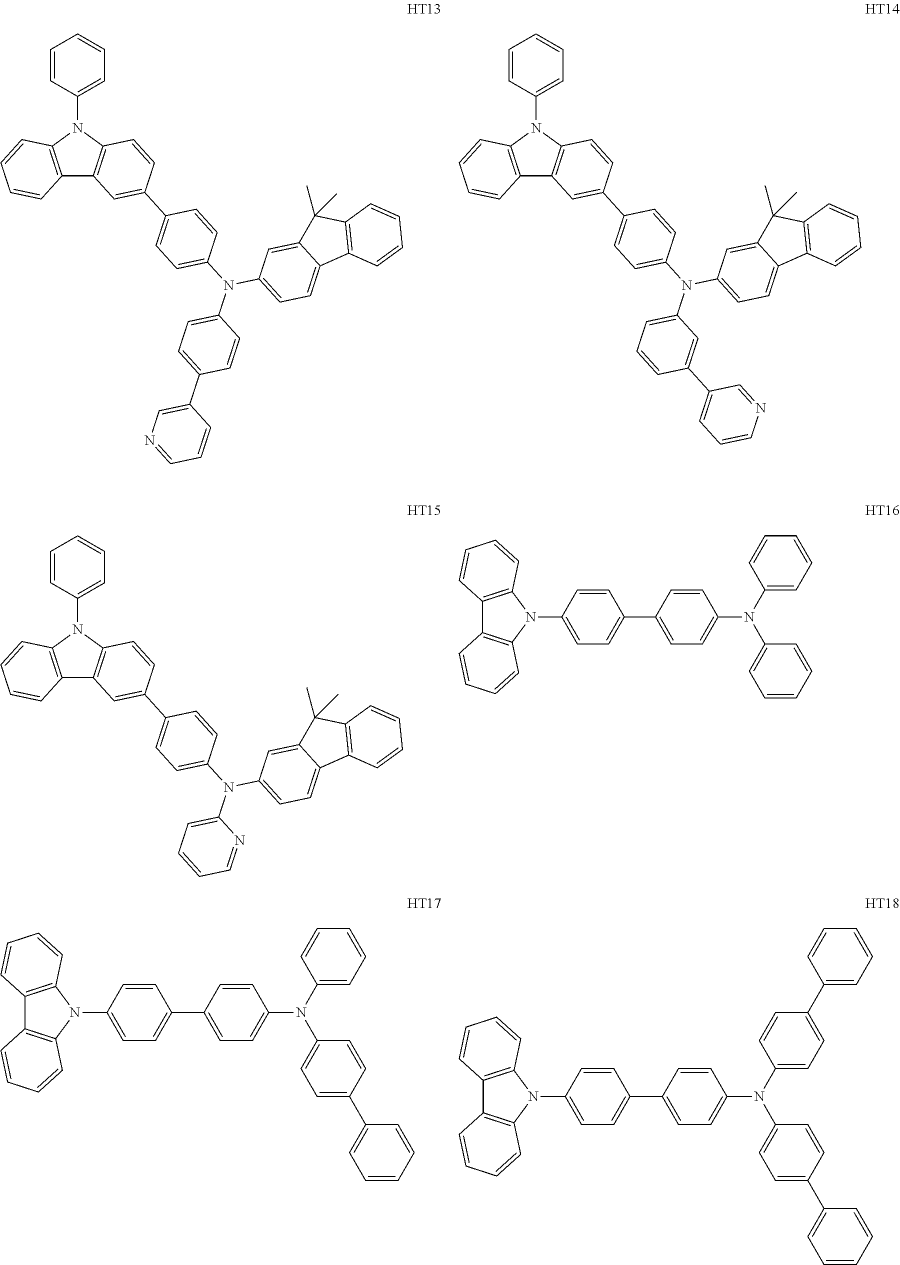 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

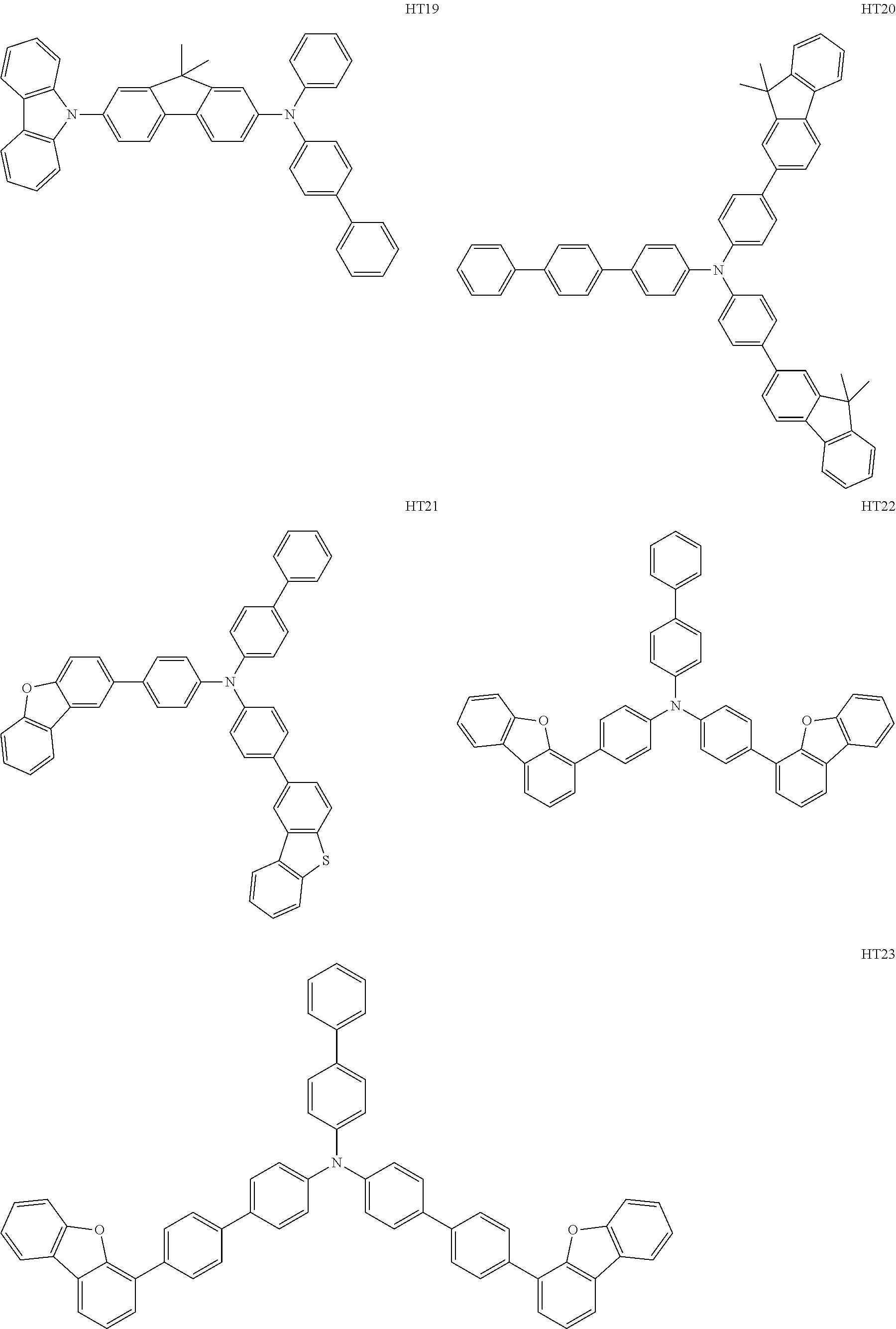 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

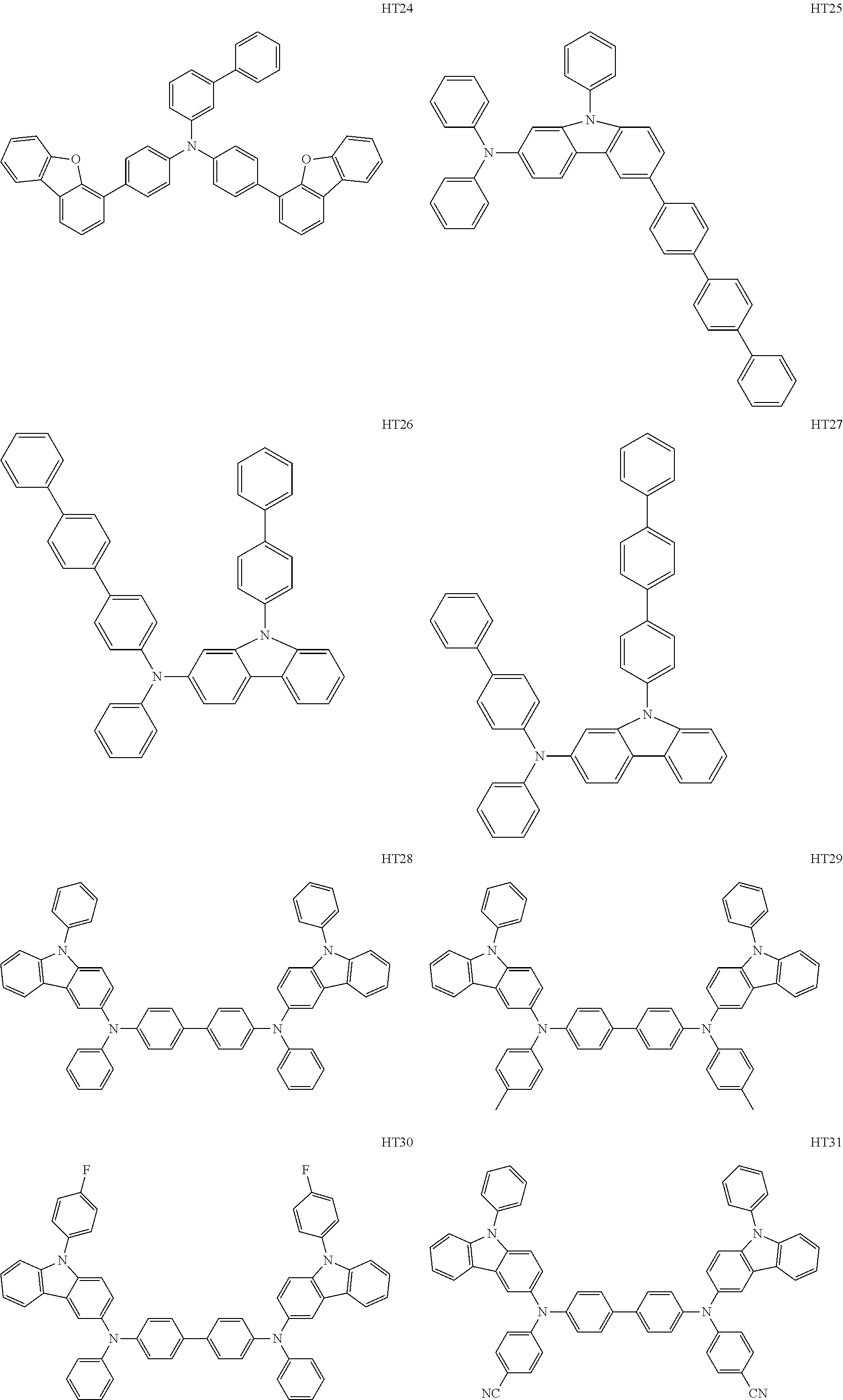

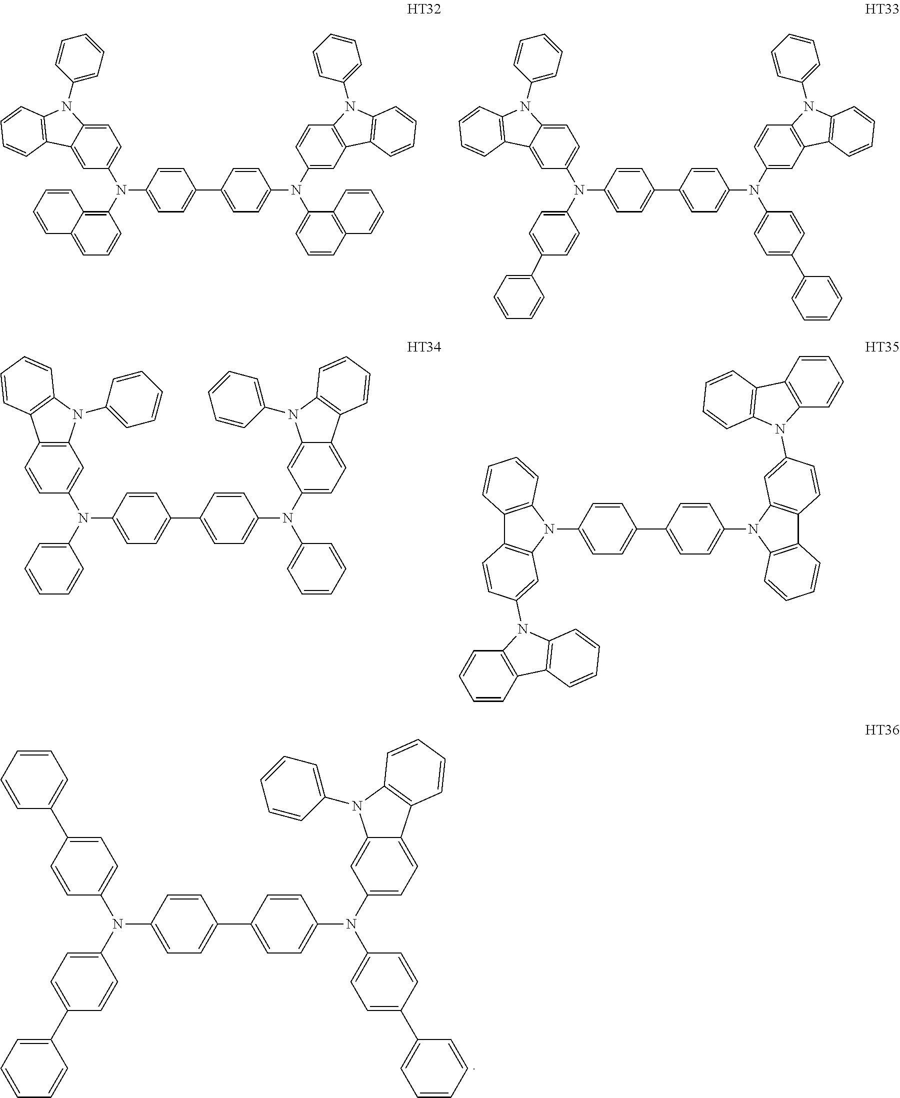

16. The light emitting element of claim 14, wherein the electron transport region comprises any one among compounds of Compound Group ER:

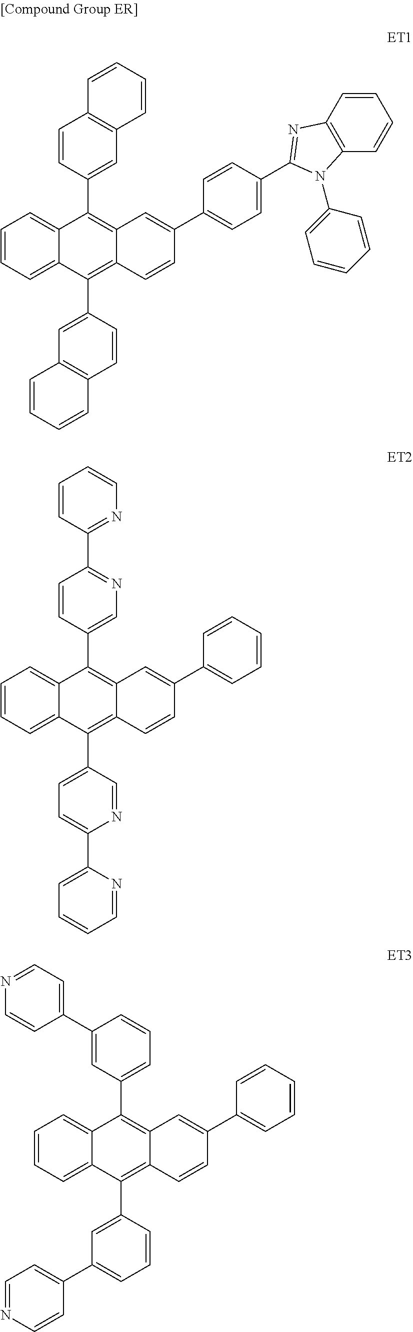 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

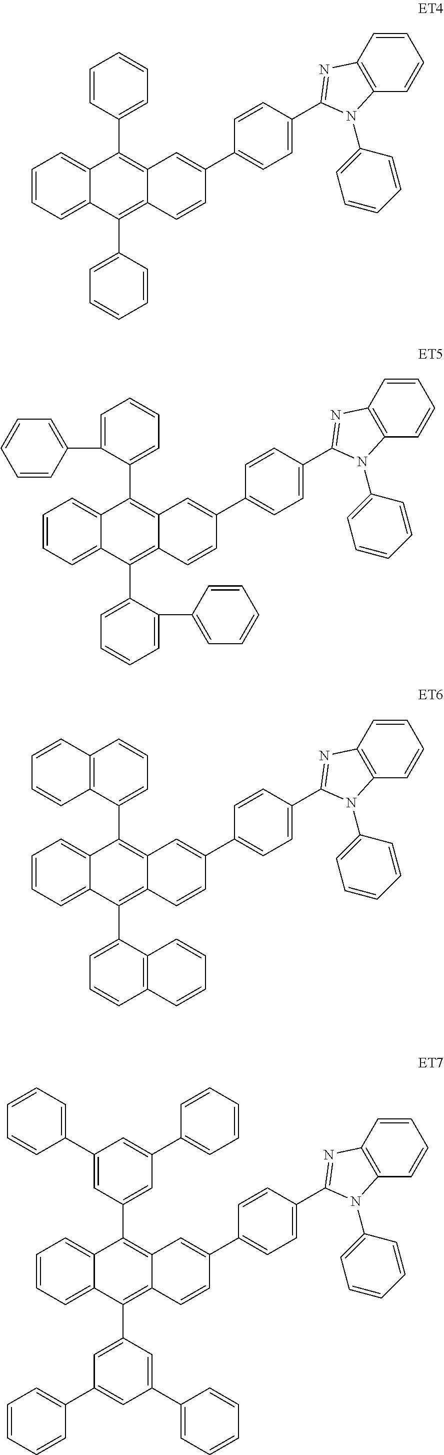 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

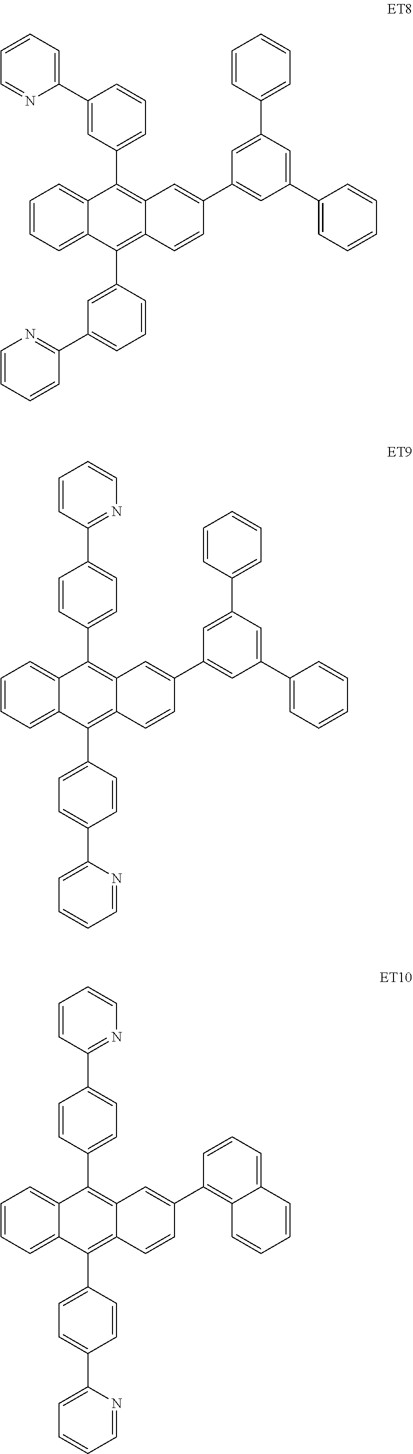 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

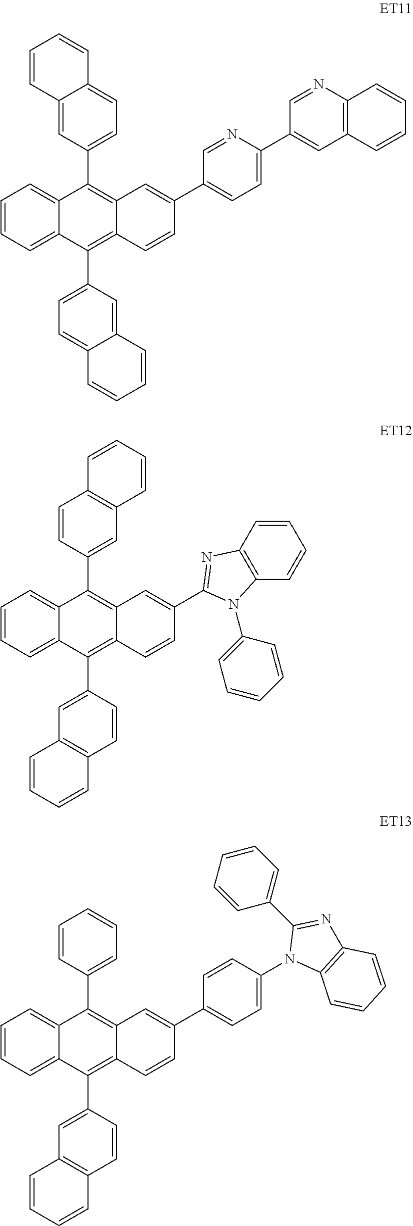

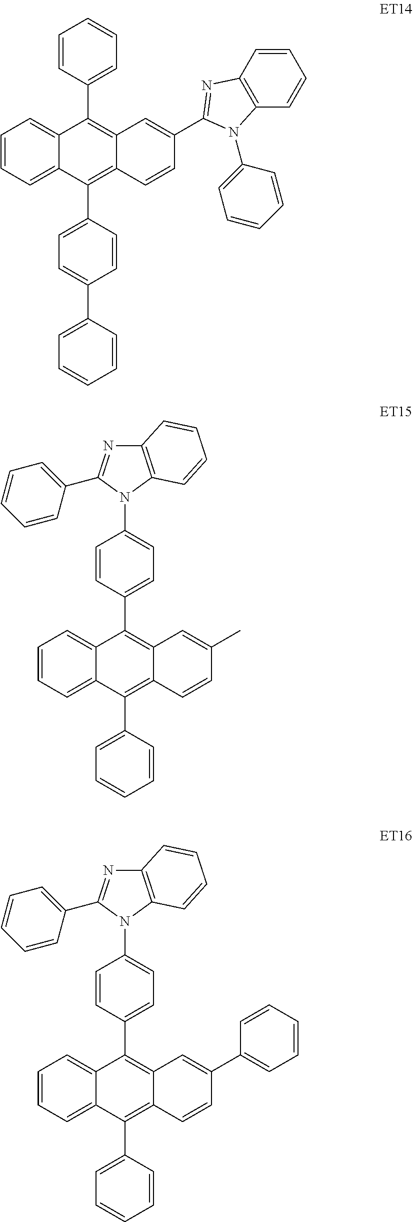 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

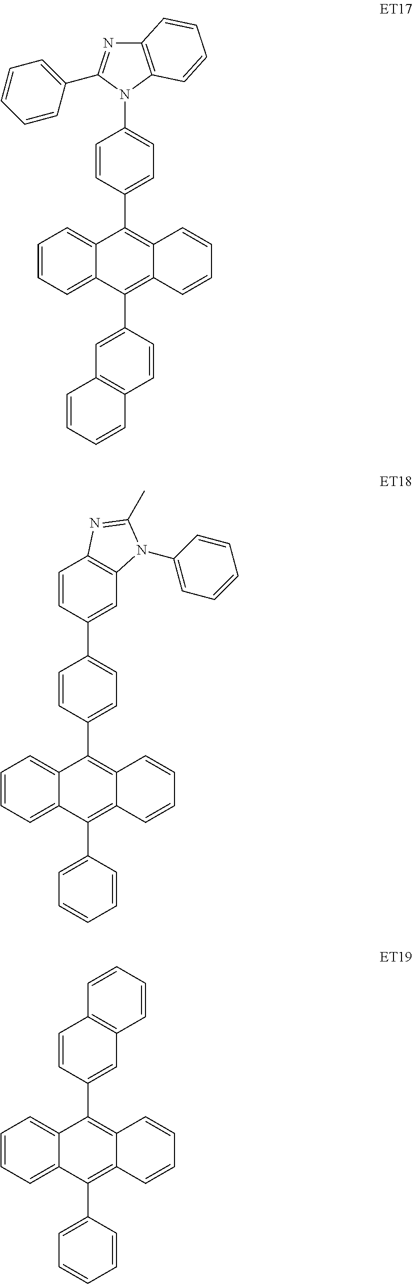

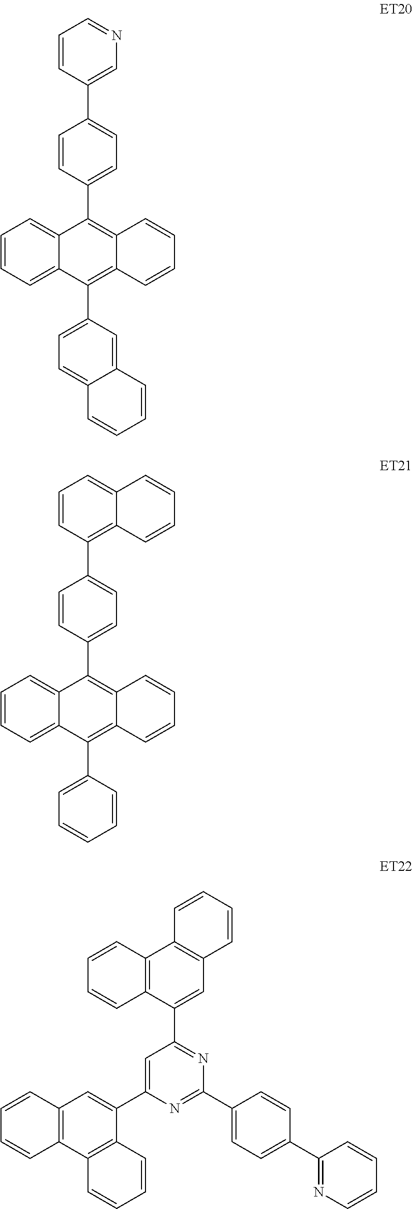

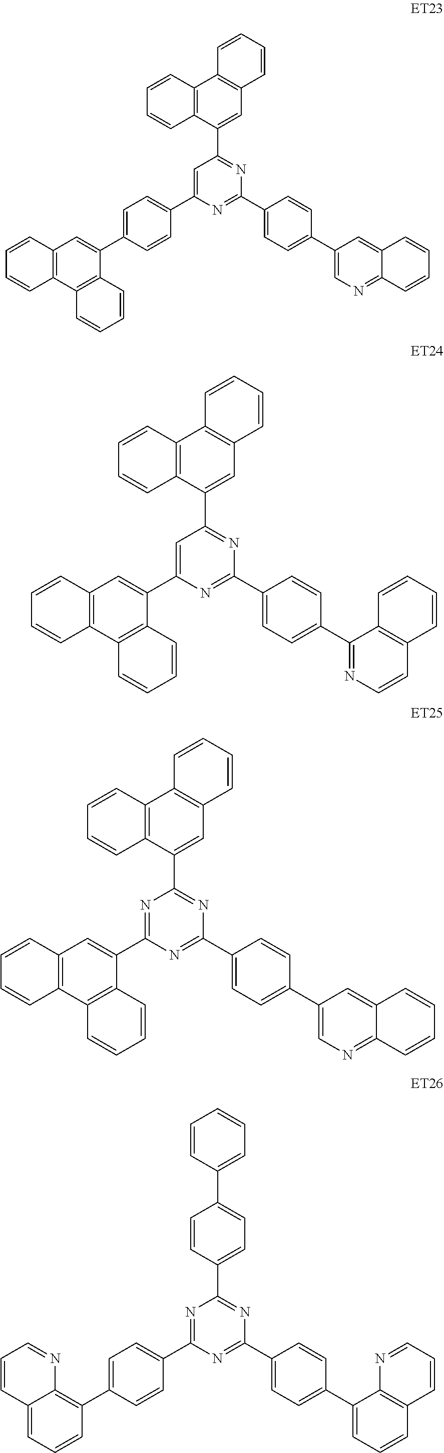 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

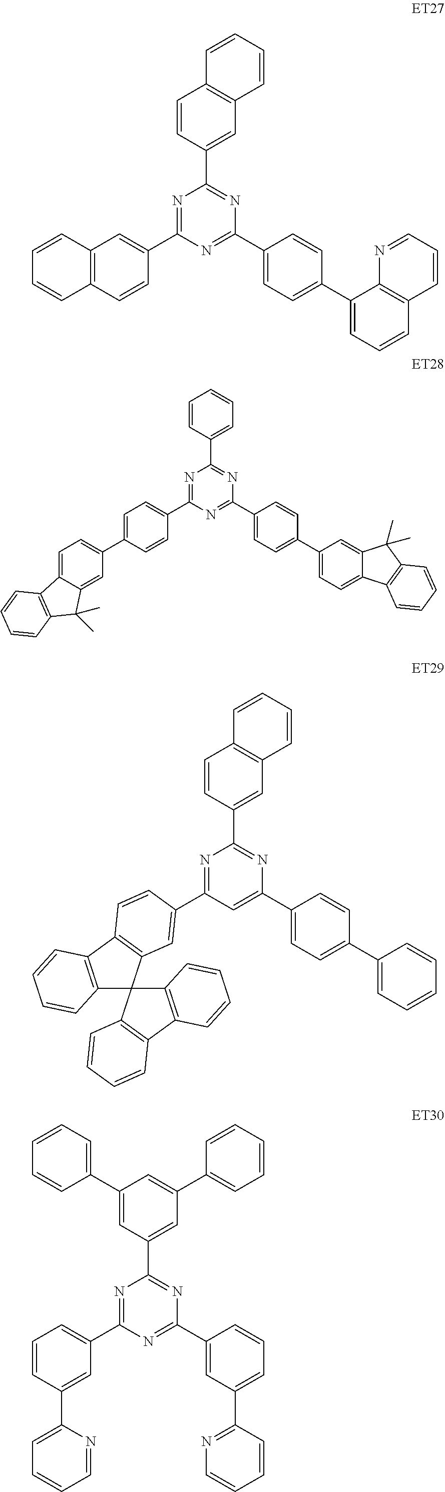 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

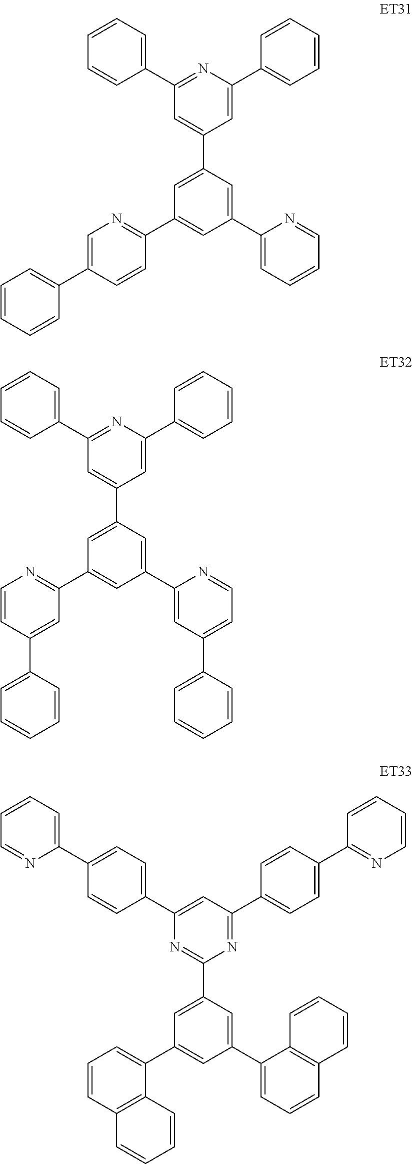

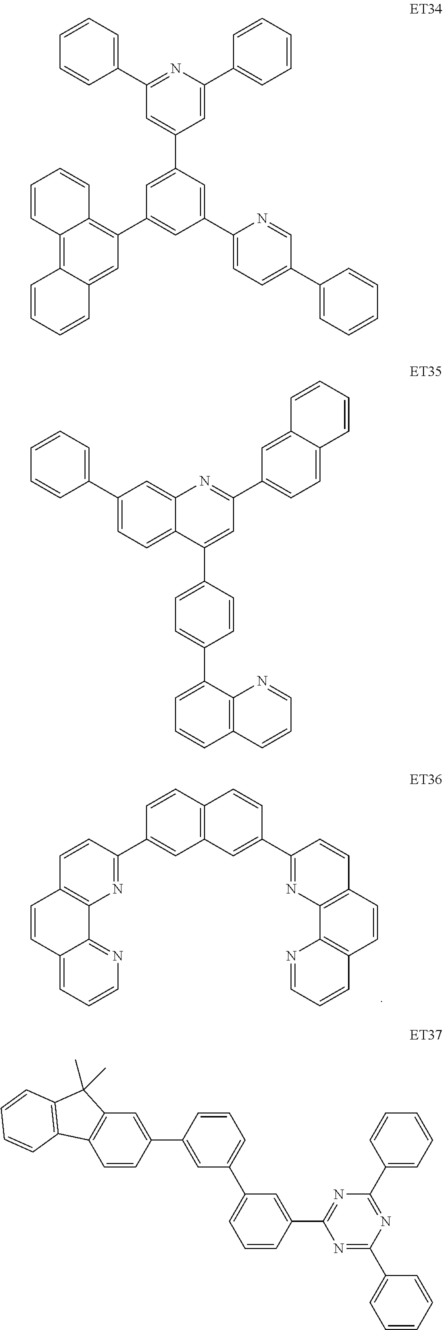 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21]

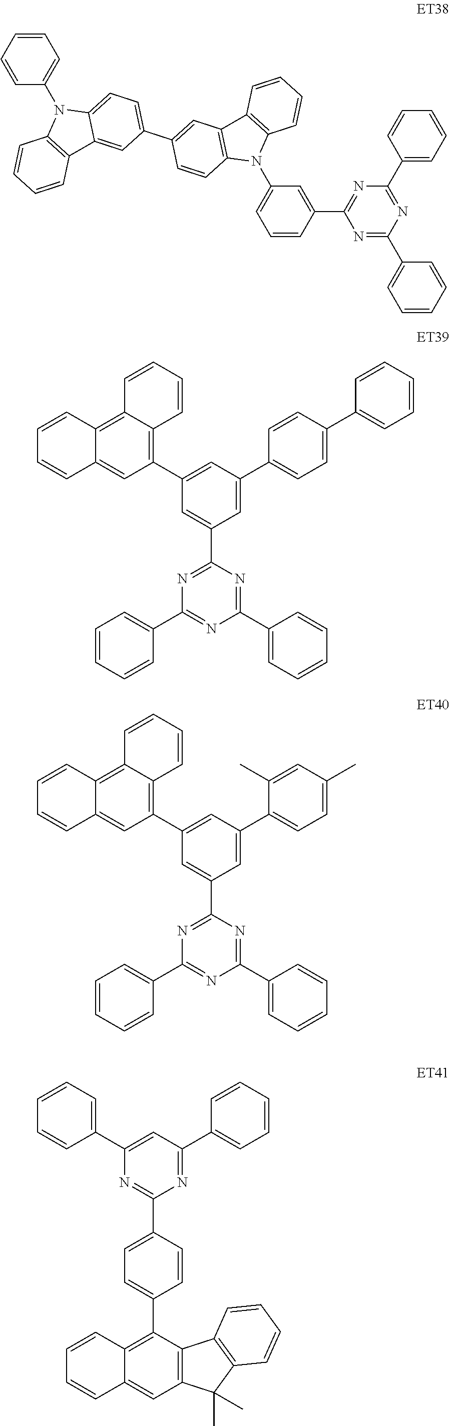

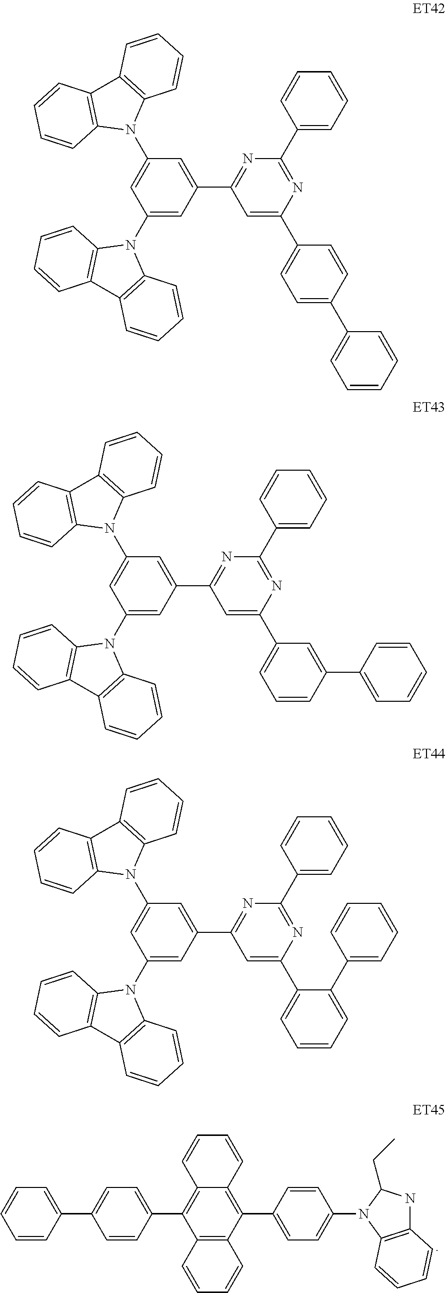

17. A light emitting element comprising:
a first electrode;
a second electrode on the first electrode; and
an emission layer between the first electrode and the second electrode and comprising a hole transporting host, an electron transporting host, a phosphorescent sensitizer, and a delayed fluorescent dopant represented by Formula 1: 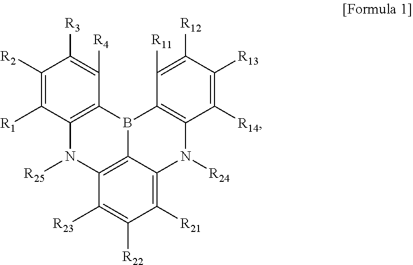
wherein in Formula 1,
two or more of R₁ to R₄, R₁₁ to R₁₄, and R₂₁ to R₂₅ each independently comprise a substituted or unsubstituted carbazole group, and the rest of R₁ to R₄, R₁₁ to R₁₄, and R₂₁ to R₂₅ are each independently a hydrogen atom, a substituted or unsubstituted alkyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms, and
when R₁ to R₄, R₁₁ to R₁₄, and/or R₂₁ to R₂₅ each independently comprises a substituted carbazole group, a substituent of the substituted carbazole group is selected from a cyano group, a substituted or unsubstituted alkyl group having 1 to 10 carbon atoms, and a substituted or unsubstituted aryl group having 6 to 30 ring-forming carbon atoms.

18. The light emitting element of claim 17, wherein the hole transporting host has a lower absolute value of a Highest Occupied Molecular Orbital (HOMO) energy level than the delayed fluorescent dopant, and the phosphorescent sensitizer has a lower absolute value of the HOMO energy level than each of the hole transporting host and the delayed fluorescent dopant.

19. The light emitting element of claim 17, wherein the hole transporting host is represented by Formula HT-1, the electron transporting host is represented by Formula ET-1, and the phosphorescent sensitizer is represented by Formula M-a or Formula M-b: 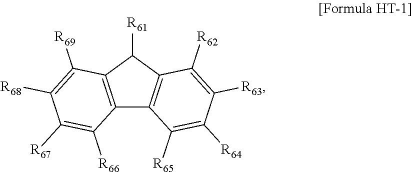
wherein in Formula HT-1,
one among R₆₁ to R₆₉ comprises a substituted or unsubstituted carbazole group, and the rest among R₆₁ to R₆₉ are each independently a hydrogen atom, a substituted or unsubstituted aryl group having 6 to 20 ring-forming carbon atoms, or a substituted or unsubstituted heteroaryl group having 2 to 20 ring-forming carbon atoms, 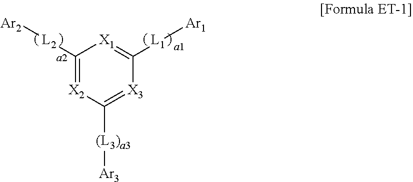
wherein in Formula ET-1,
at least one of X₁ to X₃ is N and the rest of X₁ to X₃ are each independently CRₐ,
Rₐ is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a1 to a3 are each independently an integer of 0 to 10,
L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₁ to Ar₃ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, 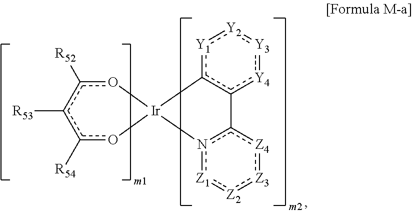
wherein in Formula M-a,
Y₁ to Y₄, and Z₁ to Z₄ are each independently CR₅₁ or N,
R₅₁ to R₅₄ are each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
m1 is 0 or 1,
m2 is 2 or 3,
when m1 is 0, m2 is 3, and
when m1 is 1, m2 is 2, 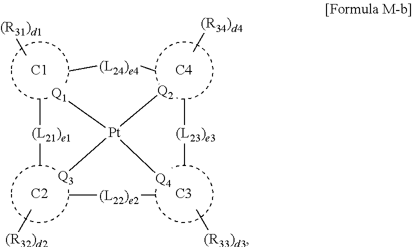
wherein in Formula M-b,
Q₁ to 04 are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
e1 to e4 are each independently 0 or 1,
L₂₁ to L₂₄ are each independently a direct linkage, 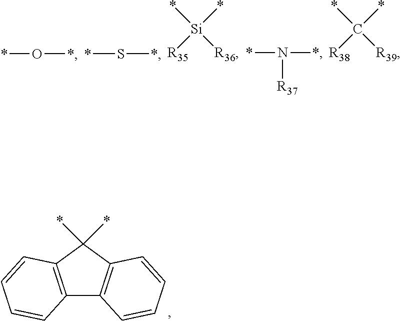
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer of 0 to 4, and
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

20. The light emitting element of claim 17, wherein the delayed fluorescent dopant comprises any one among compounds of Compound Group 1: 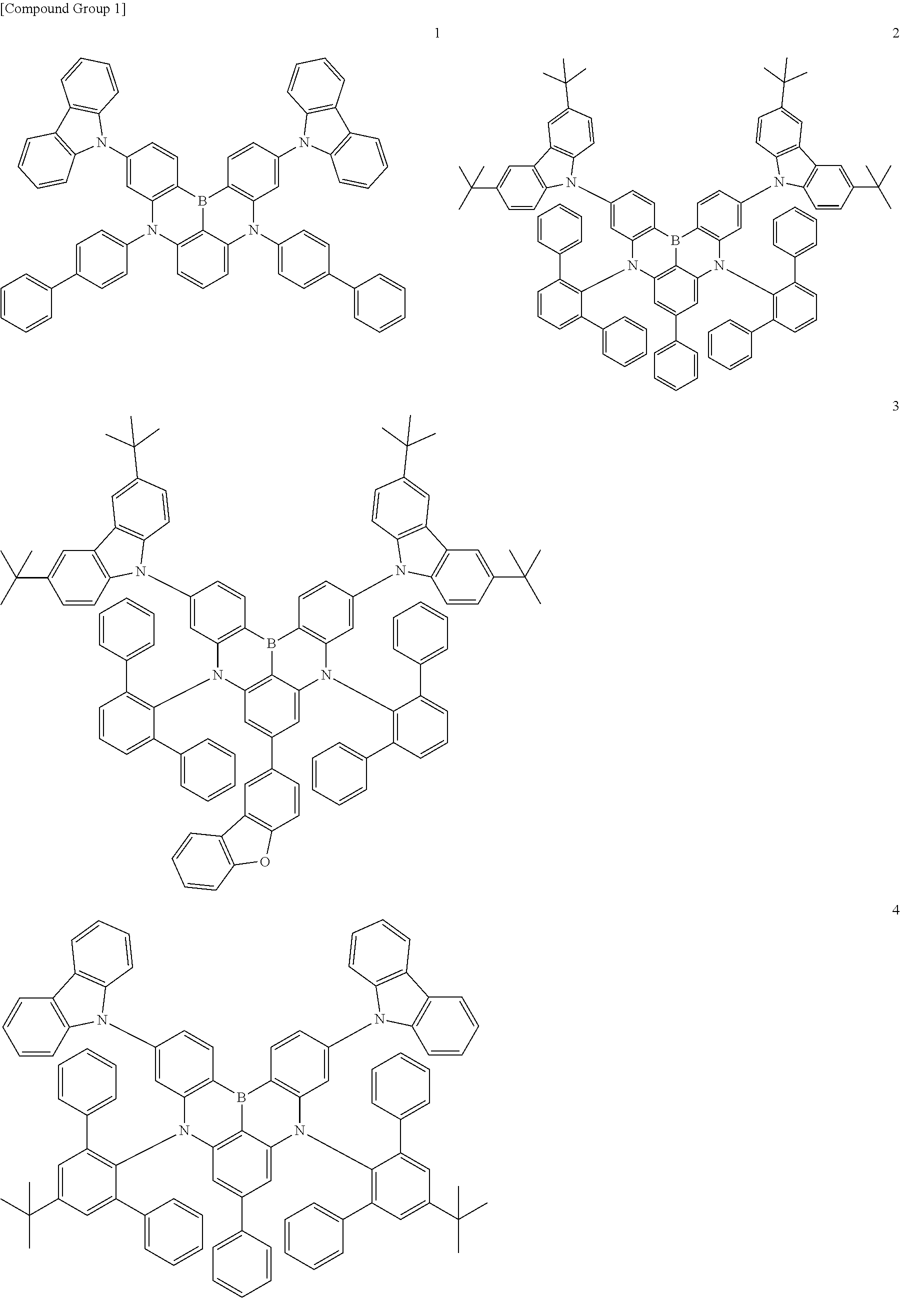 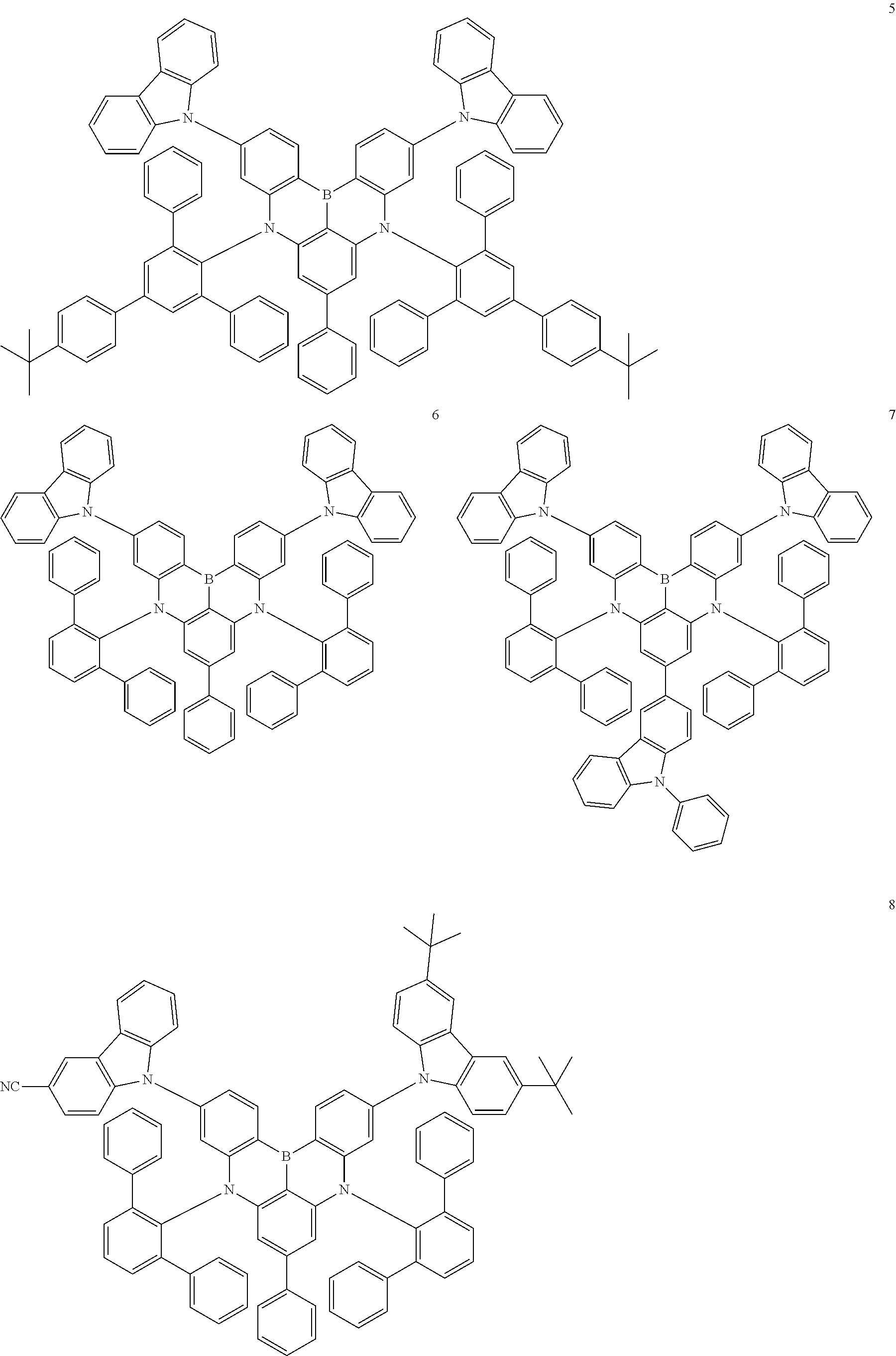 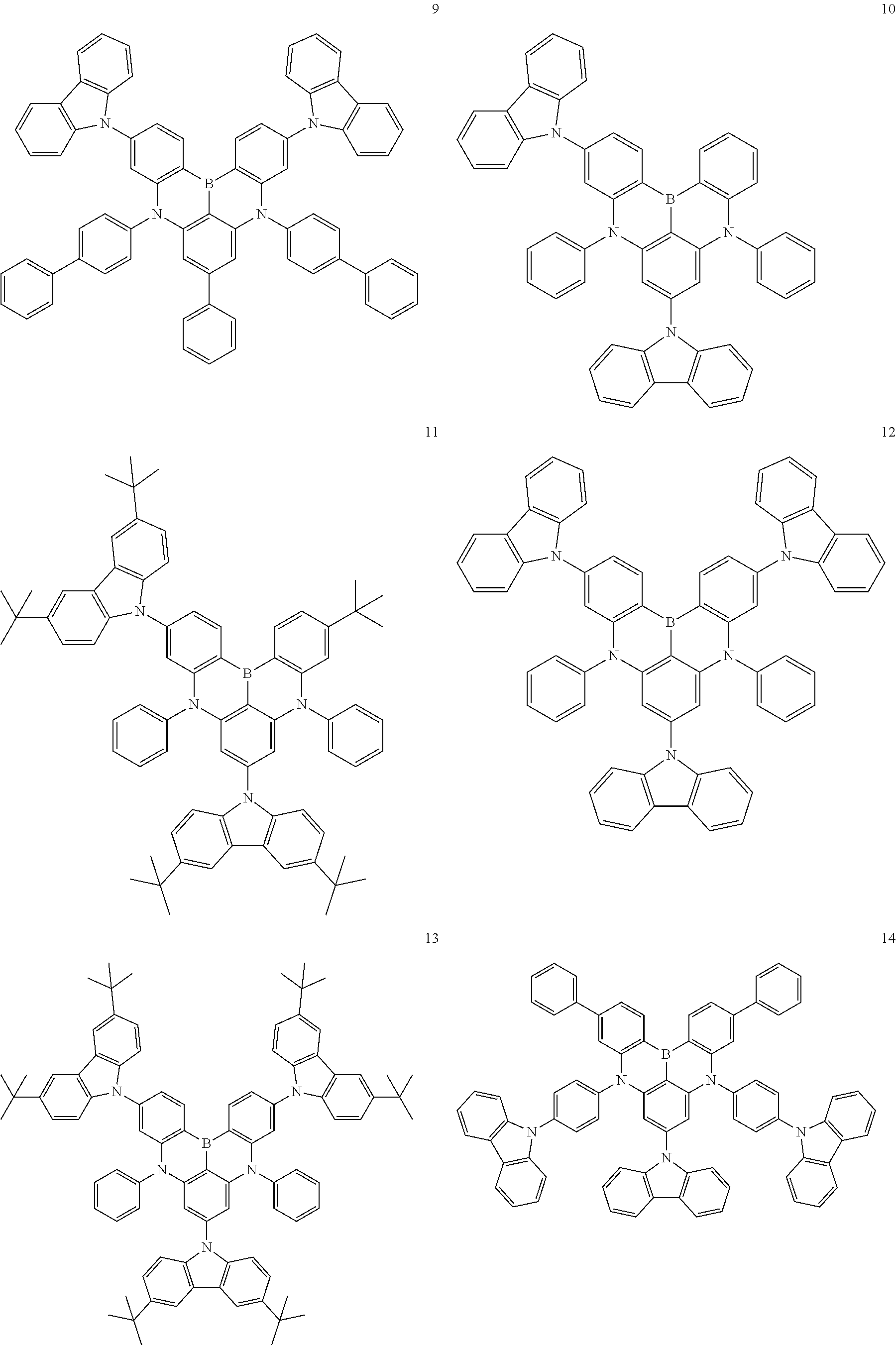 [chemical structure]
